(19) United States
(12) Patent Application Publication
(10) Pub. No.: US 2025/0085309 A1
(43) Pub. Date: Mar. 13, 2025

(54) LOW CROSS-TALK INTERCONNECTION DEVICE WITH IMPEDANCE-TUNED HYBRID SHIELDING STRUCTURES FOR INTEGRATED CIRCUIT DEVICE TEST TOOLING

(71) Applicant: Essai, Inc., Fremont, CA (US)

(72) Inventors: Nasser Barabi, Phoenix, AZ (US); Chee Wah Ho, Chandler, AZ (US); James Ray Hastings, Phoenix, AZ (US); Bela Brian Szendrenyi, Fremont, CA (US); Lum Wai Tsui, Fremont, CA (US); Augie Shastry, Fremont, CA (US); Thomas James Smith, Fremont, CA (US); Joe Xiao, Fremont, CA (US); Farokh Fares, Fremont, CA (US)

(21) Appl. No.: 18/669,517

(22) Filed: May 20, 2024

Related U.S. Application Data
(60) Provisional application No. 63/581,209, filed on Sep. 7, 2023.

(51) Int. Cl. G01R 1/067; G01R 1/073; G01R 31/28

(52) U.S. Cl. CPC G01R 1/06755; G01R 1/07314; G01R 31/2889

(57) ABSTRACT

High frequency operation of an integrated circuit test system is greatly extended by incorporation of dielectric bushings in a contactor assembly to maintain the coaxial transmission line characteristics over a larger frequency range. The provision of a balanced line structure allows for higher impedance characteristics over a broader frequency range and mitigates grounding problems. Elevated grounding annuli are incorporated to improve signal isolation and reduce the effect of undesired waveguide modes.

### CROSS REFERENCE TO RELATED APPLICATION

This Application. (Attorney Docket No. ES-2403), entitled “LOW CROSS-TALK INTERCONNECTION DEVICE WITH IMPEDANCE-TUNED HYBRID SHIELDING STRUCTURES FOR INTEGRATED CIRCUIT DEVICE TEST TOOLING”, claims the benefit and priority of U.S. Provisional Application No. 63/581,209, filed on Sep. 7, 2023 (Attorney Docket No. ES-2301-P), “HYBRID SHIELDING SOCKETS WITH IMPEDANCE TUNING FOR INTEGRATED CIRCUIT DEVICE TEST TOOLING”, the contents of which is incorporated herein in its entirety by this reference.

### BACKGROUND

The present invention relates to systems and methods for reliable test tooling for packaged integrated circuits (IC) devices. In particular, improved signal transmission probe structures for IC device test tooling are provided which include both balanced and unbalanced signal paths.

The dependability of the low frequency electrical connection between the spring probes of the contactor and the contact pads or solder balls of a DUT package can be affected by the ability of the spring probes to penetrate through foreign material layers on the DUT's contact pads/solder balls. Spring probe contactors have been developed that overcome the limitation of uncertain electrical resistance, but the problem of non-linear frequency response has stubbornly persisted. With the rapidly increasing pad/ball densities of IC devices, coupled with rapidly increasing speeds, the inadequate frequency response due mostly to the effects and limitations of the contactor assembly have become a significant obstacle to automated test systems for integrated circuits. The rapid advances in technology fostering far higher operating speeds of these devices have highlighted the need to maintain contact quality over an extended frequency range and improved manufacturability is considered essential.

At frequencies that exceed 10 GHz, 3 cm wavelengths in air, there is a tendency towards guided wave propagation at the interfaces between the physical elements of the test set-up and not solely the transverse electromagnetic field patterns found with coaxial connections. This creates undesirable leakage between signal paths and inadequate testing performance.

It is apparent that an urgent need exists for an improved contactor assembly capable of achieving superior electrical insulation between contact pins of spring probe assemblies. This improved contactor provides extended high frequency performance and enables both unbalanced and balanced signal feeds without compromising frequency response. A manufacturing process integrates a dielectric component into the contactor assembly to improve the broadband performance of the test apparatus results in better electrical insulation between the contact pins while reducing contactor manufacturing errors, resulting in higher yield.

### SUMMARY

To achieve the foregoing and in accordance with the present invention, systems and methods for reliable testing of packaged high speed integrated circuit (IC) devices is provided.

In one embodiment, a contactor assembly is fabricated with improved dielectric insulation. The contactor assembly includes an upper block and a lower block. The upper block and the lower block are coupled to each other to house a plurality of depressible probes. The contactor assembly is designed to detachably make electrical contact with a Device-Under-Test (DUT). Depending on the application requirement, these probes can be vertical or slanted relative to the contactor surface. In this embodiment, fabrication of the contactor assembly is as follows.

An array of bushing pockets is machined in a bushed block of a contactor assembly. This bushed block can be either one of or both of the upper block and the lower block of the contactor assembly. These machined bushing pockets are arranged in a pattern matching a corresponding plurality of contact pads of the DUT. A corresponding plurality of protrusions are formed from a dielectric material. This formed or machined array of protrusions extend from a dielectric base and are arranged in the same matching pattern. The plurality of dielectric protrusions are accommodated inside the bushing pockets.

Next, the dielectric base is removed from the bushed block to form a plurality of dielectric plugs in the bushed block. Note that the tops of the resulting dielectric plugs are flush with the exposed surface of the bushed block. A plurality of contact pin openings are machined within the plugs thereby forming a plurality of dielectric bushings. These plurality of pin openings enable a plurality of mutually isolated contact pins of the plurality of depressible probes to protrude from the contactor surface to make electrical contact with the contact pads of the DUT.

In some embodiments, these protrusions are pillars machined from a dielectric material. The pillars extend from the sacrificial base and are inserted into the bushing pockets. The pillars can be chamfered and/or tapered to ease insertion of the plurality of protrusions into the array of bushing pockets. The pillars can be secured to the bushing pockets using a suitable adhesive. Serrations can be added to the pillars to allow for excess adhesive to escape during the insertion process. As noted above, after the adhesive has cured, the sacrificial base is removed to form the plugs.

Alternatively, these protrusions are pillars formed by inserting rods into corresponding holes of a sacrificial base. These rods can either be machined or extruded from a suitable dielectric material. Prior to insertion, the pillars can be chamfered and/or tapered so that they can be easily aligned and pressed into the array of bushing pockets. Since the base is eventually removed, it can be made from a less expensive material. As discussed above, the pillars can be secured to the bushing pockets using a suitable adhesive. Serrations can be added to the pillars to allow for excess adhesive to escape during the insertion process.

In another embodiment, the dielectric plugs are formed by injecting a suitable plastic material directly into the bushing pockets, with the bushing pockets functioning as a mold for the plastic material. These plugs can be secured inside the bushing pockets with molded keys and/or by introducing a negative draft angle. One exemplary profile of such a bushing pocket has a trapezoidal-shaped cross-section.

In yet another embodiment, one or more layers of pre-impregnated (prepreg) material is applied to the surface of a prepared contactor block having pockets already machined into a surface. These prepreg layers are then compressed between a die block and the contactor block so that the prepreg material flows into the machined pockets. To ensure repeatability, the travel of the die block relative to the contactor block is stopped at a predetermined distance between the two blocks. One example of a hard stop is achieved by using Kapton™ tape of a suitable thickness, applied to a perimeter of the applicable surface of the contactor block. During this process, both contactor block and die block are preheated and the procedure done under vacuum to limit the danger of air bubbles forming in the material where it is forced into the bushing pockets that were machined in the contactor block. Once cured, the prepreg that covers the surface of the contactor block is machined away to leave the bushing pockets with their prepreg fill that will serve as a dielectric bushing in that pocket.

Many modifications and variations of dielectric bushings are possible. For example, instead of individual bushings, conjoined bushings each with two or more contact pin openings can be used to carry balanced signals. The dielectric bushings of the above-described embodiments can also be impedance tuned.

At the frequencies in use, now upwards of 50 GHz, even though there is no apparent coupling intent between signal conductors, the existence of two closely spaced conductive surfaces separated by an insulator such as a passivation layer, for example an anodized layer, creates a waveguide structure and permits the excitation of evanescent waves. The neighboring conductive layers are very close together and the cut-off frequency of the waveguide structure is far too high for waveguide modes at the test frequency to propagate, but evanescent waves will form, creating an undesirable coupling mechanism. Inter channel isolation can be achieved by separating each channel using a grounded, solid conductive wall. However, this suffers from the disadvantage of allowing debris to accumulate from the repeated insertions and removal of devices for testing. Debris can pierce insulating materials such as photoresist or soldermask layers on the DUT leading to unacceptable testing failure. Hence, in some embodiments, acceptable isolation may be achieved using individual conductive raised annuli that are properly sized to suit the DUT geometry. These grounded annuli protrude from the contactor block surface and include ground pin openings for the contact pins of depressible ground probes to protrude and make electrical contact with the DUT ground contact pads.

Note that the various features of the present invention described above may be practiced alone or in combination. These and other features of the present invention will be described in more detail below in the detailed description of the invention and in conjunction with the following figures.

### BRIEF DESCRIPTION OF THE DRAWINGS

In order that the present invention may be more clearly ascertained, some embodiments will now be described, by way of example, with reference to the accompanying drawings, in which:

FIG. 1 is top perspective view of a spring probe contactor, according to one or more aspects of the various embodiments;

FIG. 2 is a bottom perspective view thereof, according to one or more aspects of the various embodiments;

FIG. 3 is a top plan view thereof, according to one or more aspects of the various embodiments;

FIG. 4 is a bottom plan view thereof, according to one or more aspects of the various embodiments;

FIG. 5A is an enlarged cross-sectional view thereof, taken along section lines 5A-5A in the foregoing figures, without the spring probes, according to one or more aspects of the various embodiments;

FIG. 5B is the cross-sectional view shown in FIG. 5A with the spring probes loaded into the spring probe retention cavities of the contactor assembly, according to one or more aspects of the various embodiments;

FIG. 6 is an exploded view of a contactor, IC device, and test board illustrating the use of the contactor, according to one or more aspects of the various embodiments;

FIG. 7 is an enlarged cut-away view of the contactor assembly, IC device under test, and test board shown in FIG. 6, with the DUT pressed against the contactor assembly, and illustrating how the angled spring probes contact the contact pads of the DUT, according to one or more aspects of the various embodiments;

FIG. 8A shows a partial cross-sectional view of one embodiment of a contactor assembly with dielectric bushings providing improved electrical properties between the contact pins, according to one or more aspects of the various embodiments;

FIG. 8B is a cross-sectional view of the upper block of FIG. 8A, according to one or more aspects of the various embodiments;

FIG. 8C illustrates a cross-sectional view of an upper block having angled bushings that are coaxial with the probe retention cavities, according to one or more aspects of the various embodiments;

FIG. 9A illustrates dielectric pillars machined from a non-conductive dielectric material prior to installation in the bushing pockets, according to one or more aspects of the various embodiments;

FIG. 9B shows a perspective view of a dielectric pillar from FIG. 9A, according to one or more aspects of the various embodiments;

FIG. 10 shows multiple substrates having dielectric pillars installed onto an upper block in diverse positions, according to one or more aspects of the various embodiments;

FIG. 11 illustrates a typical perspective of a complex insulated dielectric pillar layout prior to insertion into the bushing pockets on a partly machined upper block according to one or more aspects of the various embodiments;

FIG. 12A illustrates the initial machining of bushing pockets into the upper block, according to one or more aspects of the various embodiments;

FIG. 12B shows the prepared dielectric pillar structure inserted into corresponding bushing pockets of a partly machined upper block, according to one or more aspects of the various embodiments;

FIG. 12C shows the appearance of the top of the upper block after the waste dielectric substrate is removed to form dielectric plugs, according to one or more aspects of the various embodiments;

FIG. 12D shows a plan view of more than one dielectric substrate with the pillars installed in the bushing pockets of the upper block, according to one or more aspects of the various embodiments;

FIG. 12E is a sectioned view of more than one dielectric substrate with the pillars inside in the upper block, according to one or more aspects of the various embodiments;

FIG. 12F is a perspective view of the more than one installed dielectric substrate with the pillars inside in the upper block, according to one or more aspects of the various embodiments;

FIG. 12G illustrates construction of a dielectric pillar group similar to that of FIG. 9, but from discrete component parts well suited to high volume manufacture, according to one or more aspects of the various embodiments;

FIG. 12H shows the progression of assembly of the components of FIG. 12G, according to one or more aspects of the various embodiments;

FIG. 12J shows an alternative version of the construction illustrated in

FIG. 12G, according to one or more aspects of the various embodiments;

FIG. 12K shows the progression of assembly of the components of FIG. 12J, according to one or more aspects of the various embodiments;

FIG. 12L illustrates a stepped pillar with better manufacturing properties, according to one or more aspects of the various embodiments;

FIGS. 12M-12N show alternate versions of FIGS. 12G and 12H, according to one or more aspects of the various embodiments;

FIG. 13A illustrates how a keyway feature may be machined into the bushing pockets to secure a molded bushing without adhesive, according to one or more aspects of the various embodiments;

FIG. 13B shows an enlarged view of a single bushing pocket with the keyway feature, according to one or more aspects of the various embodiments;

FIG. 13C shows a portion of the injected dielectric pillars filling the bushing pockets and engaging the machined keyway feature, according to one or more aspects of the various embodiments;

FIG. 13D shows the appearance of the top of the upper block after the waste dielectric substrate is removed, thereby forming dielectric plugs, according to one or more aspects of the various embodiments;

FIG. 13E illustrates a cutting profile and tool suitable for use in preparing a matching bushing pocket cut, according to one or more aspects of the various embodiments;

FIGS. 13F, 13G, 13H and 13J illustrate an injection process for forming the dielectric plugs of FIG. 13D, according to one or more aspects of the various embodiments;

FIG. 14 is a plan view of two adjacent dielectric bushings that support two contact pins for unbalanced signals, according to one or more aspects of the various embodiments;

FIG. 15 illustrates how an embodiment of a conjoined dielectric bushing for supporting a pair of contact pins that are used to deliver a balanced signal pair, according to one or more aspects of the various embodiments;

FIG. 16 illustrates another embodiment of a conjoined dielectric bushing for supporting another balanced signal applications, according to one or more aspects of the various embodiments;

FIG. 17 illustrates an alternative dielectric bushing for improved adhesion, according to one or more aspects of the various embodiments;

FIG. 18 illustrates yet another embodiment with contactor block(s) having a similar dielectric bushing structure to the contactor block of FIG. 8A, according to one or more aspects of the various embodiments;

FIG. 19 shows a dielectric bushing with capture ridges and a drilling taper present, according to one or more aspects of the various embodiments;

FIG. 20 shows an alternative bushing with a drilling taper and flat surface produced by a milling cut, according to one or more aspects of the various embodiments;

FIG. 21A illustrates a connector block in the region of the high frequency signal connections where each differential pair is isolated by surrounding grounded conducting raised annuli that protrude above the upper surface, according to one or more aspects of the various embodiments;

FIG. 21B shows a section line defining a cross-sectional view to be shown, according to one or more aspects of the various embodiments;

FIG. 21C illustrates a cross-sectional view at a section line shown in FIG. 21B, according to one or more aspects of the various embodiments;

FIG. 22A is a close-up perspective view of a portion of two signal conductors separated by a protruding ground annulus with the contact pins in the uncompressed position, according to one or more aspects of the various embodiments;

FIG. 22B is a view of FIG. 22A where the contact pins are shown in the compressed or operating position, according to one or more aspects of the various embodiments;

FIG. 22C is a segment of FIG. 22B shown in close up, according to one or more aspects of the various embodiments;

FIG. 23A is a profile view of the section line marked in FIG. 22B, according to one or more aspects of the various embodiments;

FIG. 23B is a close-up view of the upper contactor block depicting the relative positions of a contact ball and a grounding annulus with its concentric contact pin, according to one or more aspects of the various embodiments;

FIG. 23C is a close-up view of the lower contactor block depicting a grounding annulus with its concentric ground contact pin, according to one or more aspects of the various embodiments;

FIG. 24A shows a contactor block with bushing pockets overlayed by several layers of prepreg material, according to one or more aspects of the various embodiments;

FIG. 24B shows the bushing pockets filled with prepreg after the layers shown in FIG. 24A have been compressed, according to one or more aspects of the various embodiments;

FIG. 24C shows the contactor block with filled bushing pockets after the residue of the prepreg has been machined away, according to one or more aspects of the various embodiments;

FIG. 25 is a flowchart illustrating the fabrication of the dielectric bushings according to one or more aspects of the various embodiments;

FIG. 26 is a flowchart illustrating the fabrication of the raised grounded annuli according to one or more aspects of the various embodiments;

FIGS. 27A-27D are cross-sectional views illustrating the fabrication of the raised grounded annuli according to one or more aspects of the various embodiments;

FIG. 28 is a flowchart illustrating the fabrication of the dielectric bushings and the raised grounded annuli, according to one or more aspects of the various embodiments; and

FIGS. 29A-G are cross-sectional views illustrating the fabrication of the dielectric bushings and the raised grounded annuli, according to one or more aspects of the various embodiments.

### DETAILED DESCRIPTION

The present invention will now be described in detail with reference to several embodiments thereof as illustrated in the accompanying drawings. In the following description, numerous specific details are set forth in order to provide a thorough understanding of embodiments of the present invention. It will be apparent, however, to one skilled in the art, that embodiments may be practiced without some or all of these specific details. In other instances, well known process steps and/or structures have not been described in detail in order to not unnecessarily obscure the present invention. The features and advantages of embodiments may be better understood with reference to the drawings and discussions that follow.

Aspects, features and advantages of exemplary embodiments of the present invention will become better understood with regard to the following description in connection with the accompanying drawing(s). It should be apparent to those skilled in the art that the described embodiments of the present invention provided herein are illustrative only and not limiting, having been presented by way of example only. All features disclosed in this description may be replaced by alternative features serving the same or similar purpose, unless expressly stated otherwise. Therefore, numerous other embodiments of the modifications thereof are contemplated as falling within the scope of the present invention as defined herein and equivalents thereto. Hence, use of absolute and/or sequential terms, such as, for example, “will,” “will not,” “shall,” “shall not,” “must,” “must not,” “first,” “initially,” “next,” “subsequently,” “before,” “after,” “lastly,” and “finally,” are not meant to limit the scope of the present invention as the embodiments disclosed herein are merely exemplary.

I. Overview of Novel Aspects of the various Embodiments

The novel aspects of the various embodiments described in detail below revolve around providing dielectric bushings for housing contact pins of signal probes to provide extended high frequency performance and to enable both unbalanced and balanced signal feeds without compromising frequency response. Many methods, including the exemplary methods described herein, can be used to fabricated these dielectric bushings. These methods include hot-pressing of thermoplastics and injection molding. Note that these depressible probes can be oriented vertically or slanted with respect to the surface of the contactor block, depending on the implementational requirements.

In some embodiments, ground annuli protruding from the surface of contactor assembly collectively act as an electrical fence with minimal signal porosity. Note that these raised ground annuli function in combination with a corresponding plurality of depressible ground probes housed within the contactor assembly to reduce unwanted interfering signal to acceptable levels. Accordingly, signal probes for coupling to the DUT can be surrounded by the grounded washer-shaped raised annuli.

### II. Slanted Compressible Probes for Contactor Assembly

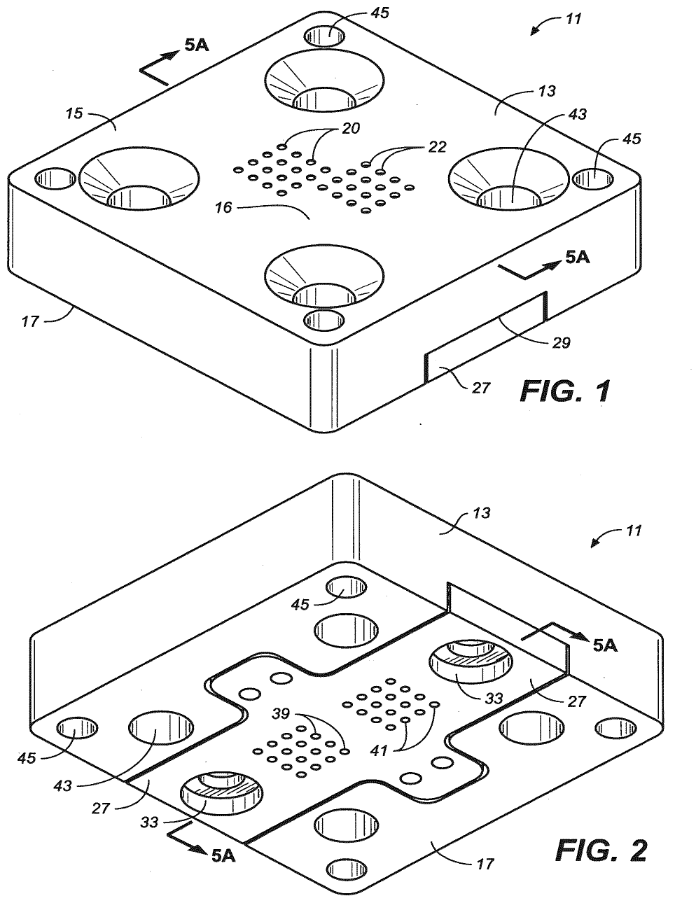

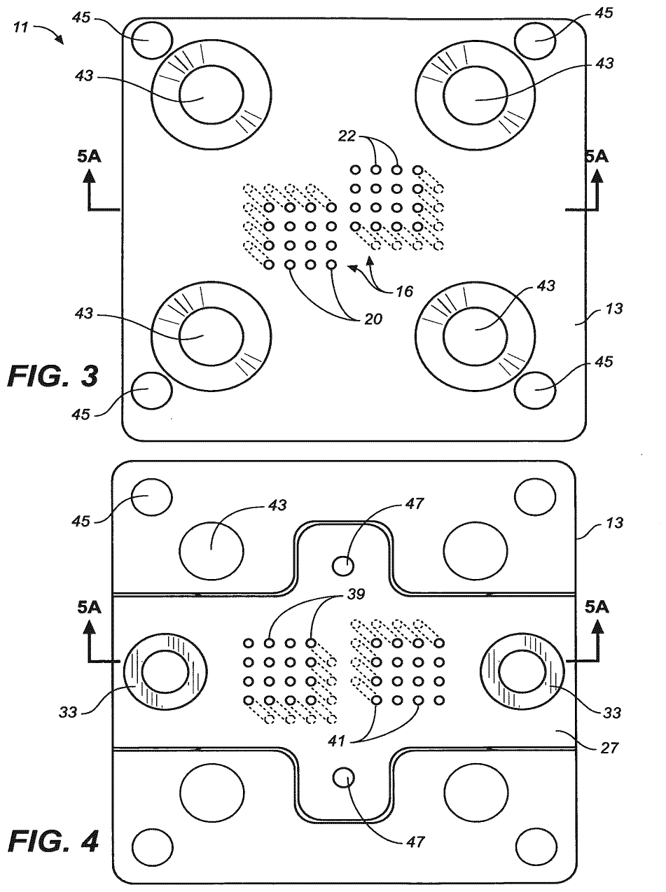

Referring to the drawings, FIGS. 1 and 2 illustrate a perspective view of an example spring probe contactor assembly 11 includes upper block 13 and lower block 27, having parallel top and bottom faces 15 and 17 respectively, defining contactor interface wall 16. FIGS. 3 and 4 show a plan view for better clarity as to the structure of the small-scale example of a spring probe contactor assembly 11.

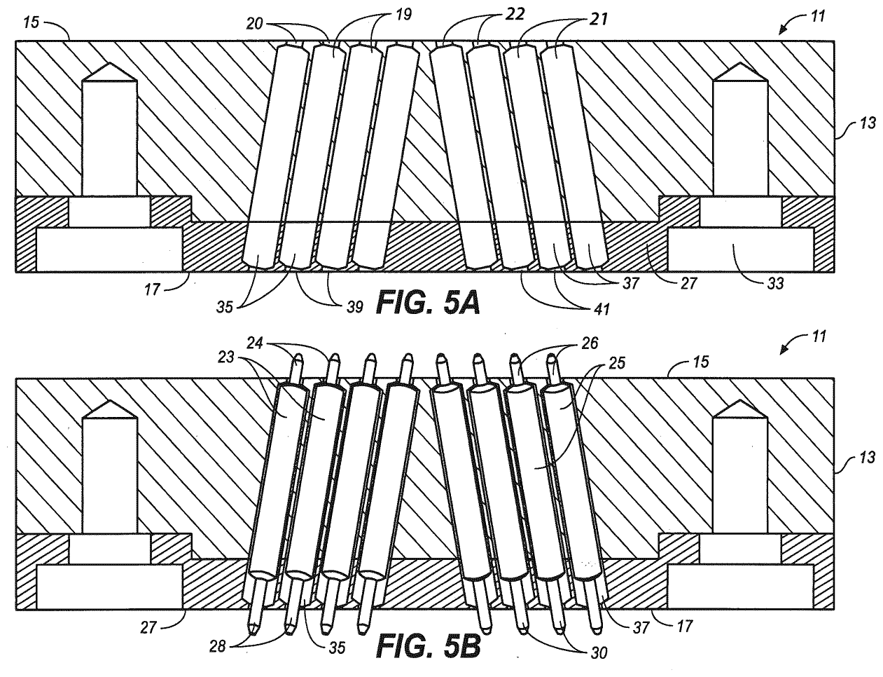

The detail of the installation of the contact pins is illustrated in FIG. 5A, where two sets of angled spring probe retention cavities 19, 21 machined into the upper block 13 extend through the interface wall 15 and terminate at the contactor's top face, in this example, in two arrays of small diameter pin openings 20 and 22. The arrays of pin openings 20, 22 are designed and located so as to match the footprint of the contact pads/solder balls for particular integrated circuit (IC) devices for testing of which the contactor assembly will be used.

As illustrated in FIG. 5B, two sets of single-ended spring probes 23, 25 having non-depressible probe tips 24, 26 and depressible spring-loaded probe tips 28, 30 are loaded into the angled spring probe retention cavities 19, 21 from the bottom-face side of the contactor assembly. As seen in FIG. 5B, when the spring probes 23, 25 are fully inserted into the probe retention cavities 19 and 21, their probe tips 24, 26 extend through and emerge from the array of openings 20, 22 on the contactor's top face. Due to the angulation of the spring probes, these probe tips project beyond the top face of the contactor at an angle, which may be different for each set of spring probes. Preferably, the angles of projection for the first set of spring probe tips 24 in reference to the z axis, normal to the surface of the contactor, will be equal and opposite to the angle of the set of spring tips 26 about the z-axis. By providing separate arrays of spring probes having an equal number of probes in each array, and angled in opposing directions, the lateral forces exerted on the IC chip by the probe tips will be substantially balanced in the x-y plane in which the surface of the contactor 15 lies. In this way, excessive force applied to the device under test may be mitigated, at least to the extent possible, which contributes to minimal risk of damage to a device under test.

The spring probes 23, 25 in the arrays are held into the contactor assembly by means of a retainer or bottom plate or lower block 27. A recess 29 shown in FIG. 1 may be provided in the bottom face of the contactor assembly for receiving and locating this lower block 27. The lower block 27 can be held to the contactor assembly by means of suitable retaining screws inserted through counter-sunk screw openings, 33 at FIG. 5A, in the lower block 27 and threaded into screw holes in the contactor assembly.

It can be seen that the two sets of spring probe retention cavities, 35, 37 at FIG. 5B, are provided in the appropriate area of the lower block 27 to accommodate the depressible end of the spring probes at the bottom face of the contactor assembly. Each of the cavities 35, 37 will be long enough to allow the spring probe barrels to move downwardly when the DUT is pressed against the probe tips 24, 26 at the top face of the contactor. Cavities 35, 37 are seen to terminate in a small pin opening 39, 41, as shown in FIG. 5A through which the depressible probe tips 28, 30 can extend for contacting the electrical contact points of a test board. These openings are generally insulated by a post-machining chemical treatment, such as hard anodizing for an aluminum structure, but bring a frequency dependence to the operation of the contactor.

The angulation of the spring probes in the contactor assembly relative to the z axis will depend on the particular application. Displacement of the probe tips have not only motion in the z-axis, but also a component of motion in the x-y plane as well. The length of the swipe of the spring tips 24, 26 of the spring probes across the contact pads or solder balls of an IC device can be designed by the choice of the spring probe angulation and the movement length of the depressible spring tips 28, 30 Generally, it is contemplated that the angulation relative to the z axis are in a range of 2 to 25 degrees, with a preferred angulation in the range of 10 to 20 degrees.

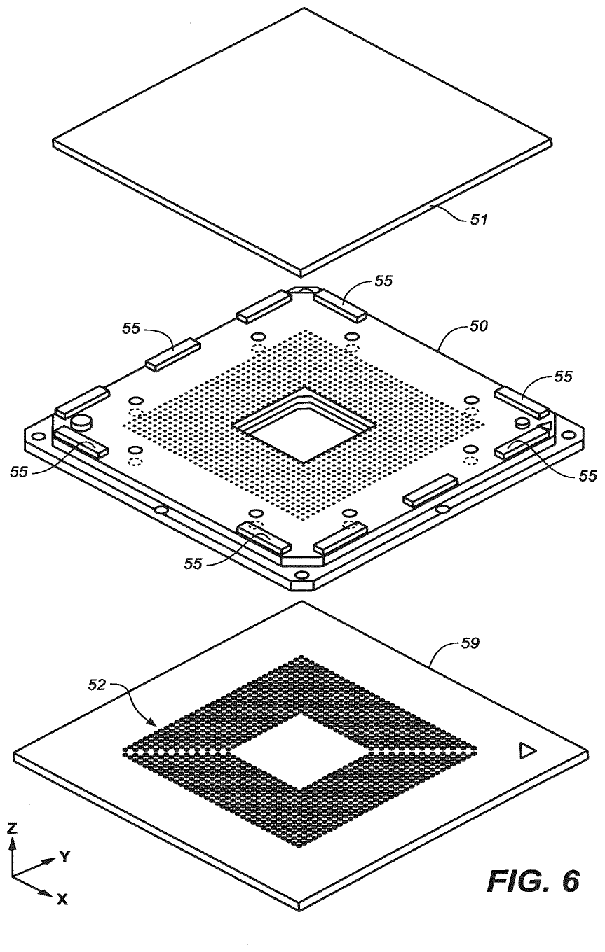

The contactor assembly 11 is suitably held to a test board, 59 in FIG. 6, through which test equipment can be connected, by means of mounting screws inserted through mounting holes 43 of FIG. 1 located in suitable positions on the contactor assembly 11. The contactor assembly 11 is further suitably provided with alignment pin holes 45 for achieving a precise alignment of the contactor assembly 11 on the test board. Suitable alignment means can also be provided between the contactor upper block 13 and lower block 27, such as providing a key structure or alignment pin holes in the contactor upper block 13 and lower block 27 (such as using alignment pins in alignment holes 47 at FIG. 4 in the lower block).

FIG. 6 illustrates a larger scale test arrangement with a far greater number of interconnections. The test contactor assembly 50 is constructed in much the same way as the example described above, with the fixed contact pins protruding from an array of openings in the central region of the contactor assembly. Alignment bars 55 can be machined as part of the machining process for the contactor assembly which serve to accurately position the device under test 51 so that the device connection points align with the array of test pins. The test board 59 attaches to the underside of the contactor assembly 50 and the array of connection points 52 accurately aligns with the depressible pins on the opposite ends from those which contact the device under test (DUT) 51. To avoid cluttering the diagram, the necessary alignment and securing components are not shown.

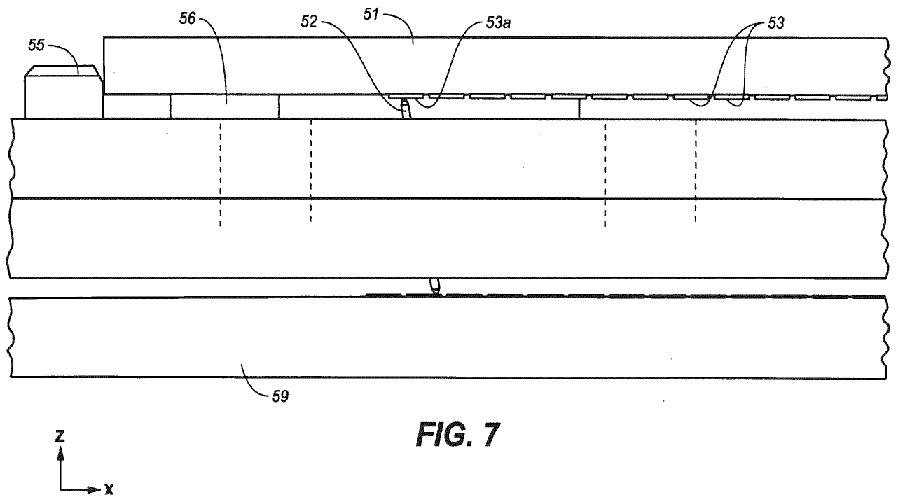

Referring now to FIG. 7, this illustrates a profile view of the connection between the elements of FIG. 6. The DUT 51 has connection points on the surface of the substrate of the device. In the case of a semiconductor or a hybrid of semiconductor mounted on a ceramic carrier these connections or contacts may be solder ball or pads 53 which are connected by a contact pin 52 at pad 53a. The DUT is aligned against the locating bars or pins 55 which can be seen in this figure to exhibit a chamfer to aid in guiding the DUT into alignment with the contactor.

A spacer 56 may be required at various locations on the assembly to ensure that the DUT does not strike the contactor assembly directly and this may be a feature of the DUT itself or else an aspect of the contactor assembly according to the DUT manufacturer's needs. The test board 59 which is used to interface between the contactor assembly and the test equipment has a contact pad architecture that aligns with the depressible contact pins and is generally much more robust than the DUT. Alignment of this element is equally important and can be done with guide pins and locators that match with features on both test board and contactor assembly.

### III. Dielectric Bushings for Signal Probe Contact Pins

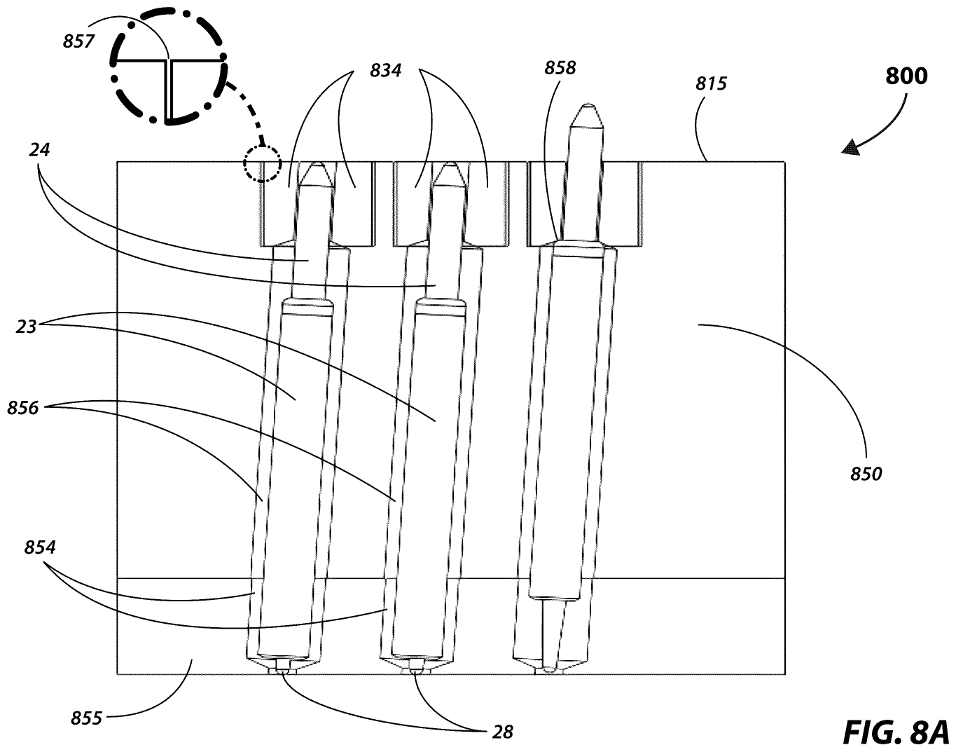

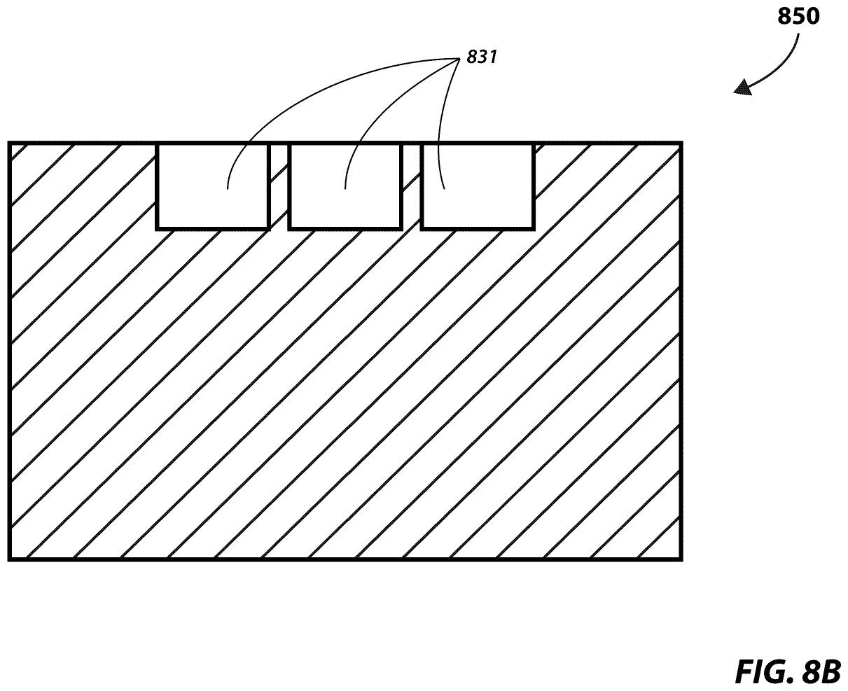

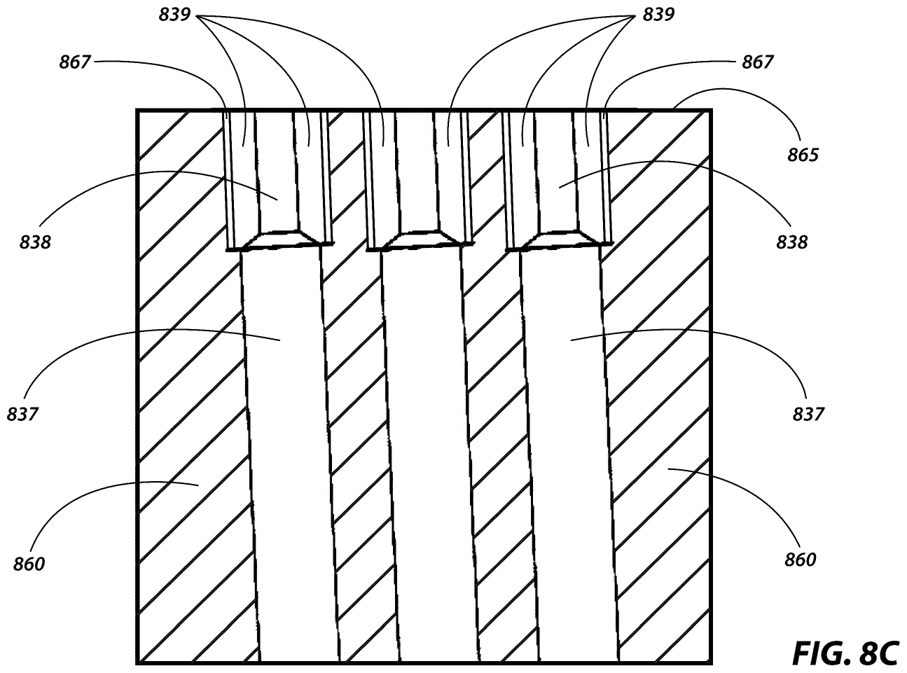

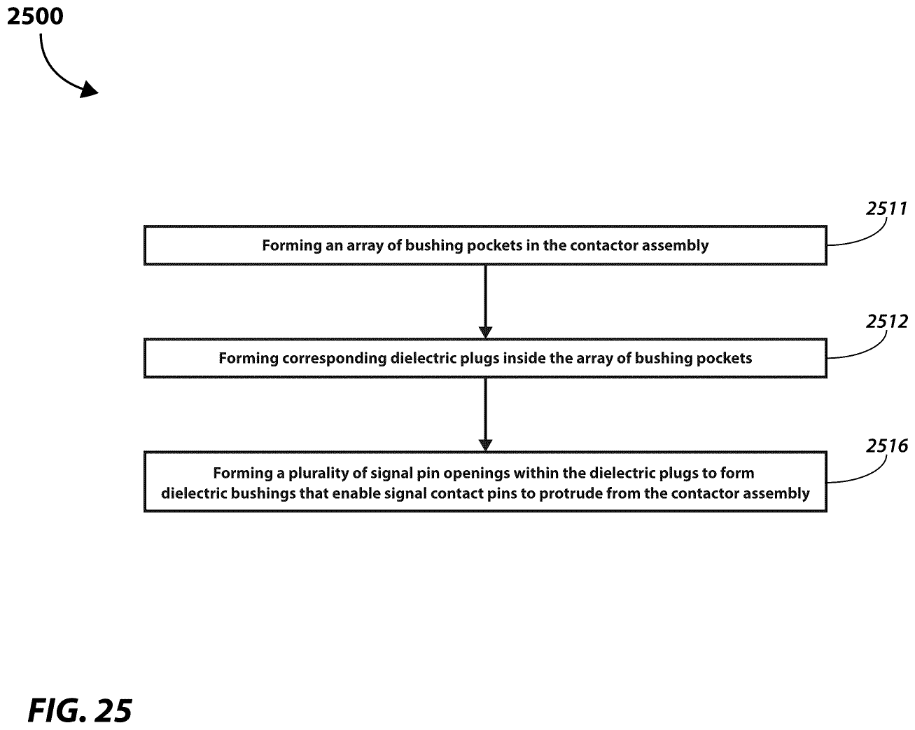

FIGS. 8A, 8B, 8C, 9A, 9B, 10, 11, 12A-12N, 13A-13J, 14-17, 18-20 and flow diagram 2500 of FIG. 25 illustrate several exemplary embodiments of test fixtures with superior dielectric properties in accordance with the present invention. Referring to step 2511 of FIG. 25, a contactor assembly is machined to form bushing pockets, e.g., pockets 831 of FIG. 8B, for accommodating non-conductive dielectric elements, e.g., plugs, (step 2512 of FIG. 25), which are eventually transformed into bushings (step 2516). Note that as discussed in greater detail below, these elements are transformed into plugs before being transformed into bushings that enable contact pins to protrude.
(a) Fabricating Dielectric Bushings

Referring to FIGS. 5A, 5B, 8A & the flow diagram 2500 of FIG. 25, FIG. 8A shows a cross-sectional view of one embodiment of an exemplary assembled contactor 800. Instead of the positioning pin openings 20 and 22 of FIG. 5A being drilled and made non-conductive using a post machining treatment, such as anodizing for example, these regions of upper clock 850 are machined to create bushing pockets (step 2511 of FIG. 25) into which non-conductive dielectric elements can be formed, which elements are eventually transformed into insulating bushings 834. The non-conductive dielectric elements can be pillars machined from a suitable dielectric material. These elements are transformed into plugs (step 2512 of FIG. 25) by inserting them into the bushing pockets before being transformed into bushings 834 with pin openings that enable contact pins to be accurately located and to protrude (step 2516 of FIG. 25) from the surface of the contactor block.

In this embodiment, the transformation from plugs into bushings include machining pin openings 20, 22 of FIG. 5A, for accepting contact pins 24 of FIG. 8A through these openings. The resulting cavity segments, i.e., pin openings, of dielectric bushings 834 interconnect with cavities 856 as shown in FIG. 8A. When contactor assembly 800 is fully fabricated, these dielectric bushings 834 are contiguous with the cavities 856 that house the probe assemblies 23 of FIG. 8A. The pin openings that accept the contact pins are co-axial with cavities 856. The diameter of dielectric bushings 834 is chosen to present a predetermined characteristic impedance resulting from the combination of the contact pin's 24 outer diameter and the outer diameter of dielectric bushing 834. A typical range of impedance for these structures lies between 30 ohms and 100 ohms, e.g., 50 ohms, for this coaxial form.

With regards to these dielectric bushings 834, shown in FIG. 8A, which also accurately align and space the contact pins 24, the dielectric constant of the bushing material selected determines the dimension of the outer diameter of the cavity segment containing the dielectric bushing 834 that surrounds these contact pins. The cavity dimension can differ somewhat from the dimensions of the main cavity 856 in FIG. 8A that contains the probe assemblies. For example, if the targeted dielectric constant is 3, the outer diameter of the bushing can be approximately 4.23 times the diameter of the contact pin 24 for a 50 ohm characteristic impedance. For the main cavity which contains the spring probe assembly this is air filled and so, for a 50 ohm impedance, the cavity diameter is about 2.3 times the diameter of the barrel of the probe assembly.

The depth to which the dielectric bushing 834 penetrates and hence the length of the bushing pocket 831 in FIG. 8B that houses the dielectric bushing is determined by the contact pin position when the device under test is mounted. When assembled, the pins 24, 28 in FIG. 8A are almost flush with surface 815 and 855 in FIGS. 8A and 8C respectively. This then sets the required distance for the probe assemblies 23 to move towards and into the lower block 855 against the spring pressure exerted by the spring that is contained within the spring probe assembly.

The lower block 855 has matching cavities 854 and the lower pins 28 of the probe assemblies 23 retract against internal spring pressure, which spring is contained within the large diameter body of the probe assembly. The lower block of the contactor assembly 800 may have the same construction as the contactor assembly shown in FIGS. 5A & 5B where the lower pin opening 39 for the retractable pin is anodized so as to provide a non-conductive passage for contact pin 28.

As discussed briefly above, the fabrication of the contactor assembly 800 of FIG. 8A includes creating pockets 831 in the upper block 850 of FIG. 8B. These pockets 831 which eventually accommodate dielectric bushings 834 are cut into the surface 815 of contactor assembly 800 shown in FIG. 8A in a way that matches the desired probe distribution. This spacing is determined by the contact arrangement on the semiconductor die to be tested and the depth is determined by the probe assemblies to be used. In general, when the probe is free, the outer body of the probe assembly in the upmost position can rest against the shoulder 858 shown in FIG. 8A of dielectric bushing 834. The typical dimensions of the dielectric bushings are in the range of 0.7 to 0.85 millimeters in outside diameter and the depth of the pockets in the range of 0.7 to 0.8 mm. To the extent that this may vary, the dimensions of the contact pins 24 have an influence. A typical contact pin has a contact tip diameter of about 0.25 mm.

The range of dielectric constants for the bushing material is typically between 2.5 and 3.5 and examples of such materials would be Vespel SP-1 from DuPont, PEEK, such as Vestakeep from Evonik Industries AG, Essen, Germany or Plavis-N from Daelim Co. Ltd., Seoul, Korea.

In this embodiment, an adhesive is used to secure the eventual bushings and FIG. 8A illustrates a small gap 857 that is needed to accommodate the adhesive. A suitable adhesive is an epoxy such as Masterbond EP21TDCHT from Master bond Inc. of Hackensack, New Jersey. Although it is possible to install individual bushing elements, this is laborious and more prone to assembly errors such as missing or ill-fitting bushings. Hence, pillars for forming bushings may be fabricated as an array, which the pillar array can then be inserted as a single piece into upper block 850.

FIG. 8C is a cross-sectional view depicting a modified embodiment of an upper block 860 similar to the contactor assembly 800 of FIG. 8A, prior to insertion of a probe assembly (not shown). Notably, the dielectric bushings 839 are slanted with respect to the surface 865 of the upper block 860. In this embodiment, the plugs (not shown) have already been transformed into bushings 839 by machining slanted pin openings 838 through the plugs. The resulting cavity segments, i.e., pin openings 838, interconnect with probe retention cavities 837. In other words, when upper block 860 is fully fabricated, these dielectric bushings 839 are contiguous and coaxial with probe retention cavities 837.

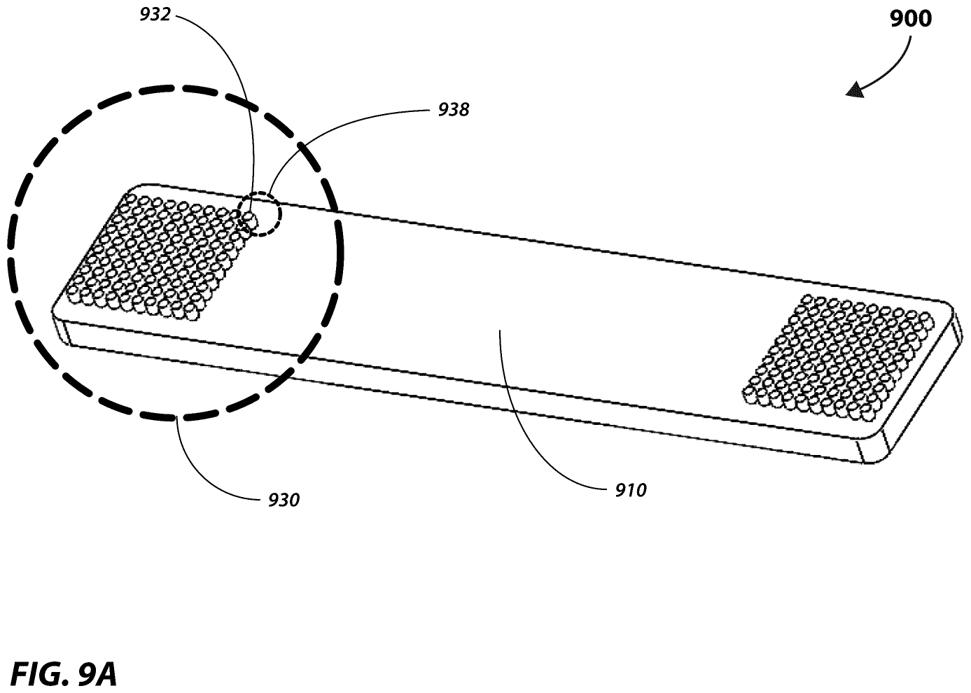

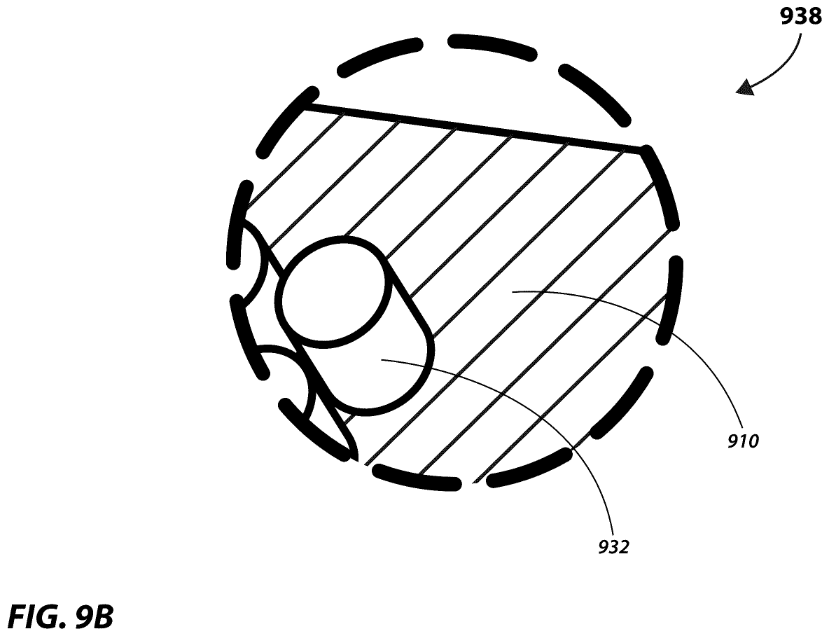

As discussed above, in this embodiment, the fabrication of the contactor upper block 860 of the contactor assembly 800 includes creating slanted pockets for accommodating dielectric bushings 839 that are cut into the surface 865 in a way that matches the desired probe distribution. An adhesive can be used to secure bushings 839 and FIG. 8C illustrates a small gap 867 that is needed to accommodate the adhesive. However, unlike upper block 850 of FIG. 8A with its vertically oriented dielectric bushings 834, pillars for forming slanted dielectric bushings 839 can be initially fabricated as an array of slanted pillars 930 as shown in FIG. 9A. This slanted pillar array can then be inserted as a single piece into the upper block 860, to eventually form slanted bushings 839 as shown in FIG. 8C.

Although fabricating this array of pillars represents a small increase in complexity of machining, the benefit is that the structure is more symmetric and frequency dependent aspects resulting from asymmetry are mostly overcome.

Referring now to FIG. 9A, a substrate of a selected non-conductive material, e.g., plastic, with suitable dielectric constant and mechanical properties is machined to create an array of small pillars 930 protruding from a base 910. The spacing and dimensions of the pillars 930 are crafted to match the required probe layout. The layout of the pillars 932 can be symmetrical or asymmetrical. For example, FIG. 9A depicts two symmetrical arrays and are only for illustrative purposes. Hence, it should be clear that the scale and number of the array(s) is determined by the intended target DUT.

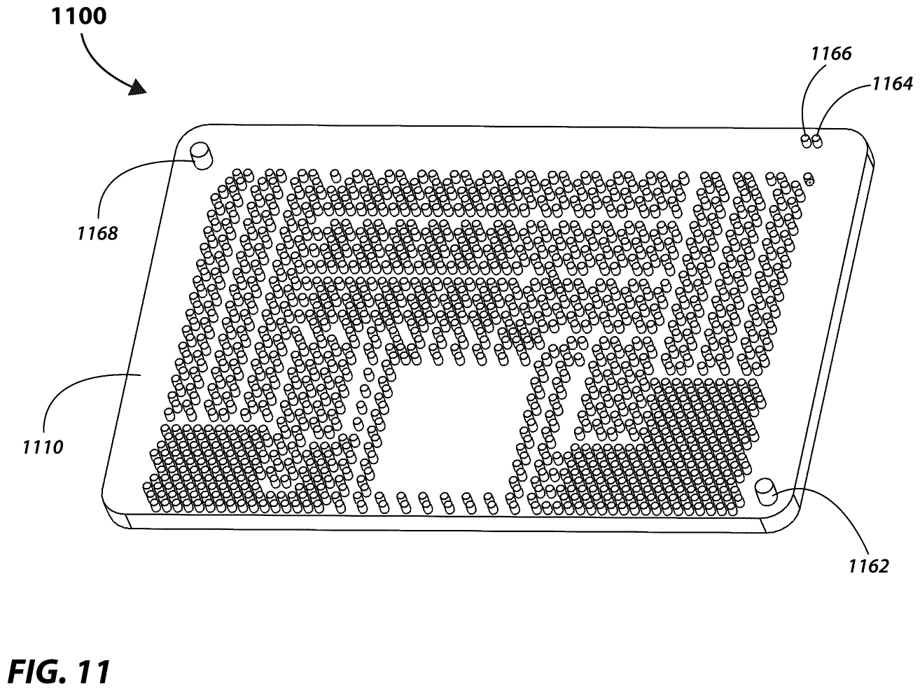

In some embodiments as illustrated by FIGS. 9A and 9B, the enlargement 938 of one pillar 932 shows a gradually tapering pillar narrower at its free end. This eases assembly considerably and reduces the chances of the pillar fouling in the upper block. Tapering of taller and larger pillars intended for alignment assistance, e.g. pillars 1168 and 1162 of FIG. 11, is particularly helpful for ensuring that the remaining shorter pillars are pre-aligned before they begin to be inserted into their respective pockets.

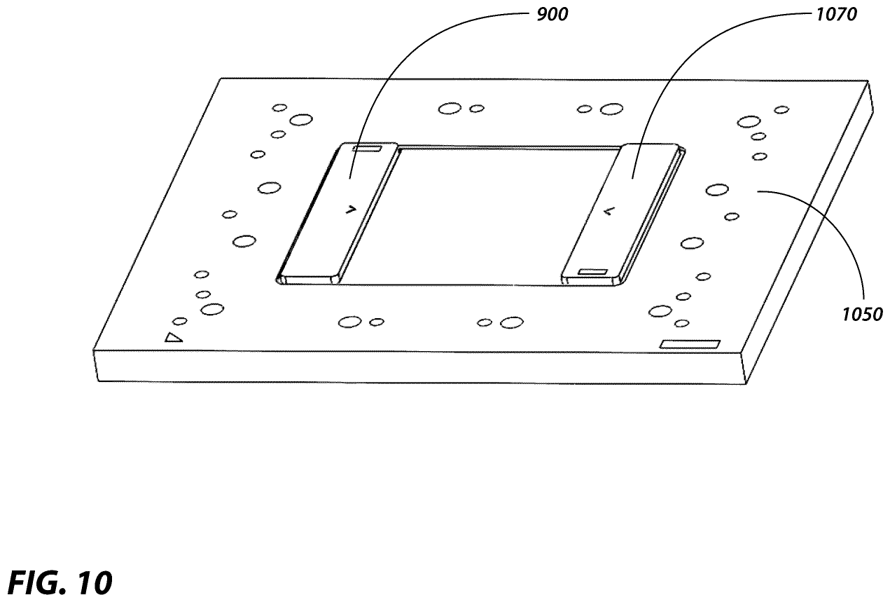

FIG. 10 is a perspective view that shows multiple structures, i.e., dielectric structures 900 and 1070, which can be separate structures or a subdivision of a single structure inserted into the machined pockets of the contactor assembly 1050, prior to finish machining of, for example, contactor surface 865 of FIG. 8C. With high probe density DUTs, the alignment difficulties are ameliorated by segmenting the complex layout within an upper block 860 of FIG. 8C to accommodate multiple substrates, each of which can be applied separately.

In addition, with respect to contactors with slanted probe assemblies, alignment pins 1162 and 1168 of FIG. 11 can also include an intentional slight angular offset to shift in the horizontal plane to eventually cause a small lateral shift as they are inserted resulting in an improved final self-centering of the pillars, e.g. pillar 932.

As discussed above, an adhesive can be introduced into each pocket prior to inserting the pillar 932 of FIG. 9B. At a later step, this pillar will be machined into the insulating bushing for securing and positioning the contact pin. A small chamfer may be used at the free end of the pillar to avoid the sharp edge that can tear against the upper block upon insertion if misaligned.

In some embodiments, a shallow trench (not shown) or serration is cut along the free end to allow air that may be trapped under the pillar to escape along with the surplus adhesive. Small shallow cuts or serrations to serve as a trench (not shown) may be machined along the vertical sides of the pillars or the pockets to allow easier displacement of the adhesive when pressure is applied to firmly seat the pillars.

Returning to FIGS. 8A, 8B & 8C, once the pillars for forming bushings 834 or 839 are secured, having been pressed firmly into an adhesive previously deposited into the exemplary pockets 831 and the adhesive allowed to cure, the machining of the upper block 850 or 860 may commence by drilling the probe retention cavity 856 or 837, respectively, into which the depressible probes, e.g., probe 23, are fitted. The inner end of the cavity 856 or 837 where it meets the bushing may be machined to a profile to compensate for the impedance discontinuity resulting from a change in dimension of the probe assembly and the inclusion of dielectric bushing 834 or 839. Note that the machining of the upper block also includes removing excess dielectric material from the exposed end of the pillars to form plugs. The plugs can then be transformed, e.g., by drilling, thereby forming bushings 834 or 839 with through holes for accepting the contact pins, as seen in FIG. 8A.

The lower retaining block 855 is machined and fitted to hold the probe assemblies captive as described in an original invention. As noted above, in a preferred implementation pockets may be machined into the lower block 855 to allow bushing in the same way as the main upper block.

FIG. 11 shows a complex array of pillars 1100 machined from a dielectric substrate 1110 and is useful for testing state-of-the-art DUTs with very high density of contacts or connections. Pillars 1166 and 1164 are examples of pillars that become bushings for contacts remote from the main connection plan of the integrated circuit as might be found in a high voltage implementation where minimum distances are respected for safety purposes. Taller, larger pillars 1168 and 1162 exemplify larger elements of the array that may be used for alignment. Alignment becomes critical for remote elements of this array since even a small angular error in alignment can compromise assembly.
(b) Alternative Methods for Fabricating Dielectric Plugs

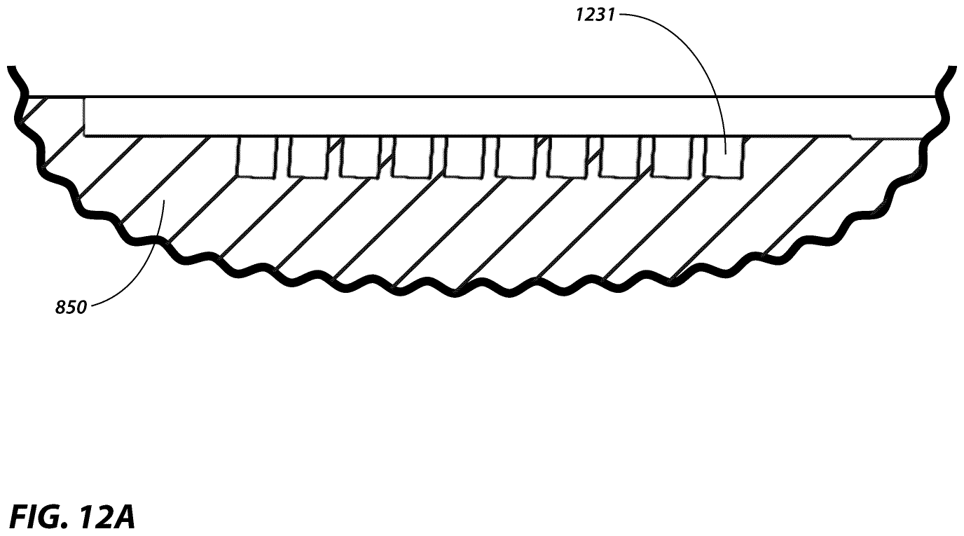

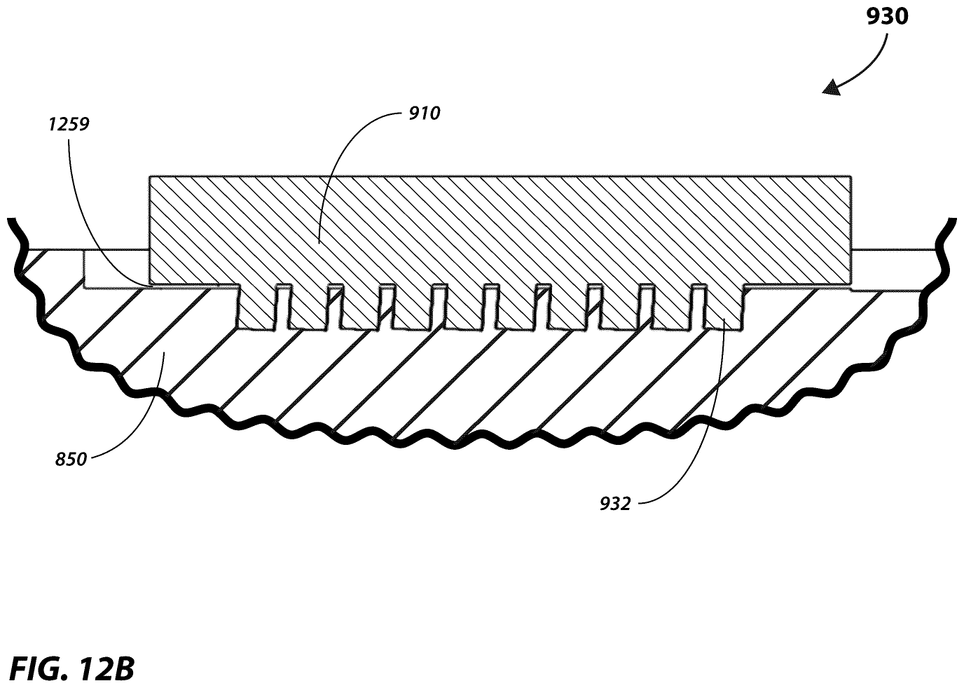

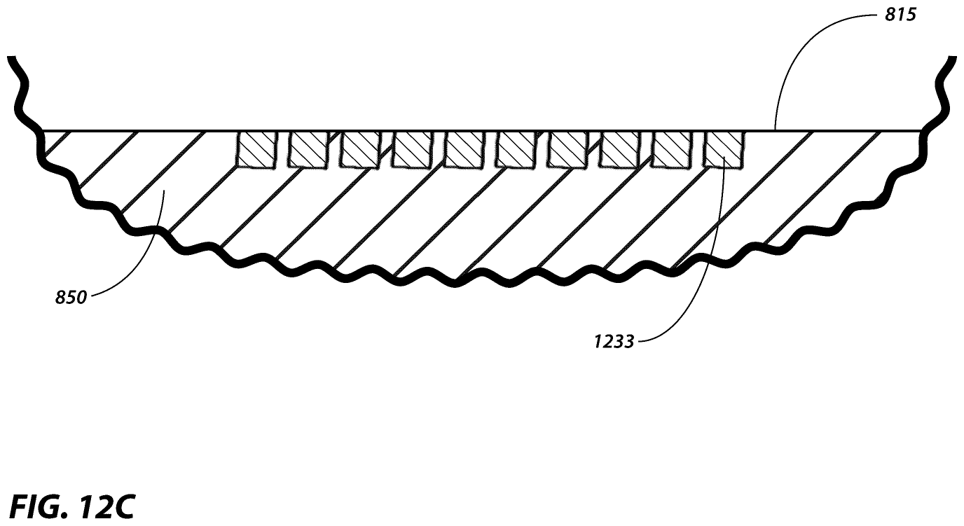

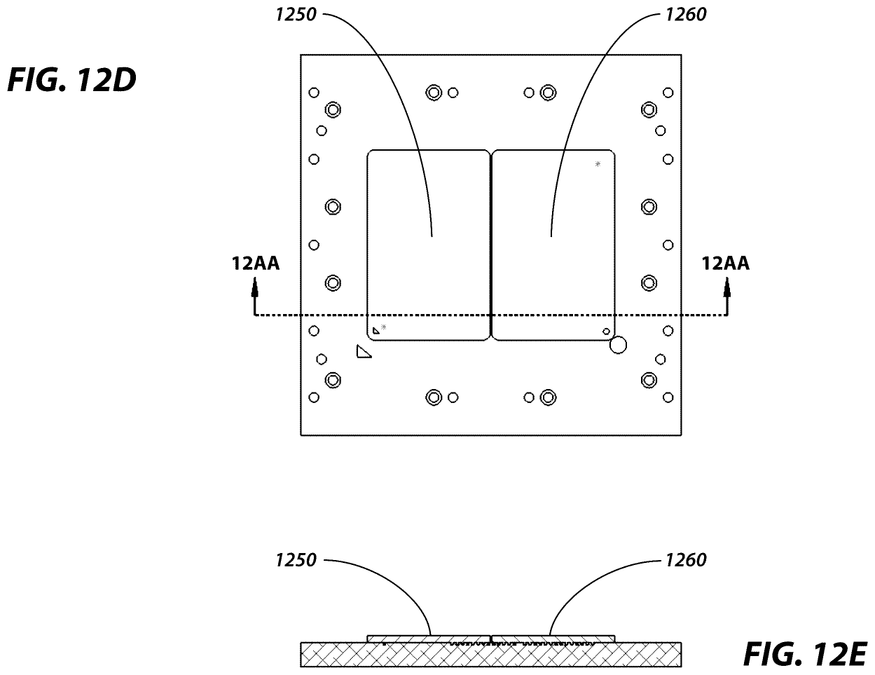

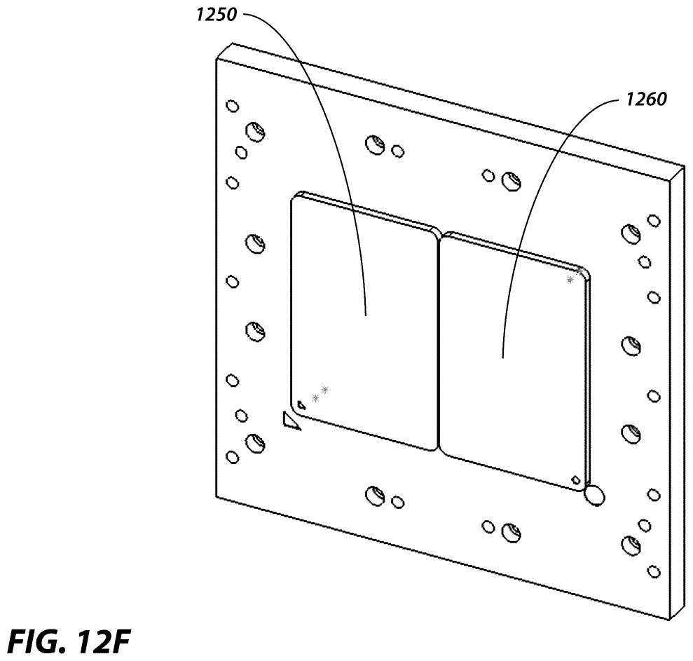

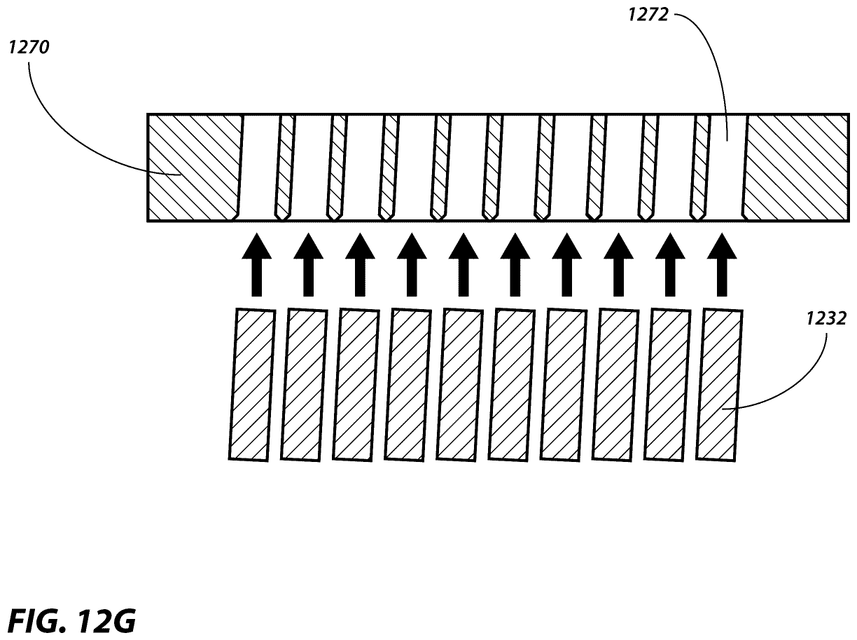

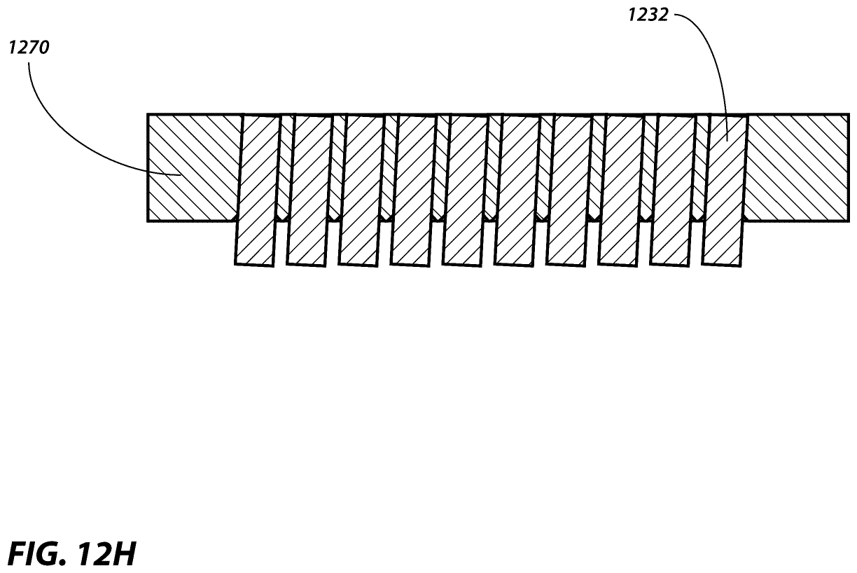

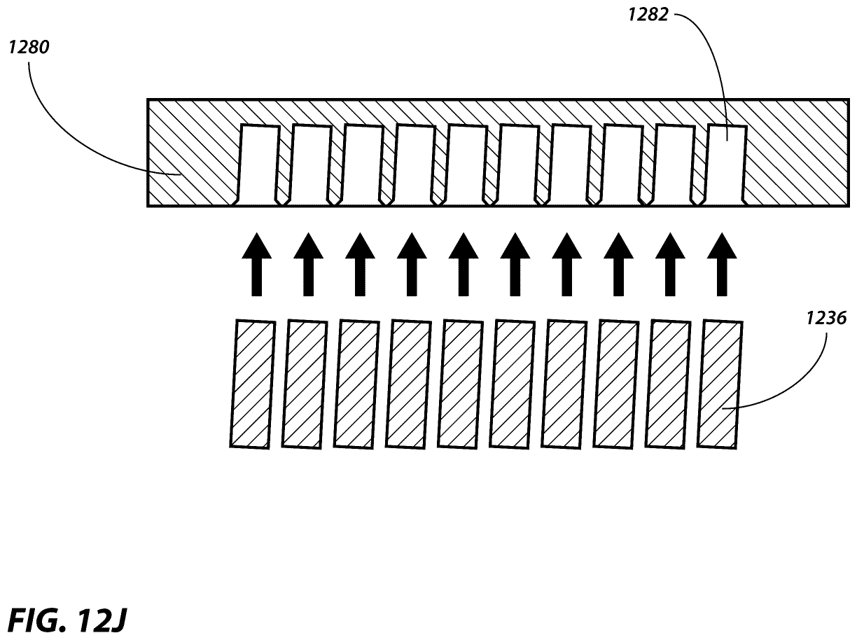

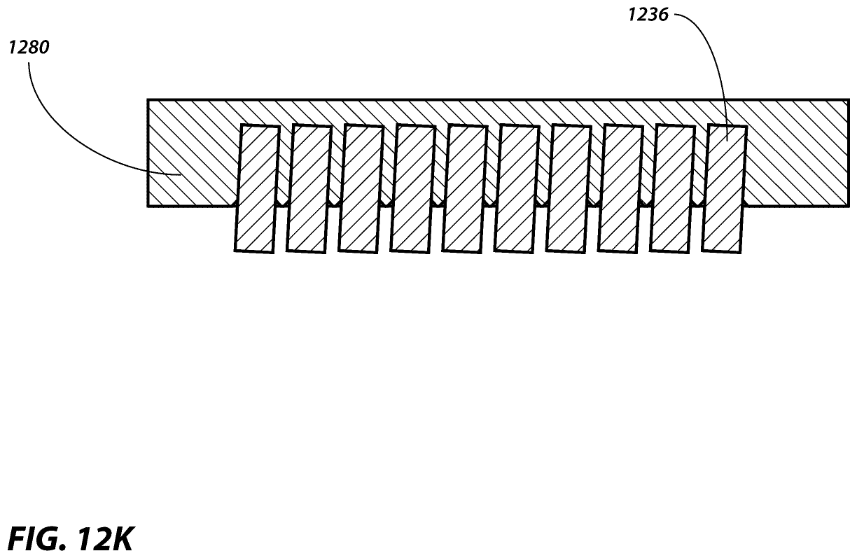

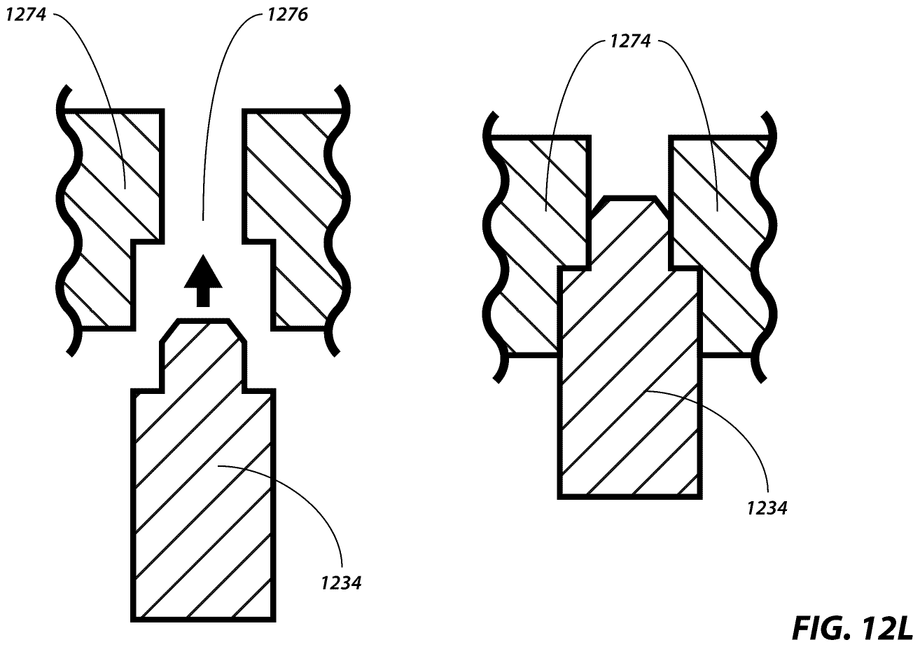

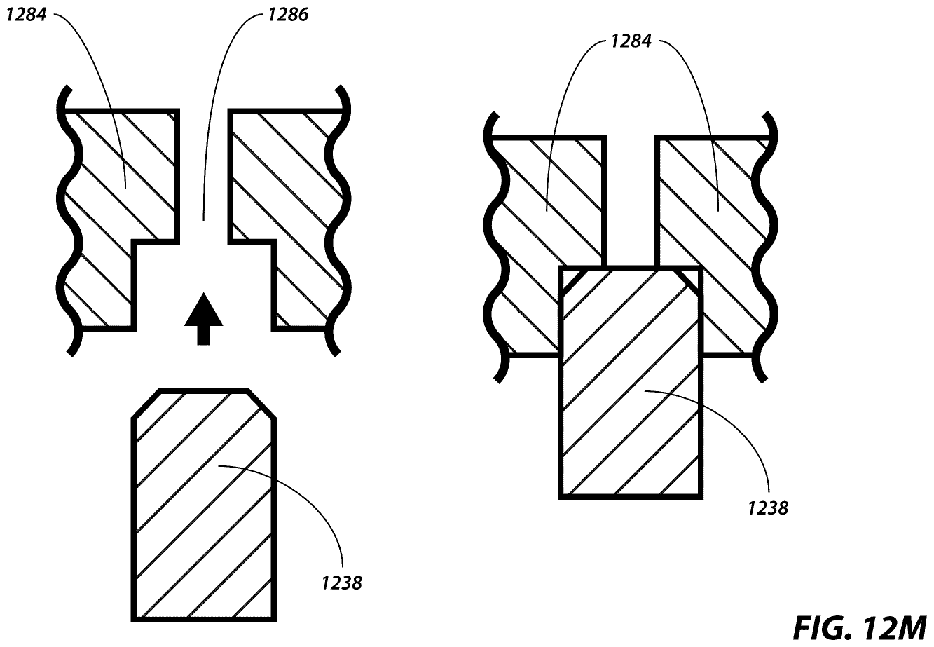

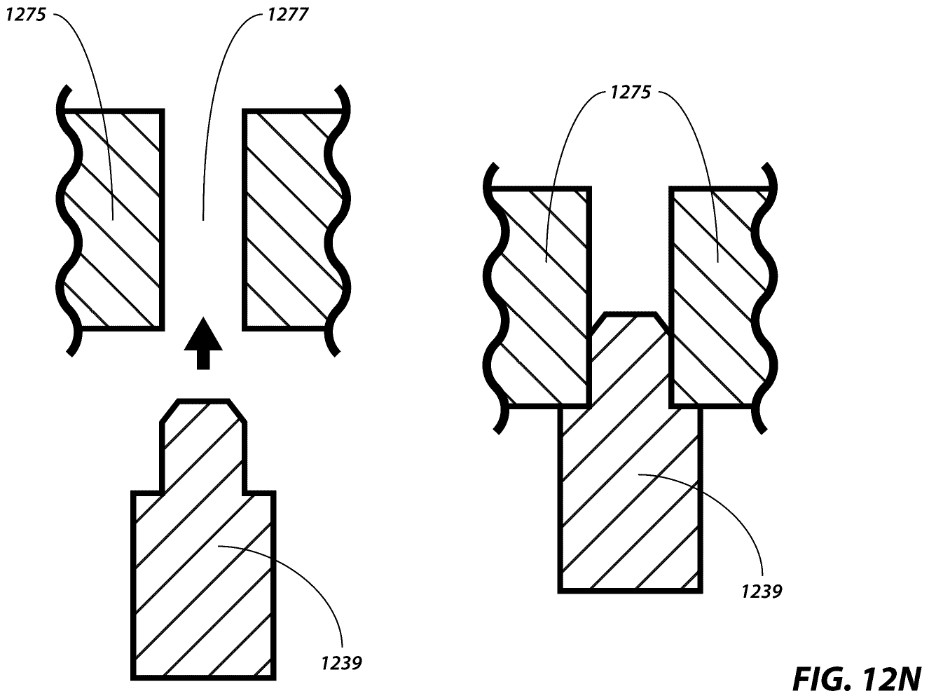

FIG. 12A shows the upper surface of the upper block 850 where the surface is machined as a step lower than the primary surface by cutting out a region into which a device under test may be accommodated. Pockets, e.g., pocket 1231, are then cut into this lower surface, positioned so as to accommodate the pillars of dielectric material in a contact layout for the intended device under test (step 2511).

Turning now to Figure. 12B, this illustrates a cross-section of how a machined base 910 with machined protruding pillars, e.g., pillar 932, is positioned into the receiving pockets that have been cut into the upper block 850 (step 2512 of FIG. 25). In this embodiment, the pockets have been cut at an angle that is the same angle that is intended for the probe assemblies to be mounted. This maximizes the homogeneity of the bushing material structure for eventually surrounding the contact pin when fully fabricated and assembled. To accommodate the small sideways displacement in the X-Y plane as the array of pillars is pressed into place, a compliant material or membrane may be used between the press tool and the substrate from which the pillars are cut.

As a result, the pillars are centered in the pockets and truly coaxial to the walls of the pockets containing the pillars, e.g., pillar 932. The adhesive used to secure the bushings may be any suitable adhesive and an epoxy material can be used chosen for its dielectric properties and proper adhesion between the respective materials of the pillars and upper block 850. Displaced adhesive can be allowed to spread into a small air gap 1259 created by choosing the pillar lengths slightly longer than the depth of the pockets, e.g., pocket 1231 of FIG. 12A

This array of pillars, e.g., pillar 932, is pressed as a single component into the upper block bushing cavities, as shown in FIG. 12B, after an adhesive has been applied and, once the adhesive securing medium has cured, the supporting substrate, along with any displaced adhesive, may be machined away as shown in FIG. 12C to reveal the upper block 850 with the individual plugs, e.g., plug 1233, firmly secured in place and flush to the surface 815 of FIG. 8A of the upper block 850, or surface 865 of block 860 of FIG. 8C.

For many purposes, the slight misalignment and resulting inhomogeneity that results from mounting the insulating bushings approximately at right angles to the top surface of the upper block 850, as seen in FIG. 8A, rather than at an angle as seen in FIG. 8C, to make this assembly truly coaxial, can cause minor changes in frequency response, but for better performance the pockets 1231 as shown in FIG. 12A can be machined to be angularly aligned with the angle chosen for the contact pins through the block.

In other embodiments described in greater detail below, it is eminently practical to use an injection molding process to fill the bushing pockets in a highly consistent way. This confers a further advantage in that features intended to compensate for high frequency difficulties may be formed in the pockets since the injection process can populate them successfully, whereas with a mechanical insertion method, negative draft angles that result from cutting features into the pockets introduces additional challenges for successful insertion of a pillar structure.

FIG. 12D shows a plan view of another embodiment of a contactor assembly that illustrates more than one machined dielectric substrate 1250 and 1260 positioned with its pillars inserted into the machined pockets in the upper block. With high pillar density, the alignment difficulties are ameliorated by segmenting the complex layout shown in FIG. 11 into two or more elements, each of which can be applied separately.

FIG. 12E shows a section view 12AA of how a divided substrate might be applied. These structures may be inserted entirely and then machined to remove the supporting upper substrate and adhesive residue in one pass, or for complex layouts each structure may be inserted and allowed to cure, then machined before the next substrate element is applied. This has the benefit that, where pillars would be close to an edge, risking misplacement or breakage, each element of a divided substrate may be produced with an extended border since it can be applied over a clean, flat surface where the prior application of an element has already had the residual material machined away.

FIG. 12F is a perspective view that shows two substrates 1250 and 1260 which may be separate structures or a subdivision of a single structure inserted into the pockets of the upper block, prior to finish machining of this surface.

In another embodiment shown in FIG. 12G that is well suited to high volume manufacture, instead of machining the pillar array from a single piece of dielectric material, the pillar structures are initially formed as rods 1232. This process is enabled by using machinery that employs screw-making technologies that permits enormous production rates to be achieved for pillar components. As an added benefit, this further allows some of the dielectric pillars to be created from different materials if required by the application and does not demand that all the pillars be identical. A retaining base 1270 is prepared with a hole pattern matching the required pillar locations for the intended test fixture. Holes, e.g. hole 1272, are cut into this base 1270 and the holes are sized to be a close fit to the dielectric rods, e.g. rod 1232, that become pillars. To ease the insertion of the rods 1232 into the base, a small chamfer to relieve nicks, burrs or sharp edges can be included as part of the drilling process, either as a separate step or as an aspect of the drill tool itself. Moreover, the base material can be a material well suited to the task of securing the pillar components rather than having to be a costly and sacrificial item that is stripped away after these dielectric pillars are finally positioned in the test apparatus upper block; for example, Delrin is a desirable material for constructing the base 1270 because of its low cost and ease of machining. The dielectric performance of the base 1270 is irrelevant since it is removed in its entirety once the rod insertion into the receiving cavities in the block 850 or 860 at FIGS. 8A and 8C is complete.

The rods, e.g. rod 1232, are loaded into the holes, e.g. hole 1272, in the prepared base 1270 as indicated by the arrows that show the direction of insertion. An adhesive may be used to ensure security of the rods that become the pillars, e.g. pillar 1232, in the base 1270.

FIG. 12H shows the assembled base and pillar structure after the rods 1232 that become the pillars are fully inserted into the base material 1270. Note that the shading of the figure indicates that the base and the rods are different materials The rods that are now pillars in the completed sub assembly have specific demands on their dielectric properties, whereas the base is required to provide sufficient mechanical strength to enable the pillars to be engaged into the upper block of the test apparatus, after which it is stripped entirely away in the subsequent machining process.

FIG. 12J is similar to the illustration in FIG. 12G except that the locating holes 1282 cut into the base 1280 penetrate part way through the base material. The assembly proceeds as described above and an adhesive can be used to secured the rods 1236 into the base as they are installed in the direction of the arrows. Relieving the open ends of these holes 1282 with a chamfer to negate the presence of nicks, burrs or sharp edges is as described above. If needed, a small hole may be drilled in the base 1280 at the floor of each pocket to relieve any pressure from trapped gas which might prevent complete insertion.

FIG. 12K shows the completed assembly of the components of FIG. 12J with the rods 1236 fully inserted into the base 1280. Although these constructions are routinely precise enough to not require further processing prior to installation of the pillars into the pockets cut in the prepared upper block of the test apparatus, an optional step would be to trim the length of some or all of the pillars if required by the design of the test apparatus.

In another embodiment as illustrated by FIG. 12L, the dielectric rods 1234 are created with a diametric step that more precisely determines the free length of the pillar, which ensures that the pillars can be accurately pressed into the pockets in the upper block and that any tendency to be pushed out of position by excess pressure is alleviated. FIG. 12L shows a cut 1276 into the substrate material 1274 which is easily achieved with a step drill having a smaller pilot hole drill with a transition to an endmill-like cutting surface cut so as to cut a slightly wider, flat-bottomed hole. The pilot hole allows the securing adhesive an easy exit.

The pilot spigot of the stepped rod or pillar 1234 is chamfered so as to ease entry into the pilot hole. The flat step shown where the transition from the pilot spigot to the desired pillar diameter is illustrative and in practice, the addition of a light chamfer to the transition abates the wear difficulties when the step cutter fails to cut a square cornered hole leaving a slight radius. Because dielectric rods 1234 can be manufactured at high speeds and large quantities using a screw-cutting type of apparatus, excellent dimensional precision is practical. This means that the repeatability across the entire array is exceptionally good and no post-assembly trimming is required. The illustration of the pillar before and after assembly does not show the adhesive film that is used to secure the two elements, and as mentioned previously the pillar may be dressed with longitudinal features to improve adhesion both in the substrate and in its subsequent insertion into a receiving bushing pocket of either an upper or a lower block.

FIG. 12M shows another embodiment where the pilot spigot is absent from dielectric rod 1238 that will form a dielectric pillar but the style of the hole 1286 cut in the substrate material 1284 is similar to that of FIG. 12L. In this illustration, the rod 1238 is shown with the chamfer sufficient to mitigate any wear effect of a corner radius appearing at the outer edges of the hole step.

FIG. 12N shows yet another embodiment wherein dielectric rod 1239 includes a diametric step, while sacrificial base 1275 has a simple through hole 1277 without any steps. In this illustration, the dielectric rod 1239 that will form a pillar is shown with the chamfer to mitigate the wear effect of a corner radius appearing at the outer edges of the hole step.

The above-described FIGS. 12G through 12N illustrate vertical, i.e., axial, cross-sectional views of rods that become pillars once they are inserted into the retaining base that are merely representative, and are intended to include various suitable profiles such as parallelograms, oblongs and trapezoids. In most embodiments, these rods and their corresponding holes have circular horizontal, i.e., radial, cross-sections and can have with square cut ends or they may have chambered ends/openings. In the base material of FIGS. 12G through 12N, holes with a square end merely requires a simple drill to be used to cut these holes into the base material. Similarly, the upper block pockets that receive the rods may be designed and machined with this in mind.

The embodiments of FIGS. 12G-12H, 12L, 12M and 12N with through holes in their respective retaining bases can be optically scanned for quality control. For example, after the pillars are formed, any missing pillars can be detected by optical scanning to identify any unintended through holes still remaining in the retaining bases that should have already been filled by inserted rod(s).

Although exemplary FIGS. 12L, 12M and 12N show a vertically aligned structure for accommodating vertical contact pins, the same technique is directly applicable to assemblies having an angulation to accommodate slanted contact pins without any conceptual change to the structure of rods 1234, 1238 or 1239, and combinations thereof.

Many modifications to the embodiments depicted in FIGS. 12G-12N are also possible. For example, it may be possible to press-fit the rods of FIGS. 12G-12N into their respective sacrificial substrates without adhesive. If the materials are compatible, ultrasonic bonding of the rods to their sacrificial substrates may also be possible. As discussed above, the pre-drilled substrates and pre-formed rods of FIGS. 12G-12N can be mixed and matched to create different pillar array configurations, thereby keeping fabrication costs down as since DUT contact separation are generally standardized. Depending on the desired pillar array configurations, it may be more cost-effective to fabricate over-populated pillar arrays with extra pillars in batches, and then machine away or drill out the extra pillars thereby removing unwanted pillars.
(c) Forming Dielectric Plugs using Injection Molding

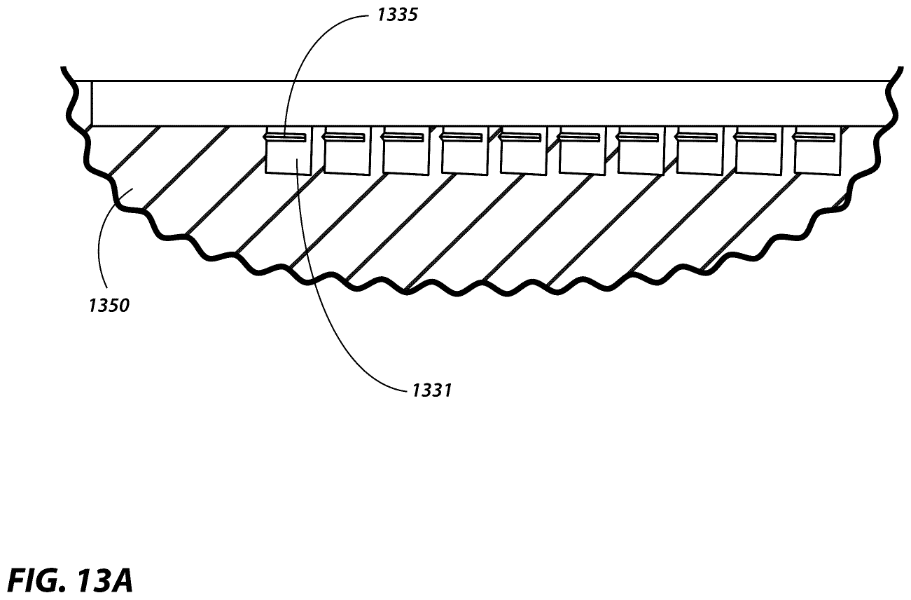

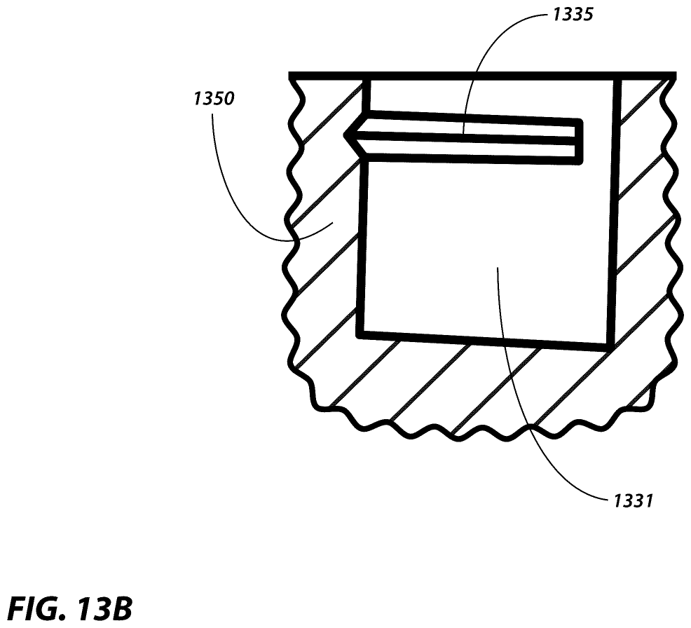

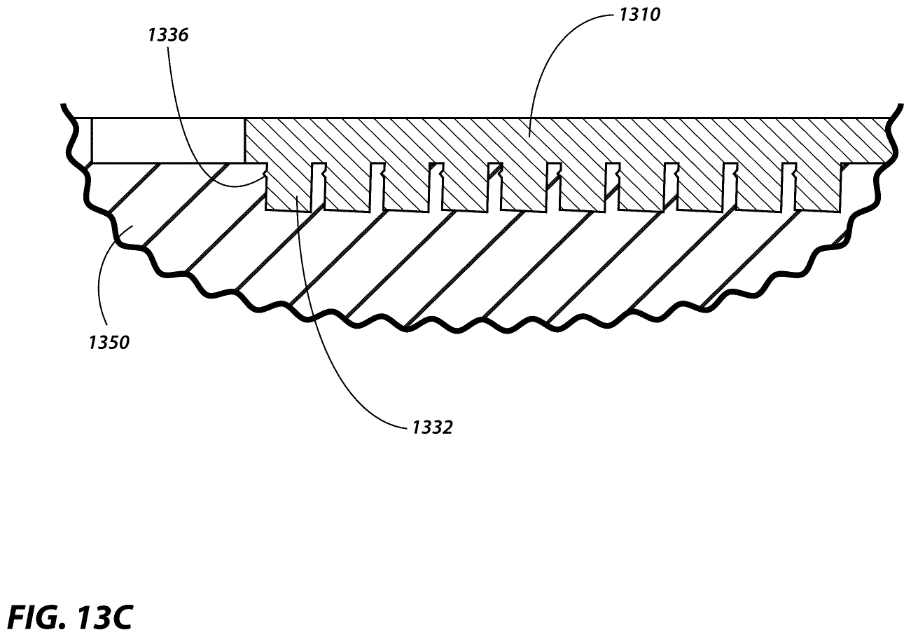

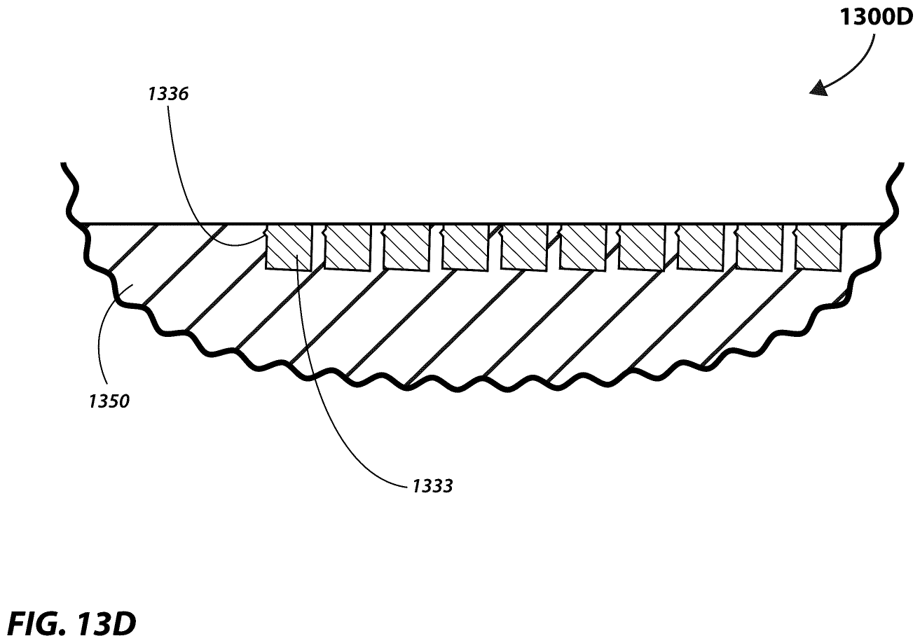

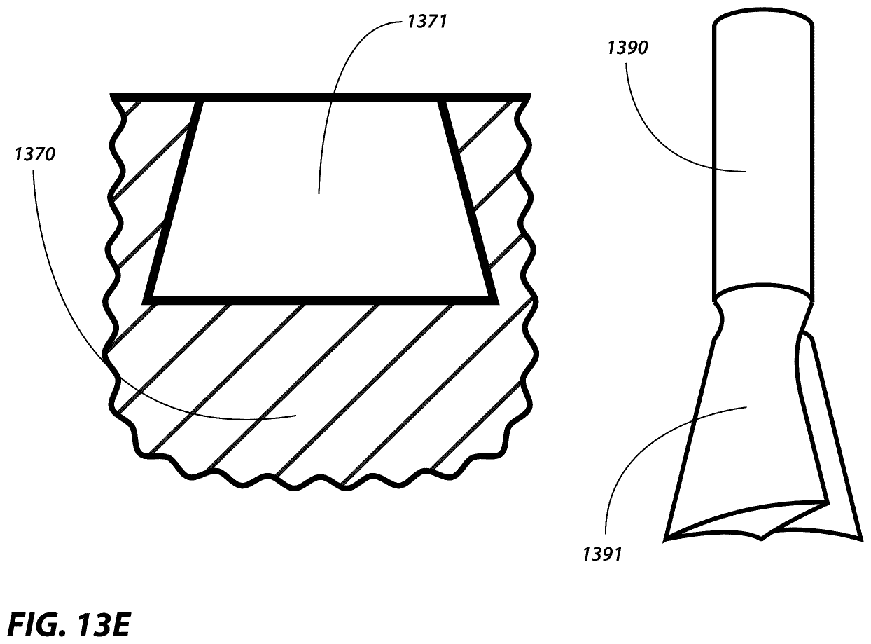

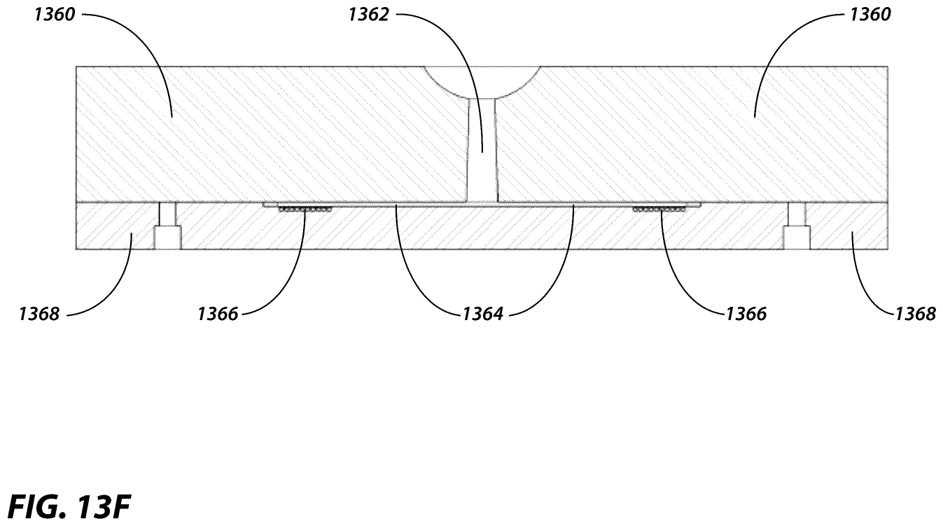

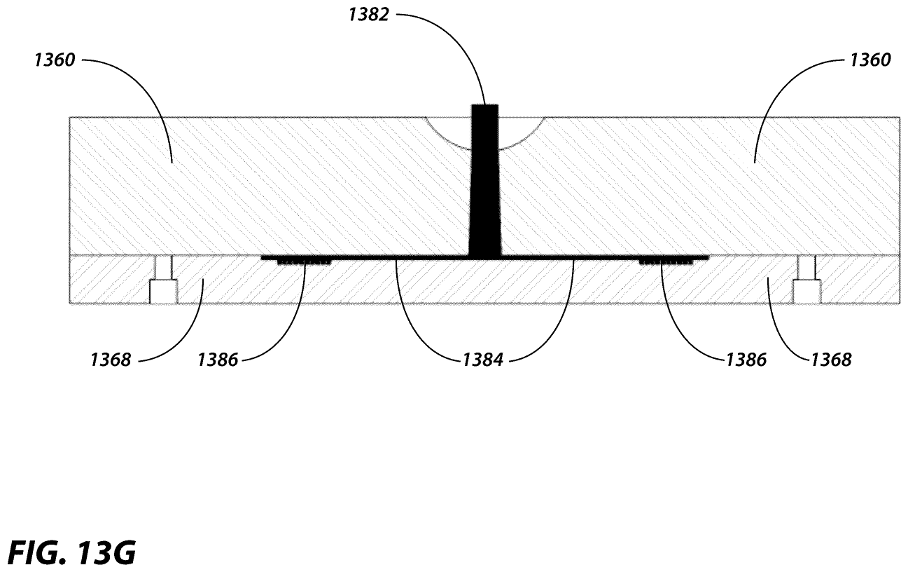

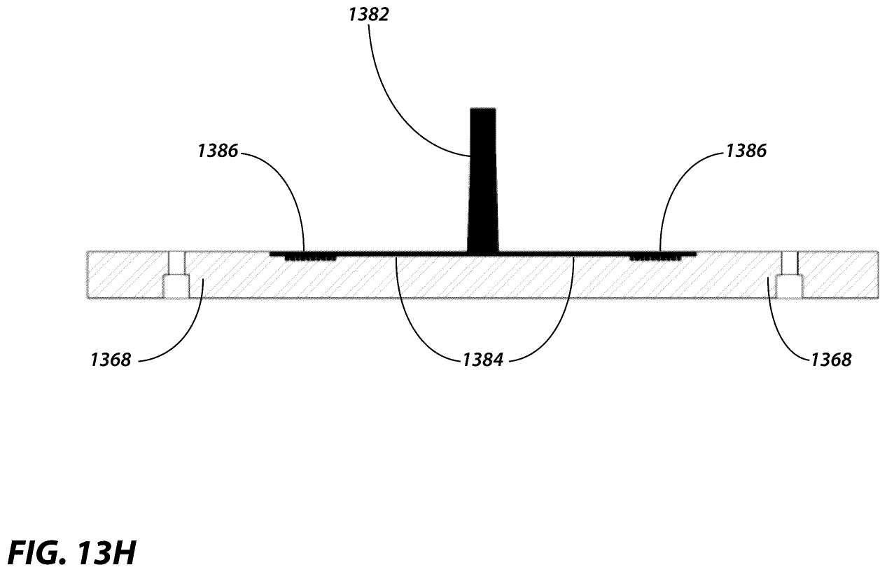

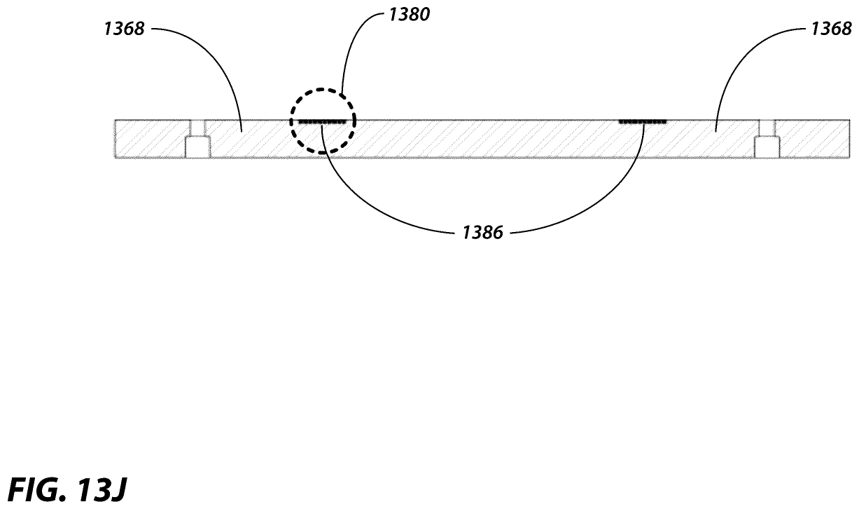

Turning now to FIGS. 13A-13D and 13F-13J, an exemplary injection molding process is described. As shown in FIG. 13A, pockets 1331, to accept plugs for forming bushings (transformed bushings are not shown), may be machined into the upper block 1350 as described previously. However, in order to ensure that the plugs are securely retained, instead of using an adhesive a small feature, e.g., valley 1335, may be machined into the wall of each pocket 1331. This valley need not be extensive and serves to retain the plugs securely and can be thought of as a key that locks the plug in its place; in the vocabulary of injection molding, this locking action is achieved by the provision of a negative draft angle that prevents release of the molded element.

FIG. 13B shows an enlarged cross-section of a single pocket 1331 machined into the upper block 1350 of the illustration of FIG. 13A for clarity. More than one feature may be machined in each pocket for this purpose and a method of over-molding suitable for use with some plastic materials used for creating the plugs.

FIG. 13C shows a section through a molded part where the dielectric plastic material 1310 fills the pockets 1331 with protrusions 1332 secured or locked in place by the ridge 1336 that is formed when the plastic material fills the valley 1335 cut into the pocket. Typically, an upper mold plate 1360 of FIG. 13F is clamped to the surface of the prepared block 1368 that is to be bushed. The mold plate has an entry chimney 1362 machined into it through which the plastic dielectric material will be forced. Plastic dielectric material is then injected under high pressure and temperature and this plastic dielectric material flows to fill the space 1364 contained between the mold plate and the upper block 1368 into the pockets 1366 that were machined into the upper block. In this way, the pockets 1331 are filled with the plastic material with the key or ridge 1336 of FIG. 13C forming as the material fills the pocket. This key 1336 ensures that the bushing material is securely attached as an integral part of the upper block.

FIG. 13G shows the injected material after injection is completed, with the sprue 1382 atop the surface fill 1384 and the filled pockets 1386. The filling of the region between the mold plate 1360 and the upper block 1368 is a residual layer that covers the surface of the upper block in the depressed region where the DUT will eventually be positioned for test. This injected material is then allowed to cool.

As shown in FIG. 13H, once cool and the plastic material set, the upper mold plate 1360 is removed to expose the injected material and the residual excess material is then machined away as previously described and as illustrated by cross-sectional view 1300D of FIG. 13D, revealing the upper surface of the upper block 1368 and leaving the plugs 1333 (for forming bushings) which are now locked in place. In this example, cross-sectional view 1380 of FIG. 13J can be the same as cross-sectional view 1300D of FIG. 13D, and upper block 1368 can be the same as block 1350 of FIG. 13D. Subsequent machining can be performed on the upper block to create the cavities for the probe assemblies and holes cut into the bushings for the contact pins as described above.

The physical discontinuity or inhomogeneity caused by a ridge or depression in the metallic block that is used to retain the injected element causes a small electrical discontinuity which can result in a minor, frequency dependent impedance change. This change is usually small and if found to be troublesome may be tuned out with a suitable reactive element elsewhere in the test signal path.

In some embodiments, a compensating cut may be made at the lower edge of the fabricated bushings proximate to the cavity that is cut in the upper block to contain the probe assembly. In some embodiments the fabricated bushing has a negative draft angle that more closely matches the dimensions required to maintain the planned characteristic impedance of the connection and that tapers to match the taper dimension of the contact pin.

FIG. 13E illustrates an exemplary exaggerated cross section (not to scale) of a bushing pocket 1371 cut into the upper block 1370 having a negative draft angle so as to retain the injected material that eventually becomes the dielectric bushing. A beneficial aspect of this embodiment is that a cutting tool 1390 has a cutting surface 1391, whose major diameter is slightly smaller than the diameter of the intended pocket at the open end. A simple drilling can be made to remove the bulk of the material forming the pocket and exemplary dovetail tool 1390 with cutting surface 1391 is lowered into the existing hole and then moved orbitally to undercut the surface opening so as to form a reverse tapered hole or pocket having a negative draft angle. The cutting flute angles can be chosen so as to produce a pocket whose sides closely match the angles of the contact pin in the operating position to yield a smooth constant impedance section of transmission line so as to reduce frequency dependence of the test apparatus.
(d) Variants of Dielectric Bushings

In the various described embodiments, when signals are single ended, unbalanced and fed against ground, the resulting bushings, e.g., bushing 834 or 839 of FIGS. 8A and 8C respectively provide good broadband performance. Hence, the exemplary probe assembly 23 of FIG. 8A functions the inner conductor of a coaxial cable while the metal body of cavity 856 is the outer conductor. Choosing the dimensions of the diameters of the inner and outer conductor sets the characteristic impedance. When the probes that make the contacts between the device under test and the interconnection circuit that attaches to the test equipment penetrate a simple, close fit anodized hole, the result is to create a short length of low impedance line. At the frequencies of interest, the small phase change that this causes can be viewed as a lumped capacitive element and is fairly easily characterized. However, by using a dielectric bushing, this more closely resembles a continuous line length or phase shift and dimensional choices allow the same impedance to be present as the rest of the probe assembly, so the result is just a small phase change without the frequency dependence of the lumped capacitance effect.

Increasingly, semiconductor devices are pushing for faster and faster operation. One limit that is troublesome is that unbalanced operation, that of a single conductor against a ground, leads to distortion which is often due to shared ground paths. To a significant degree, this difficulty may be ameliorated by using a balanced transmission or signal delivery scheme where “push-pull” operation isolates the signal path from the ground connection and this is increasingly used by the integrated circuit device manufacturers.

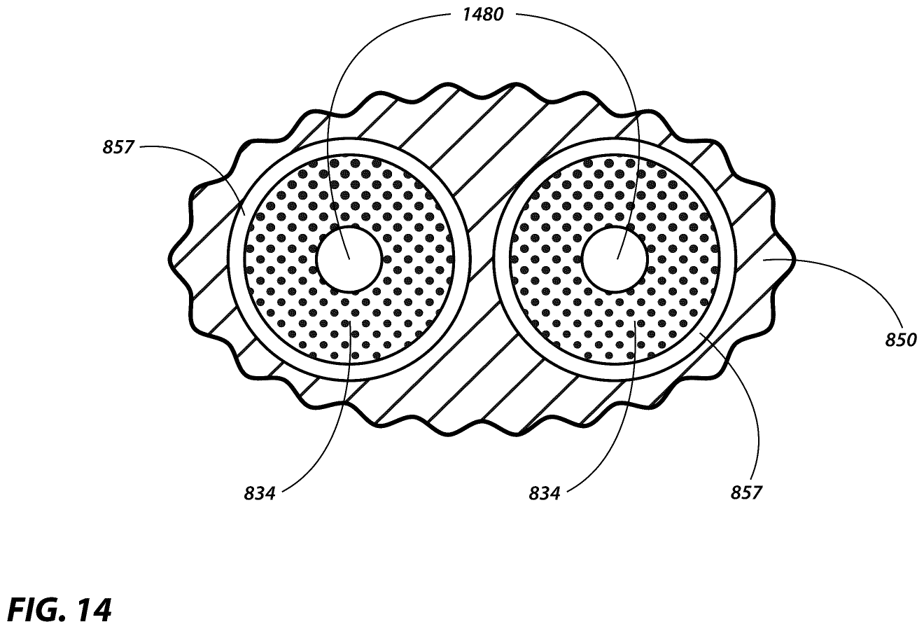

FIGS. 14 through 17 show horizontal, i.e., radial, cross-sectional views of bushings and pockets that are merely representative, and are intended to include suitable curved profiles, for example, round shapes such as circles or elongated curved shapes such as ovals. These dielectric bushings and/or pockets may have square cut ends or may be chamfered. In FIG. 14, two adjacent bushings 834 are inserted into the upper block 850. The small gap 857 between the bushing pocket and the dielectric bushing is shown for emphasis in the case where an adhesive bond is used and this gap is usually completely filled by the adhesive so that no gap remains. This gap is not present when an injection molding approach is taken. The pin openings 1480 are drilled into plugs to transform them into bushings 834 to allow the contact pins to pass through unimpeded.

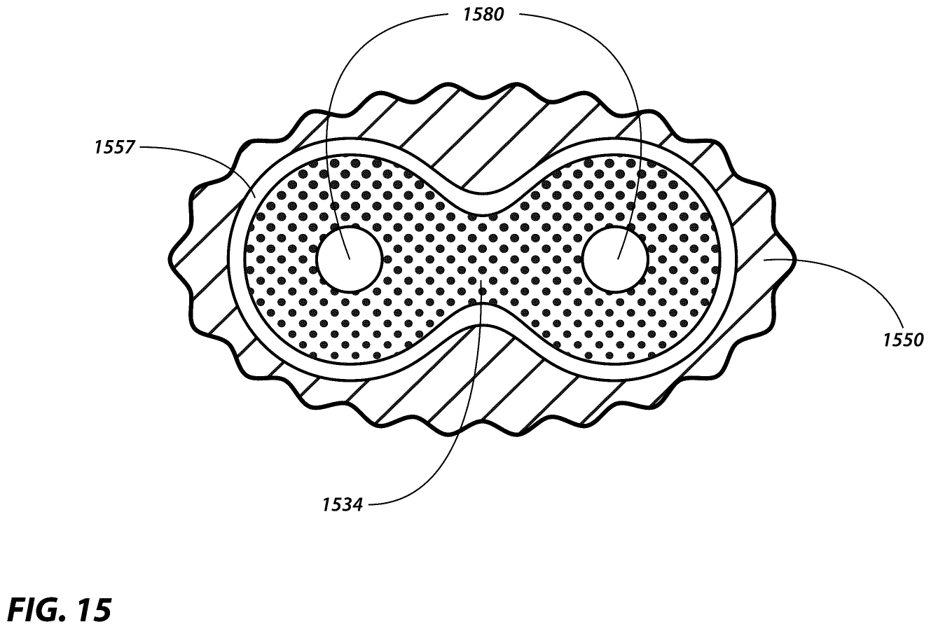

When a well-balanced signal path is desired, the bushing(s) may be constructed as in FIG. 15 so as to resemble the shape of an hour-glass or figure “8” so that pin openings 1580 of each bushing 1534 accommodates two adjacent pins whose relative placement can be held reliably at a constant predetermined spacing. The upper block 1550 is machined as before except that the conductive metal material between the two adjacent probe retention cavities that will house the probes that form the transmission line is also partially or completely removed so as to match the impedance created by the shape of the bushing 1534. The air gap 1557 is filled with adhesive when the bushings are created in accordance with FIG. 9 and, of course, the use of injection molding techniques is equally applicable to this kind of structure. An interlocking feature, similar to the valley feature 1335, of FIG. 13A and 13B, may be machined in upper block 1550 or as better suited to any particular design choice.

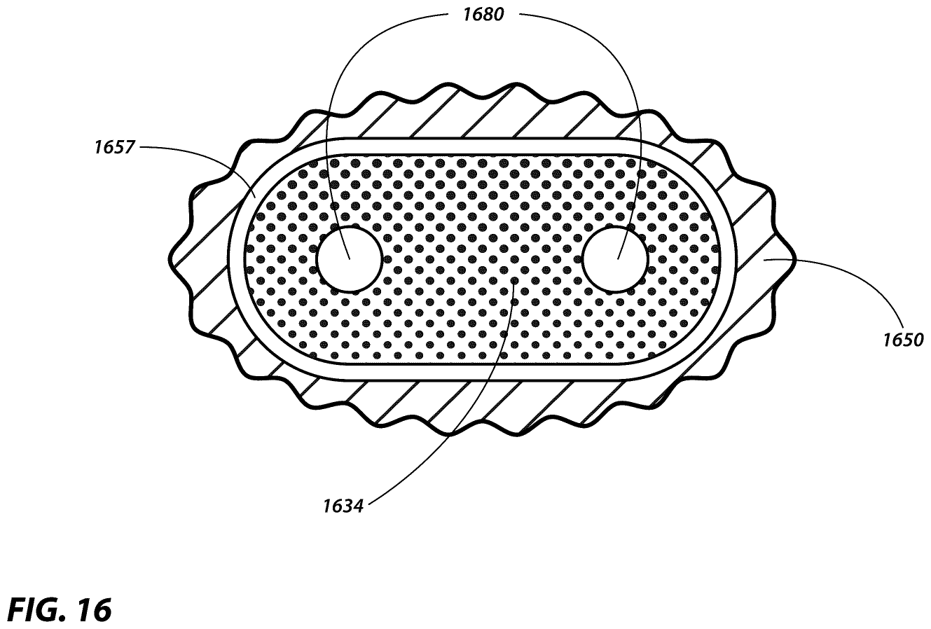

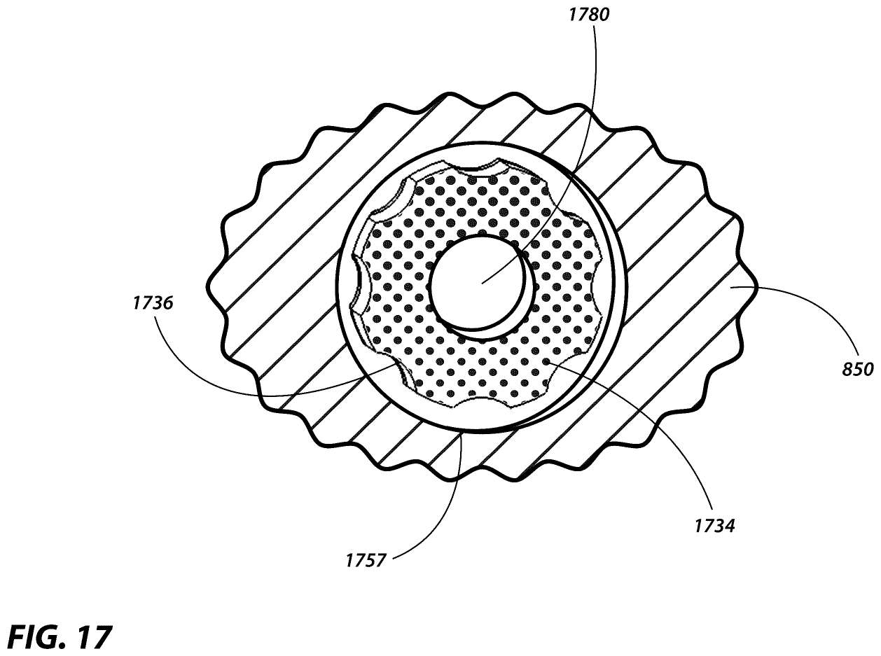

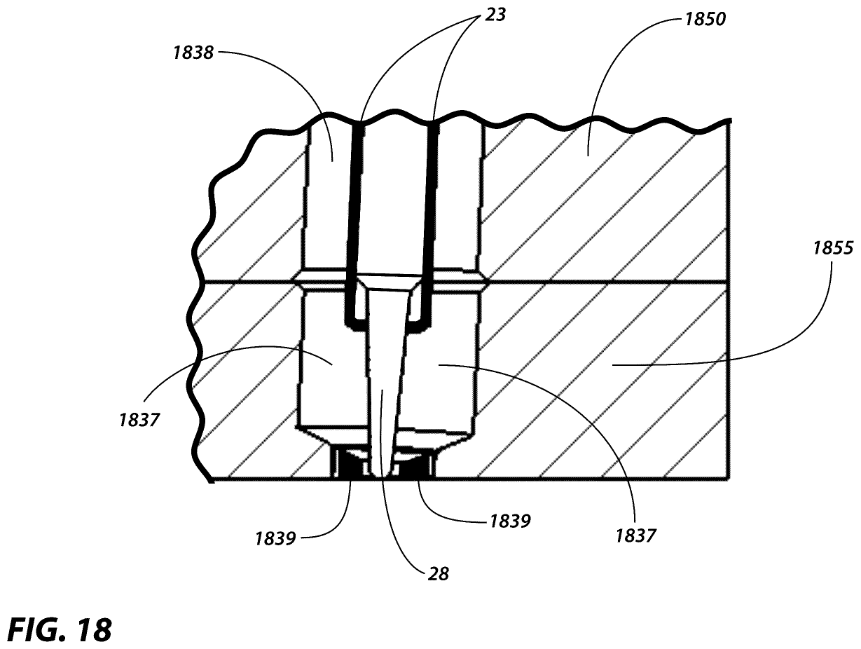

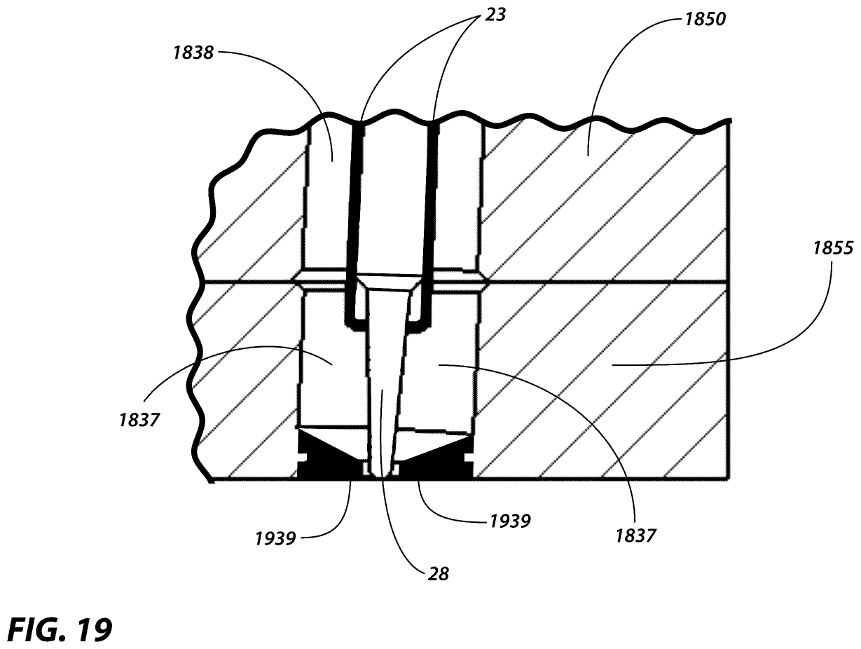

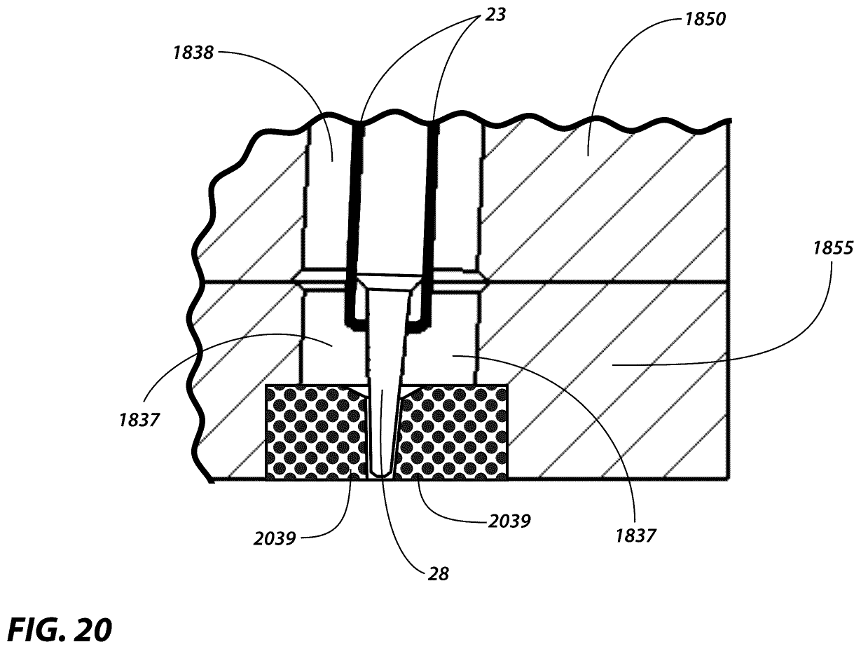

In a balanced feed, the prevailing electric field is between the two conductors and less dependent on adjacent shielding and this structure is capable of providing higher impedance transmission lines than the customary coaxial structures that have prevailed in past designs. This may be achieved using exactly the same machining techniques already described and illustrated in FIG. 9A and results in a more desirable transmission path. In essence, two adjacent dielectric bushings are simply machined as one part without the intricacy of having to separate them and may further take the shape of an elongated dual dielectric bushing 1634 as shown in FIG. 16. The same techniques are applied to the air gap 1657 between the dielectric bushing 1634 and the upper block 1650 when an adhesive is used and the positioning holes 1680 drilled in the same way as described above.

It is contemplated that bushings, as exemplified by dielectric bushings 1534 and 1634, may also assume other shapes. For example, a group of conductors of more than one isolated pair, such as a three-phase triad. With a balanced feed line structure, the probe retention cavity is similarly machined so that the conductive upper block material that forms the probe retention cavities that enclose the probes is partly or completely removed to create a transmission line structure having the same impedance as that which results from using the chosen dielectric bushing structure. Fine adjustments to this machining allow compensatory changes that can be used to optimize frequency response and this may appear as minor steps or ridges or depressions in the bore. It should be noted that in some cases it may be desirable to use dielectric materials having different properties for selected signal paths so that the impedance of the lines may be altered to better meet the test needs of certain devices under test. So when the rod structures of FIG. 12 are made, the rods do not have to be of a single dielectric material and can be chosen to suit the application.

An advantage of a balanced structure is a reduced dependance on the presence and condition of any ground structures, because the impedance of this kind of transmission line is mostly dependent on the distance between the conductors.

In an alternative embodiment, FIG. 17 illustrates a dielectric bushing 1734 having serrations 1736 machined into its periphery suitable for use when an adhesive is used to secure the dielectric bushing to the upper block 850. In some embodiments, the dielectric bushing material is a plastic material, and hence the adhesion properties between the adhesive and the plastic material can be uncertain. By machining the periphery of the dielectric bushing 1734 with these small indentations, the surface area of the dielectric bushing that is exposed to the adhesive is increased and the shear load presented can be diminished which results in improved stability, reduces manufacturing damage and increases the mechanical lifetime of the test assembly. The upper block 850 may still be machined with a circular pocket having a small air gap 1757 of the same dimension as the pillar, prior to its indenting, that can be treated with adhesive. One benefit of using serrated bushings is that any excess adhesive is more easily displaced and there is no significant electrical penalty to be paid. The contact pin opening 1780 for the contact pin to pass through the dielectric bushing is drilled into the bushing as described above.
(e) Dielectric Bushings for Lower Contactor Blocks

In some embodiments, as illustrated by FIG. 18, the lower block 1855 may be treated in the same way as the upper block 1850, where pockets are cut and non-conductive dielectric bushings 1839 are installed with the benefit of better control of the characteristic impedance of elements of the contactor assembly.

Accordingly, FIG. 18 illustrates the application of a bushing 1839 to the lower block 1855. Cavity 1838 which is cut in the upper block 1850 is extended part way into the lower block as 1837, having an air dielectric. This is because the pin should be free to move axially so that the DUT connection can be properly made. In a complete assembly, this movement into the lower block cavity 1837 is against the spring pressure that displaces the displaceable pin 28 which contacts a test board.

Using the same techniques as described for the main upper block, pockets are cut into a contactor lower block 1855. Pillars for forming dielectric bushings may be cut from a dielectric substrate or fabricated from separate components in the alternative embodiment discussed above. The protruding pillars are secured to lower block 1855 using an adhesive, which when cured is removed along with the substrate. Alternatively, dielectric bushing material may be injection molded directly into bushing pockets by using the technique shown in FIG. 13A to secure the bushing. The cavity 1837 and the contact pin opening 1780, as shown in FIG. 17, in the bushing is then machined prior to assembly. Similarly, the complex bushings shown in FIGS. 14B and 14C may be used. A machined feature that creates at least one region having a negative draft angle serves to lock in place the injected component.

The dielectric bushing 1839 of FIG. 18 is shown as being smaller than the dimensions of the cavity 1837 that houses the probe assembly. The cavity size is determined as the ratio between the outer diameter of the probe assembly outer housing 23 and the internal cavity dimension needed to create a transmission line of predetermined characteristic impedance Z₀. A similar design approach is used to create the design Z₀ for the region of the probe which lies within the non-conductive dielectric bushing. This may be chosen to either be the same as the Z₀ of the major part of the probe assembly or be chosen to have some other characteristic impedance or lumped component value so as to compensate for any undesired frequency dependent effects. It should be clear that the dielectric constant of the dielectric bushing material determines the relative sizes of the contact pin opening 1780 and its mounting pocket.

Accordingly, in yet another embodiment, FIG. 19 illustrates the application of a dielectric bushing 1939 to the lower block 1855. Cavity 1838 which is cut in the main block 1850 is extended part way into the lower block as 1837, having an air dielectric. This is to allow the probe to be free to move axially so that the DUT connection can be properly made. This movement into the lower block cavity 1837 is against the spring pressure that displaces the displaceable pin 28 which contacts a test board. In contrast to FIG. 18, the dielectric bushing 1939 is shown as being of equal or greater diameter than the air cavity 1838 and 1837 since the effects of the dielectric constant of the dielectric bushing material, coupled with the intended effect of the dielectric bushing, determines the other dimensions.

As shown in FIG. 19, dielectric bushing 1939 can be created by an injection molding method and retained by simple ridges or depressions in the lower block 1855. After injection of the desired dielectric material into pre-cut pockets in the lower block, cavity 1837 is drilled and in this figure a simple drill is used, which leaves a shaped depression in the inner part of the bushing, corresponding to the cutting angle at the drill tip. By choosing a suitable tip geometry for the drill, the resulting shape of the bushing may provide a suitable impedance transformation at the upper ranges of the intended frequency in use, compensating for discontinuities resulting from locating features in the geometry of the bushing pocket and the bushing itself.

FIG. 20 illustrates a larger dielectric bushing 2039 whose diameter exceeds that of the cavity 1837. This can be considered as a discontinuity that resembles a lumped reactive element when the thickness of the dielectric bushing is a small fraction of a wavelength at the frequency being used. If the bushing is substantial, then the hole cut to pass the contact pin 28 may be either a plain hole or else tapered so as to correspond to the probe geometry at the intended protrusion length from the base so as to ensure that the probe assembly is in a state of compression. Here the bulk of cavity 1837 can be removed using a drill, but instead of allowing the bushing to retain the entire taper resulting from the drill point cutting into the bushing, an end mill can be used to reduce this taper to a mostly flat bottom to the cavity save a small amount of taper that can be used to better guide the probe assembly into position. Cuts of this nature can be used to selectively alter the reactive effect of the dielectric bushing upon the test circuit.

The creation of the bushing secured in place, by an adhesive or an injection molded technique can be achieved using the same methods as described above, and its subsequent machining of a contact pin opening, e.g. contact pin opening 1780 of FIG. 17 for contact pin 28 is then performed.

### IV. Fabricating Protruding Ground Annuli for Ground Contact Pins

In the embodiments described herein, the structures that locates and secures depressible probes are contained within the upper and lower blocks and the spring-loaded tips of the probes protrude outside the surface of the blocks. In some embodiments, surface anodizing is used to form a hard passivating layer on the surfaces of the blocks. This creates a thin, hard insulating layer which aids in protecting the surfaces from damage, reduces the accumulation of environmental debris and helps protect against electrical leakage or short circuits.

Since the anodizing is a dielectric material, this creates a condition favorable to the establishment of an evanescent electromagnetic wave at the metal-dielectric interface and, if excited by a signal connection at one point, signal energy may be coupled elsewhere at a neighboring signal connection. In some embodiments, interfering signal energy may be far stronger than anticipated, yielding test measurements that can be markedly compromised. Attenuation of the unwanted signal power may be about 35 dB whereas it is more generally desired to approach about 60 dB.

As operating frequencies for integrated circuit devices move beyond 50 GHz, about 6 mm wavelength in air, these guided wave modes become quite troublesome and problems which are not apparent below 10 GHz begin to sharply limit performance. One manifestation of these problems occurs when the signal transitions from a coaxial structure to a connection to a device under test. Feeding such a device using a balanced feed goes some way to extending the frequency performance but, at some point, the discontinuity that is present where the coaxial feed-lines stop will excite unanticipated waveguide modes that allow signal coupling in unexpected ways. These waveguide modes can be limiting because they facilitate signal leakage that may be prejudicial to device operation. One of these is the coupling between otherwise isolated signal paths that occurs as a surface wave propagation effect.

Evanescent surface waves may not propagate easily, but a good example can be seen where a near-field effect exists within about one third of a wavelength of a radiating structure. At 50 GHz, a near-field effect corresponds to a distance of about 2 mm from the radiating structure, which approaches the interconnection separation distance common in test arrangements. It is, consequently, quite difficult to achieve the required isolation between signal channels in an integrated device.

A solid conductive elevated fence, located between signal points but not touching the DUT, may reduce the unwanted interfering signal by more than 90 dB. In practice such a fence may be prone to accumulating debris which may cause damage to the DUT if the debris allows mechanical forces to be applied to the DUT. Hence in accordance to one or more aspects of various embodiments of the present invention, the novel approach described in detail below advantageously reduces the interfering signal level to an acceptable level and significantly mitigates the risk of damage that could be caused by a solid fence.

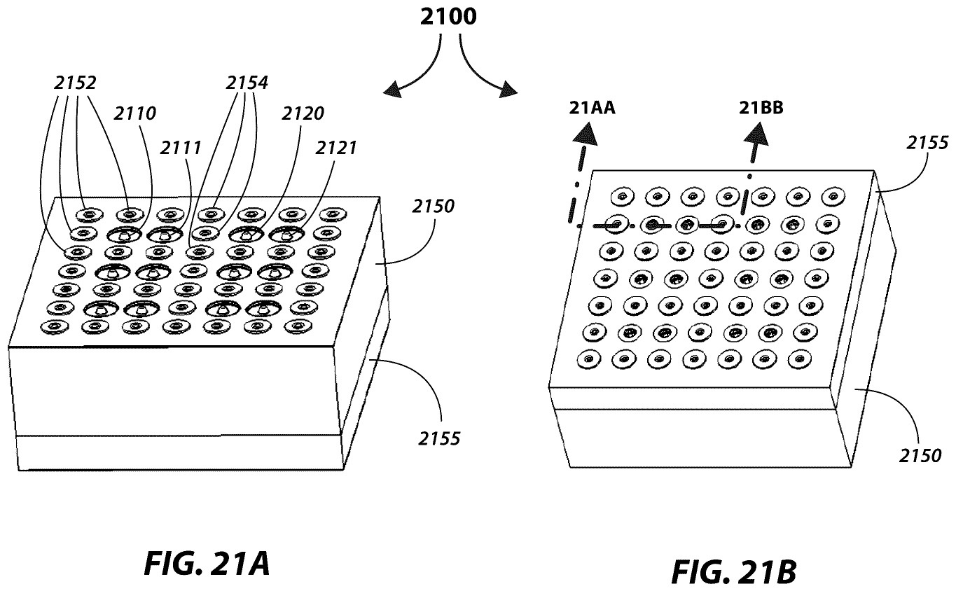

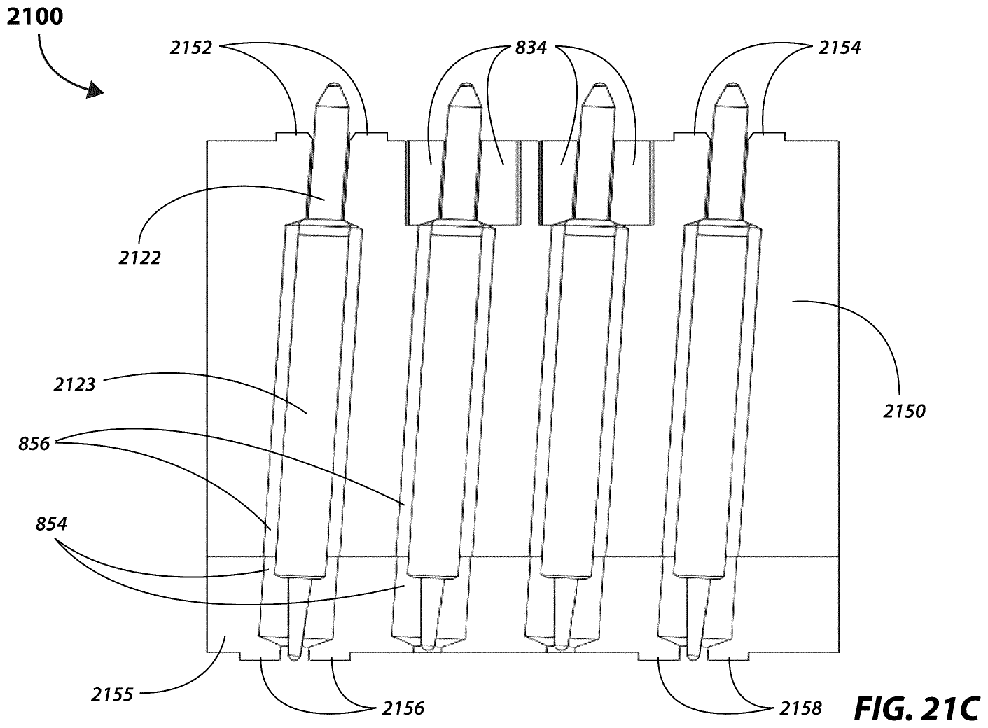

Referring to FIG. 21A and 21B, perspective view of contactor 2100 illustrates a representative example of contact pins for coupling to the DUT (not shown) surrounded by grounded washer-shaped raised annuli that collectively act as an electrical fence with low signal porosity. Note that these raised ground annuli function in combination with a corresponding plurality of depressible ground probes housed within the contactor assembly to reduce unwanted interfering signal to acceptable levels. The contact pins 2110 and 2111 are an exemplary differential signal connection pair of pins fed through a paired coaxial structure where each inner conductor is a spring-loaded pin. The inner conductors are located radially by insulated bushings set into the upper block 2150. The upper block is anodized to passivate and protect its surface. The lower block 2155 has a similar surface which is also anodized in the same way as the upper block 2150 and fits close to the surface of a test board. This lower face of the lower block 2155 and the test board are in close proximity and can be fixed in position using a fixed securing mechanism such as screws or clamps. Unlike the upper surface of the upper block 2150, there is no repeated component insertion and so the quality of the connections for the lower block 2155 against the test board is normally invariant.

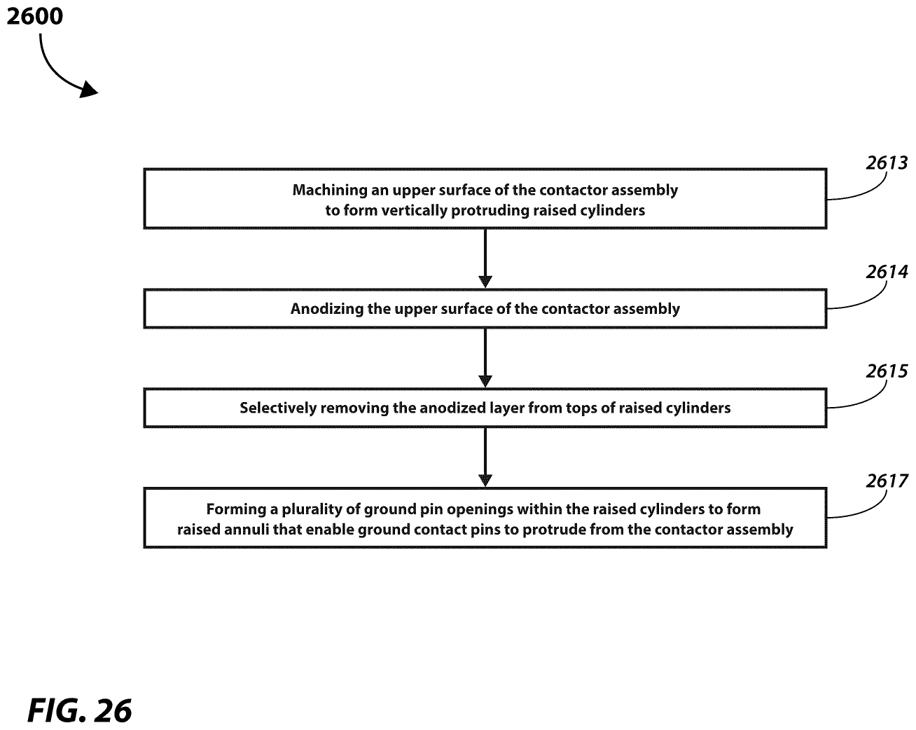

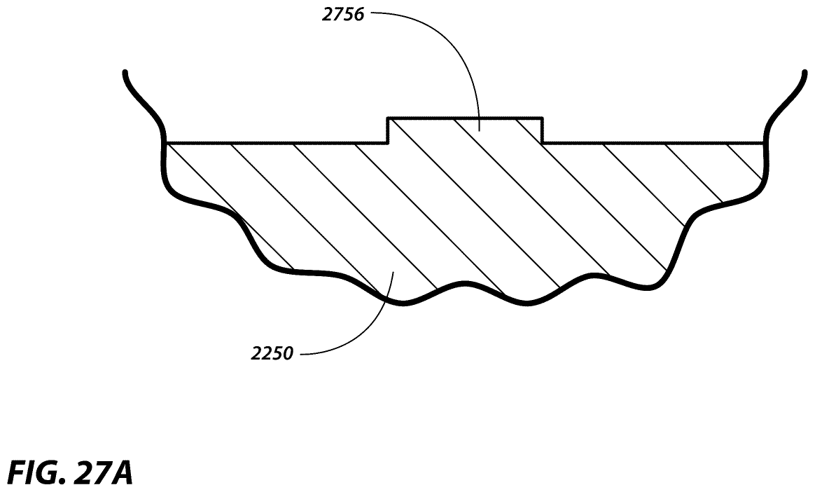

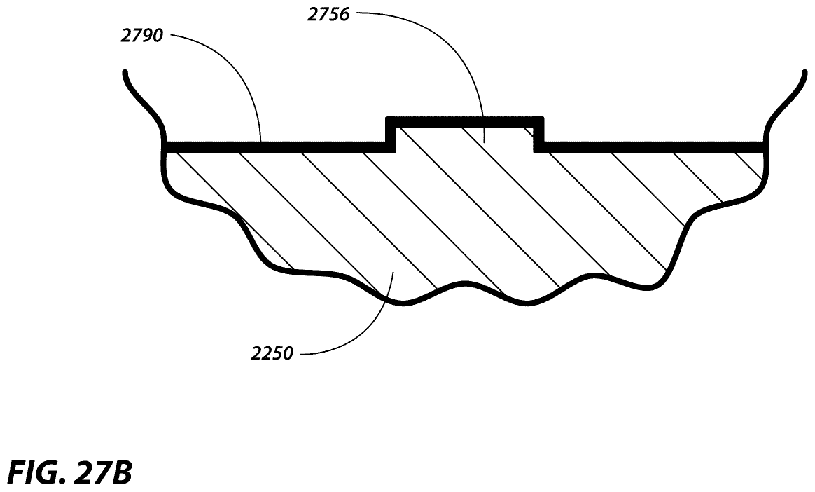

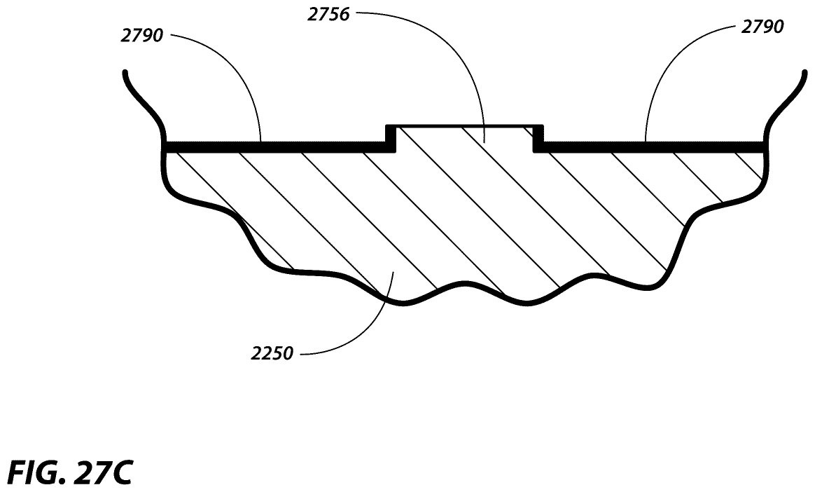

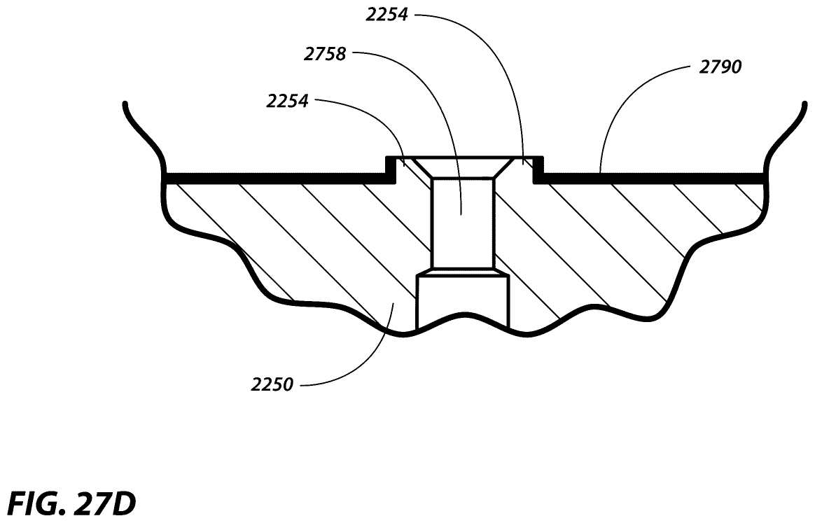

Fabrication of raised annuli is depicted by FIGS. 27A-27D and also by the flowchart 2600 of FIG. 26. The profile of the contact surfaces having the raised ground annuli, e.g., annulus 2254, as shown in FIG. 21C, are fabricated by first machining the upper surface of the upper block 2250 to form raised cylinders, e.g. cylinder 2756 (see FIG. 27A and step 2613 of FIG. 26). The upper surface of the upper contactor block 2250 can then be passivated by anodizing or some equivalent treatment to create a robust insulating layer, e.g., layer 2790 (see FIG. 27B and step 2614). Next, as shown in FIG. 27C, the passivation can be selectively removed from the surfaces of the raised cylinders, or the cylinders cleaned off using a cutting process to remove the anodizing and reveal bare metal at the raised points of these cylinders, e.g., cylinder 2756 (step 2615 of FIG. 26). Finally, as illustrated by FIG. 27D and step 2617 of FIG. 26, ground pin openings, e.g., opening 2758, are formed within each of the raised cylinders to form the raised annuli, e.g., annulus 2254. These ground pin openings enable contact pins of the ground probes to protrude from the raised annuli to make electrical contact with corresponding ground contact pads of the DUT.

Referring now to the embodiment depicted by FIG. 21A-21C, each grounded raised annulus, e.g., annuli 2152 and 2154, have a bare metal surface protruding above the flat surface of upper block 2150. A ground contact pin, e.g., pin 2122, is set concentrically within each of these annuli.

As shown in FIG. 21A and 21B, this same structure can also be featured on the lower contactor block 2155. The grid spacing of the contact pins is chosen to correspond to the spacing of the contact pads or balls of the DUT so that each connection is made by depressing a contact pin against spring pressure to guarantee a good electrical connection. This spacing and layout is determined by the layout of the DUT ball grid array or equivalent contact pads and in some embodiments may be quite irregular. Accordingly, in this example, adjacent differential signal connection pair 2120 and 2121 are separated from signal pair 2110 and 2111 by grounded pillars 2154. In the same way, individual signal contact pins can be isolated from neighboring signal contact pins.

In FIG. 21B, a section line 21AA-21BB is shown and FIG. 21C illustrates a cutaway view along this section line to aid in discussion. Contact pin 2122 can be a spring-loaded grounding pin that sits within the probe assembly 2123 as described previously above. The lower end of the probe assembly protrudes through the lower edge of the lower block 2155. When this is positioned on a test board, the lower contact pin is forced to be level with the surface of the annuli 2156 and 2158 on the lower contactor block 2155. It is acceptable for the raised ground annuli on the lower block to seat against the test board. A DUT (not shown) placed against the upper contact pin 2122 compresses the internal spring contained in the barrel of the probe assembly and the force applied to the contact ball or contact pad on the DUT is reacted through the spring against the contact point of the lower pin against the test board.

In FIG. 21C, cavities 854 and 856 in upper block 2150 and lower block 2155 respectively form the outer coaxial conductor for the coaxial structure with the barrel of the probe assembly 2123 and dimensioned so as to form a desired characteristic impedance for the coaxial structure. In the case of the ground probes, all that is required is sufficient clearance so that the probe assemblies can move freely. In some embodiments, the probe retention cavities are all cut with the same machining tool and have the same dimensions.

Pin 2122 protrudes through machined grounded raised annulus 2152 and is free moving along its length. In some embodiments, the outer diameter of ground pillar 2152 is about 0.5 mm and the vertical height is about 50 μm (approximately 0.002″). The inner diameter circumference of the ground annulus can be chamfered so that when a DUT contact ball or pad is properly positioned contact occurs just with contact pin 2122 and the ball or pad does not interfere with the raised grounded annulus 2152. This prevents the transfer of non-compliant mechanical loads to the DUT. Grounded annulus 2154 is the same as annulus 2152.

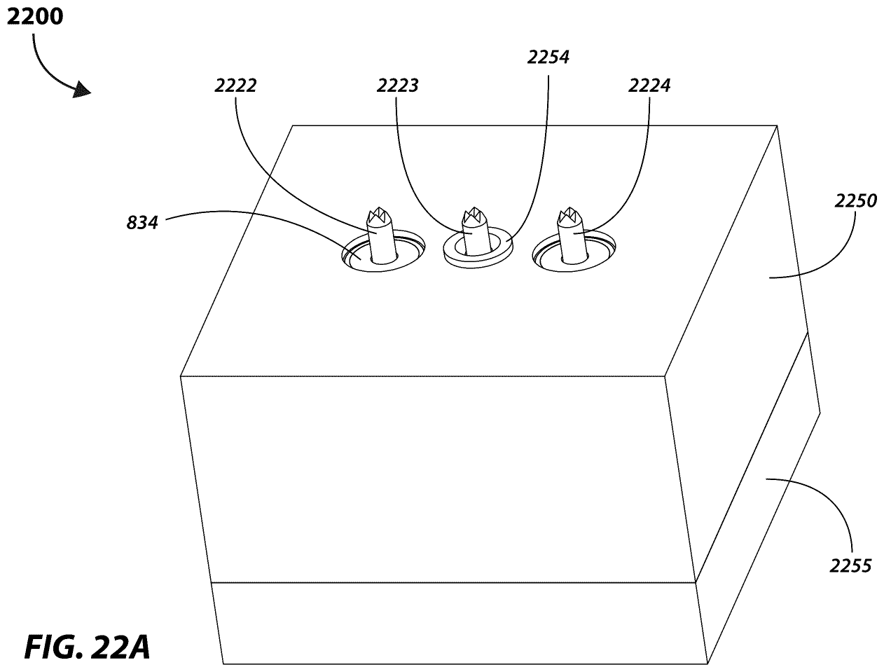

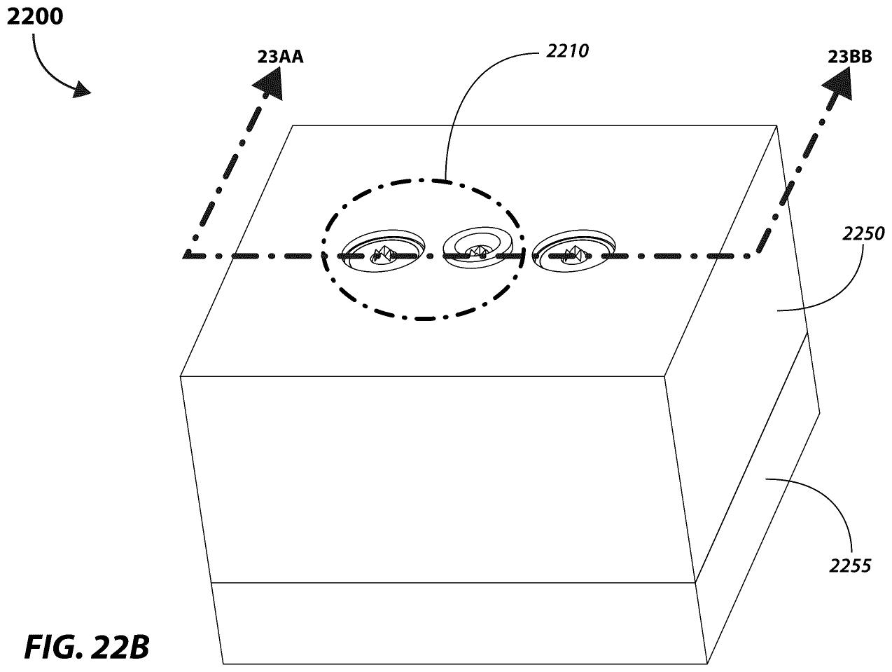

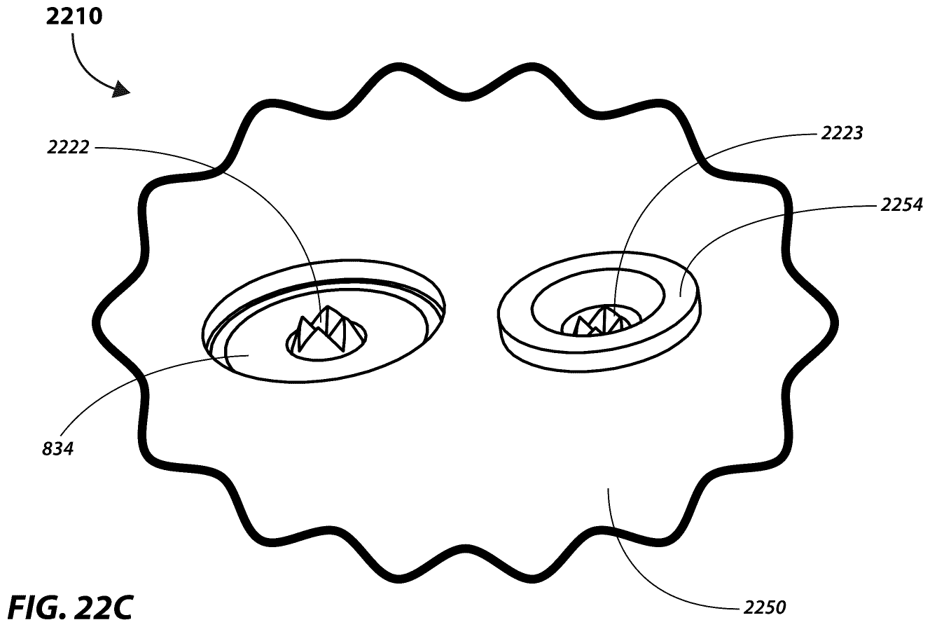

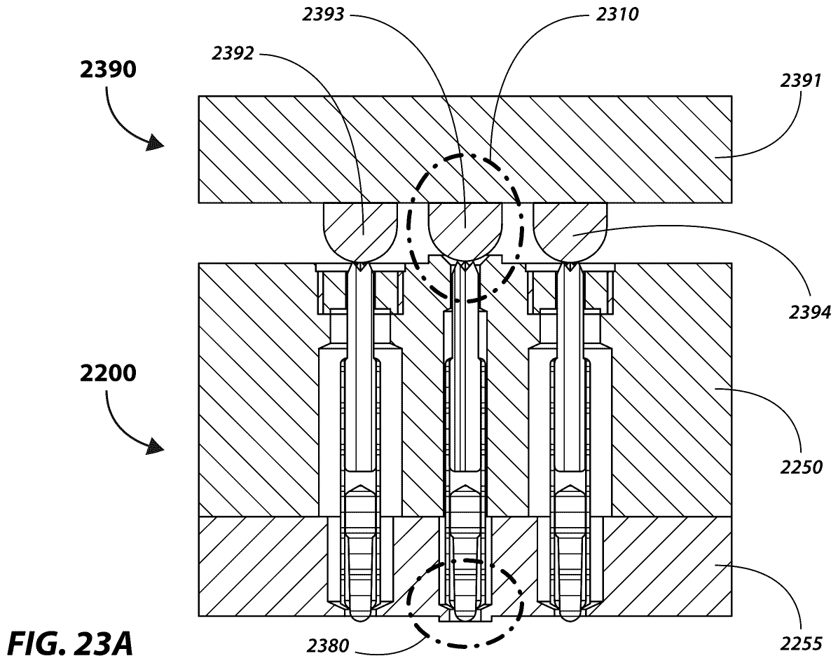

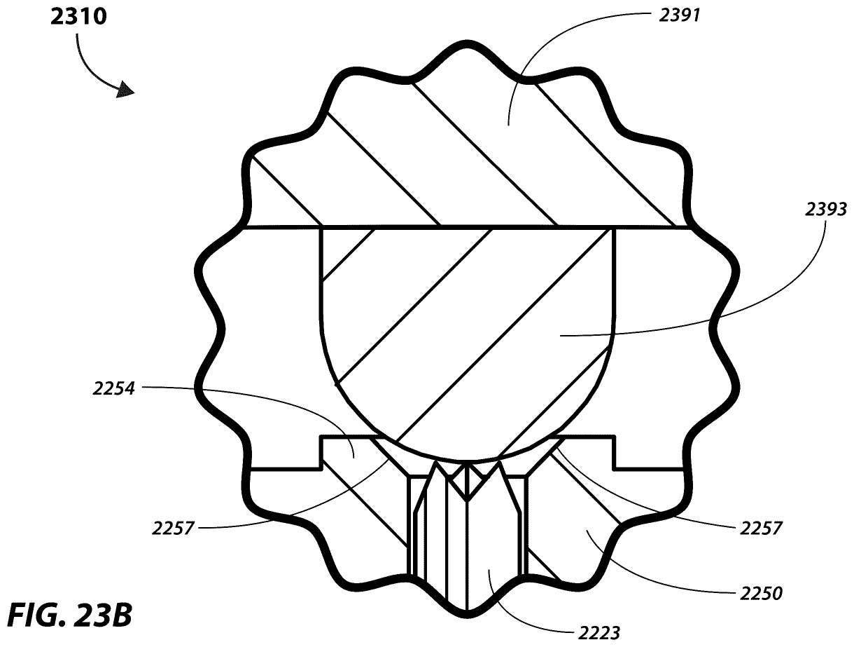

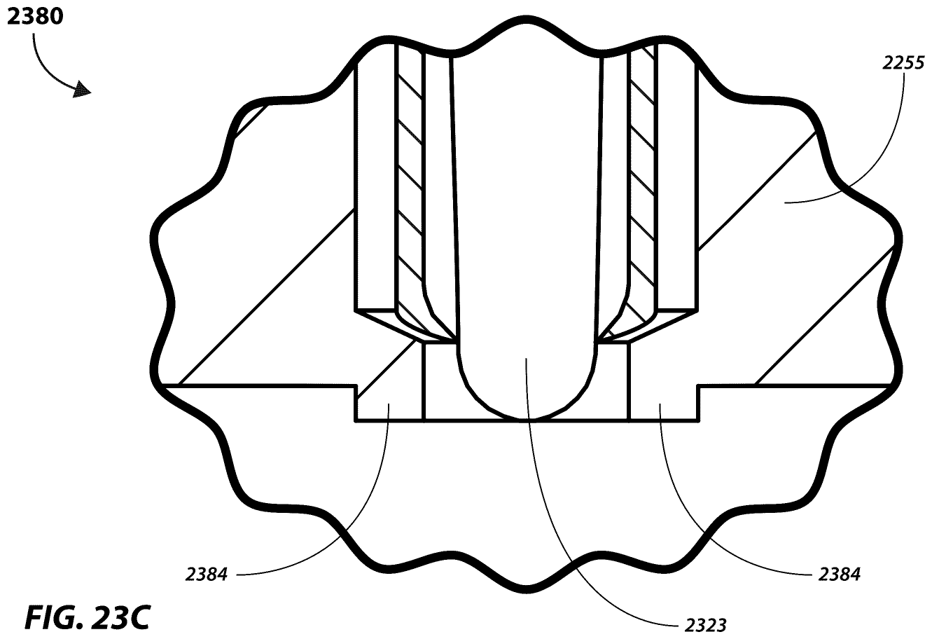

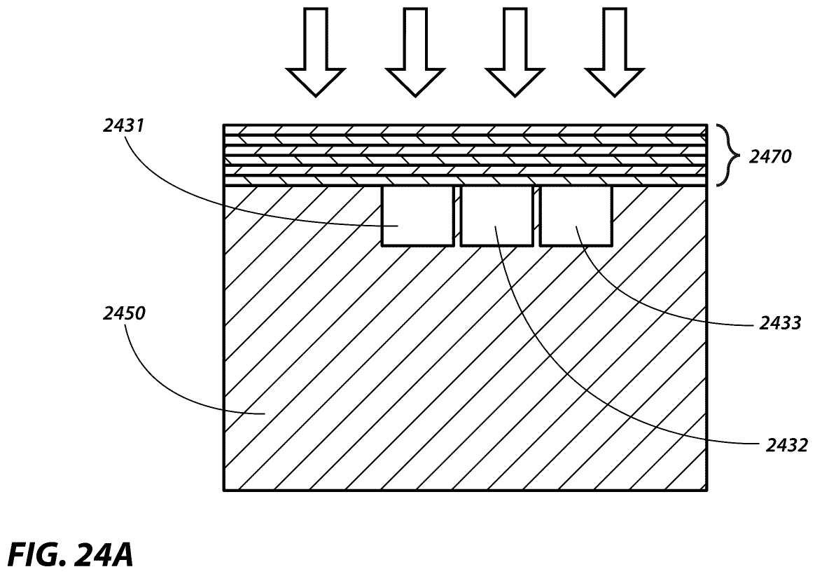

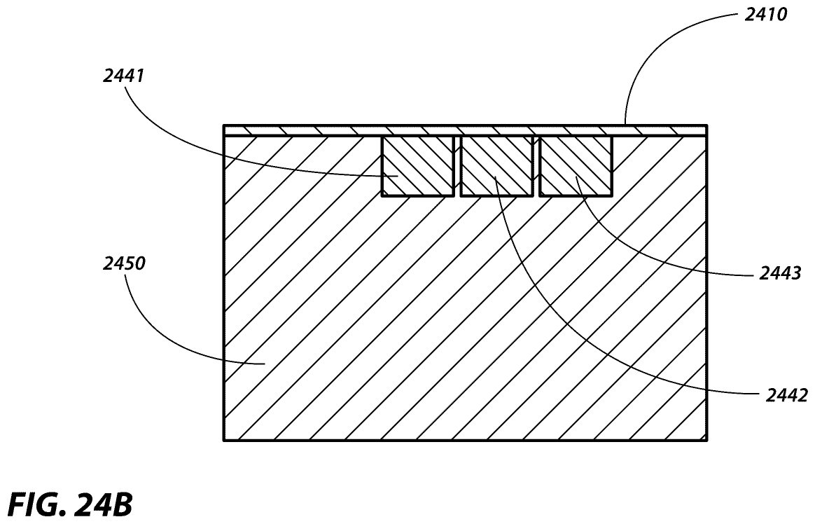

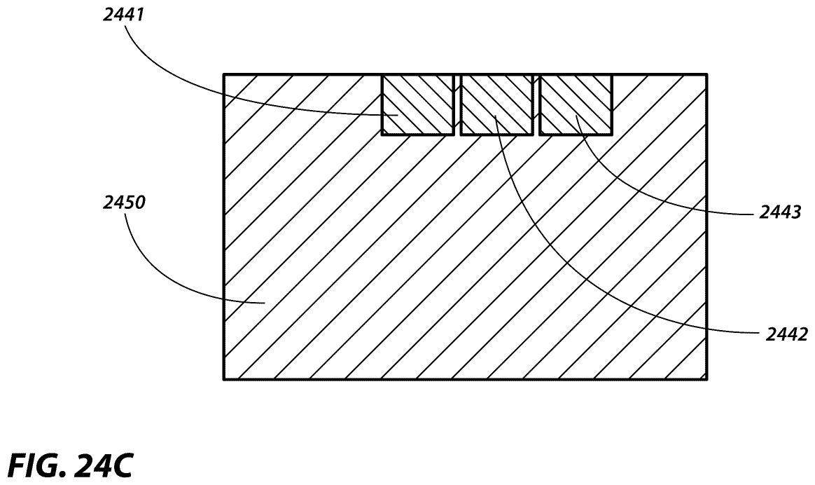

Referring now to exemplary contactor assembly 2200 of FIG. 22A-22B, coaxial signal pin 2222 is shown with locating bushing 834 secured in a machined cavity formed in upper block 2250, as exemplified by FIGS. 21C and 23A. Grounding annulus 2254 is shown with ground contact pin 2223 protruding. Grounding raised annulus 2254 has a chamfer along the circumference of the inner diameter to avoid direct contact forces with the contact ball of the DUT (not shown). Coaxial signal pin 2224 is also shown. In some embodiments, the cavity containing the dielectric bushing 834 has an internal diameter at the surface of 0.8 mm. Ground contact pin 2223 is fitted concentrically with annulus 2254 and will make the ground connection for the DUT at each applicable contact point. The contact pins 2222, 2223 and 2224 protrude enough to ensure good contact is made when compressed by the DUT contact balls or pads and in some embodiments this protrusion can be in the neighborhood of 500-600 μm.

FIG. 22B shows a view of FIG. 22A with the pins shown in the compressed or operating position when a DUT (not shown) is properly positioned. Section line 23AA-23BB is shown in FIG. 22C as a profile and segment 2210 will be shown first as an enlarged close up to aid in discerning the detail.

In FIG. 22C, pin 2222 is shown compressed into the operating position, with the dielectric bushing 834 locating it co-axially with the cavity into which bushing 834 is fitted. The inner diameter of the raised annulus 2254 is chosen so that the contact ball 2393 of the DUT does not touch it as shown in FIG. 23B. This diameter may be adjusted, for example by providing a taper or step 2257 at the inner circumference, to compensate for impedance discontinuities due to the changes that occur when the ball is present. In some embodiments, the outer diameter is a simple cylindrical shape with an internal diameter of 0.8 mm. In some embodiments the internal diameter is tapered so as to provide a broader band match for the discontinuity caused by the presence of the ball.

As shown in FIGS. 23A & 23B, ground contact pin 2223 is shown compressed and ground annulus 2254 is shown with an inner taper, e.g., a chamfer, which taper is cut to allow the DUT contact ball 2393 to make contact with the contact pin 2223 while preventing any mechanical forces that would result if the contact ball 2393 were to touch the interior of the ground annulus 2254. Mechanical forces that result from inadvertent contact may damage DUT 2390.

FIG. 23A illustrates a cross-sectional view along section line 23AA-23BB with the pins in the compressed or operating test position and the DUT 2390 present so as to illustrate the relative positions. The horizontal common tangent line or plane at the lowest point of contact balls 2392, 2393 and 2394 is parallel to the level upper surface of the contactor block 2250, above which grounding raised annuli protrude. In some embodiments, the tangent line or plane is coplanar with the upper surface plane of contactor block 2250.

FIG. 23B is a close-up view 2310 illustrating the relationship between the ground contact pin 2223, a DUT contact ball 2393 located at a bottom surface of the DUT substrate 2391 and concentric raised grounding annulus 2254. It should be pointed out that when DUT 2390 is properly positioned, the contact ball 2393 makes contact with the grounding pin 2223 and avoids mechanically contacting the inside of the grounding annulus 2254. Hence, in some embodiments, taper 2257 may be cut so as to be parallel to the tangent line of the contact ball 2393 at that point.

In some embodiments, as illustrated by the close-up view 2380 of FIG. 23C, the lower contactor block 2255 also includes grounding annulus 2384 with its pin opening enabling concentric ground contact pin 2323 to make contact with the test circuit board (not shown).

As discussed above, the manufacture of the contactor assembly surface having the raised annuli can be done by machining the surface to a depth that sets the height of the raised annuli. The closer spaced the annuli, the better the isolation between signal contact groups. This would appear as annuli having a relatively large diameter, but as the gap between annuli is reduced, the cutting tool should be smaller and the overall machining time will increase and will have an adverse effect upon the manufacturing cost. The choice of the annulus spacing, the inter-annulus gap, is therefore a compromise between manufacturing time and acceptable inter-signal isolation. The position of the annuli is set by the grid spacing geometry of the contact regions of the DUT.

Once the surface topography is created, in some embodiments, the entire surface may be anodized. Once the anodization process is complete, then a cutting pass is taken to relieve the surface of the raised annuli of their anodizing so that this surface region is bare metal. Other methods of passivation may be used, for example the application of a high quality adhesive non-conductive tape such as Kapton™ tape.

### V. Additional Methods of Fabricating Dielectric Bushings

As described above, the dielectric bushings that are used to position the depressible probes coaxially in the probe retention cavities cut into the upper and lower blocks of the contactor assembly. In addition to injection molding methods described above and depicted by FIGS. 13F-13J, in some embodiments, these bushings can also be created by hot-pressing thermoplastics. FIGS. 24A-24C depict one method of extruding a suitable dielectric material into the array of pockets. In this example, layers of pre-impregnated material (prepreg) can be used to create highly repeatable dielectric bushings as described in detail below.

FIG. 24A illustrates an upper block 2450 with dielectric bushing pockets 2431, 2432 and 2433 machined into the upper surface (see step 2511 of FIG. 25). Several layers of prepreg 2470 are placed over the top of the machined block and a die used to compress the prepreg layers between the die and the block in the direction of the arrows. This applied force causes the prepreg to be forced into the bushing pockets 2431, 2432 and 2433 so as to form dielectric plugs 2441, 2442 and 2443 as shown in FIG. 24B (step 2512 of FIG. 25). The residue 2410 can cover much of the surface of the upper block 2450 that contains the now filled bushing pockets.

To enhance this process, it is helpful if both the contactor block 2450 and the die used to compress the prepreg are both preheated. This reduces the viscosity of the prepreg so that it will flow more easily into the bushing pockets and this preheating may reduce the curing time for the prepreg material. It is also beneficial if this process is performed under vacuum since the vacuum aids greatly in reducing the presence of air bubbles in the prepreg as well as removing air that can become trapped within the pockets as the prepreg flows under mechanical pressure into the pockets. Removal of trapped air significantly improves the homogeneity of the bushings when fully formed and cured.

In some embodiments, a layer of Kapton™ tape is secured at the edge of the area within which the prepreg will be compressed. This may also be just a strip at the edges of the surface of the block. The Kapton™ tape is exceptionally durable and will act as a hard stop to prevent over compression of the prepreg. If the die is forced to the surface of the contactor block, then the prepreg residue has to be squeezed out entirely, but by limiting the travel of the die relative to the block then the spill from the edges of the block is better controlled and limited. The result of this limiting action is to avoid messy spillage which may need to be cleaned away prior to further machining efforts. The risk of uneven displacement of excess prepreg with attendant potential for distorting the contactor assembly is thus mitigated.

Once the process to form the dielectric plugs is complete and the curing time has elapsed, subsequent machining is used to remove any residue from the upper surface of the contactor block 2450 thereby revealing clean metal as shown in FIG. 24C. Pin openings are then formed within each of the dielectric plugs to form dielectric bushings (step 2516 of FIG. 25). Continued machining can be used to form the new surface with ground annular projections as previously described and the remaining machining performed to fashion the finished contactor assembly as described previously.

### VI. Integrated Fabrication of Dielectric Bushings and Ground Annuli

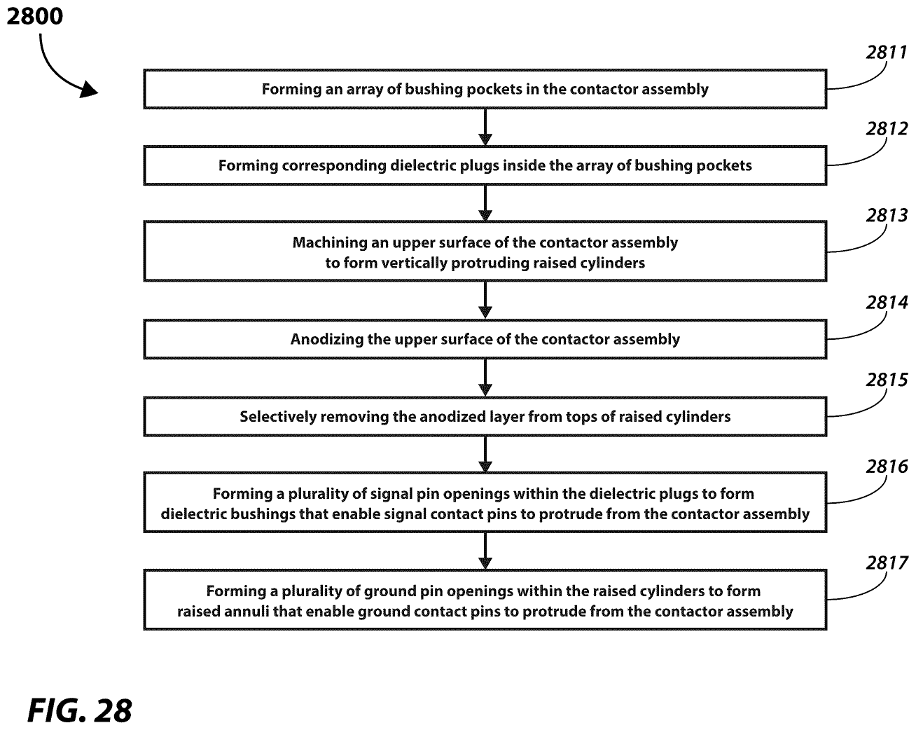

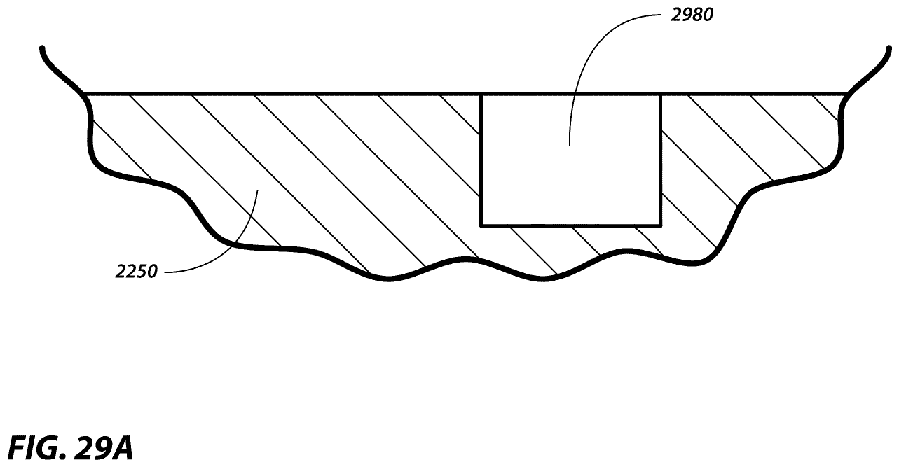

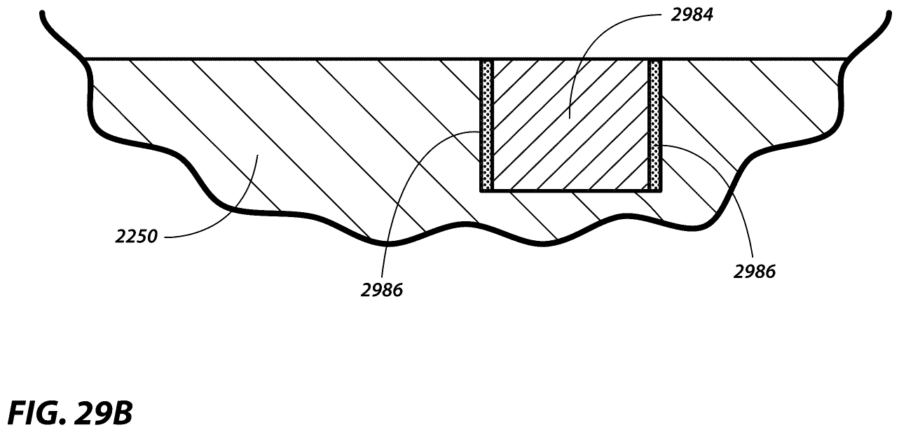

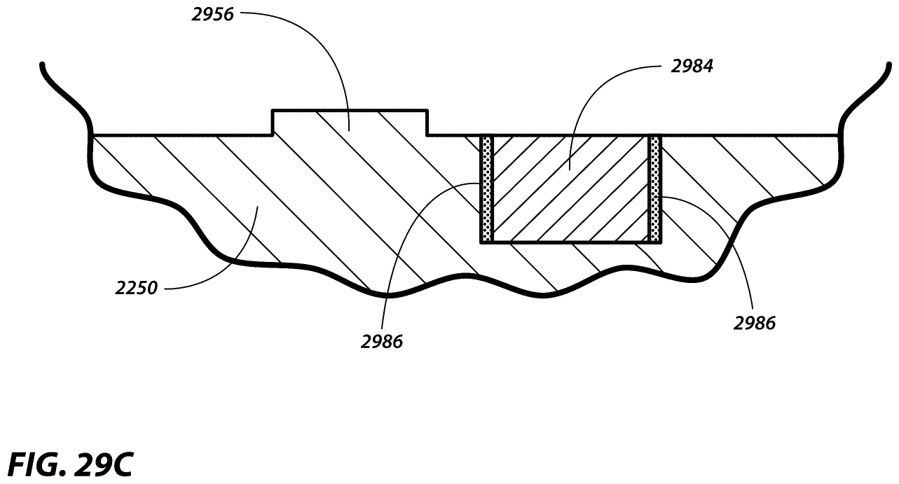

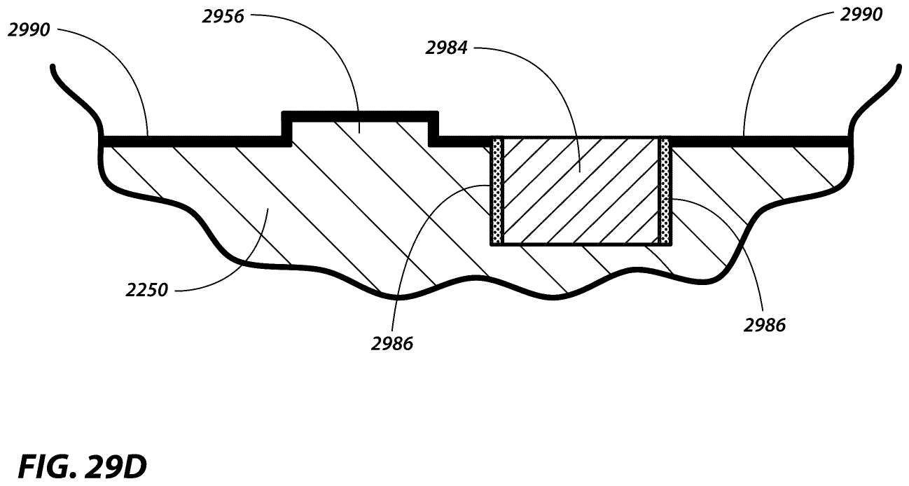

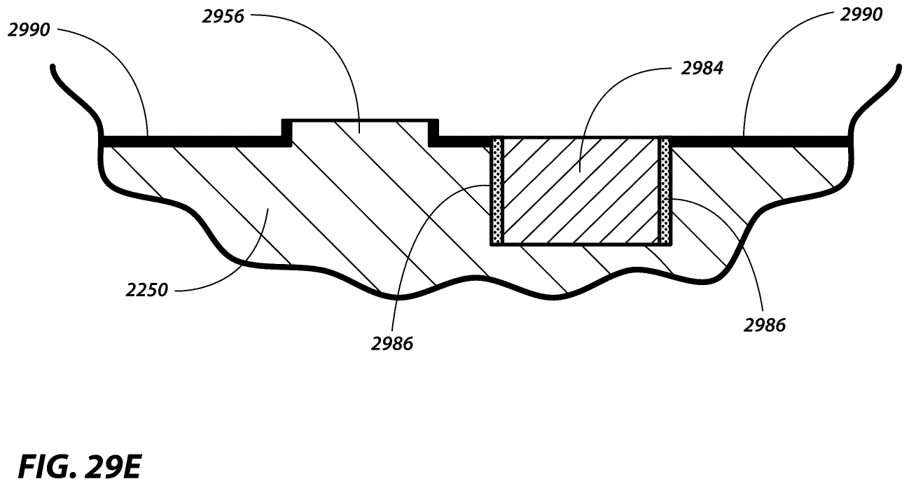

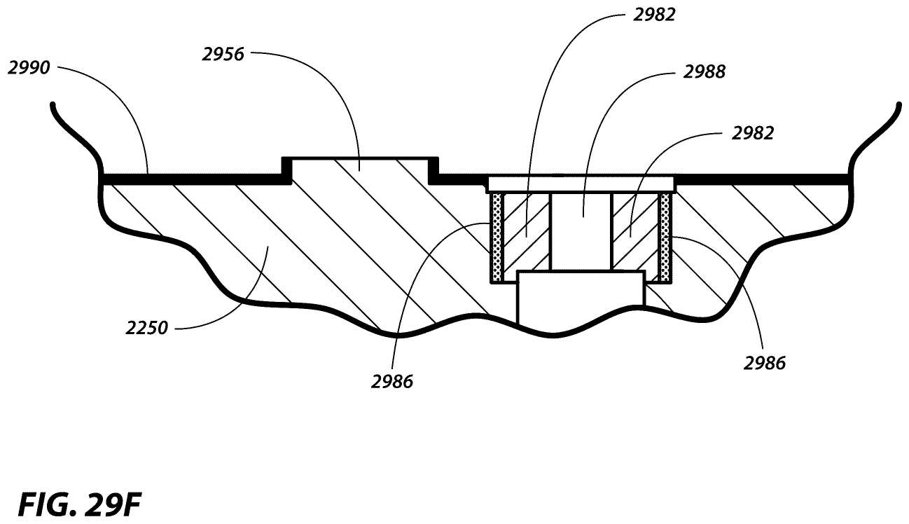

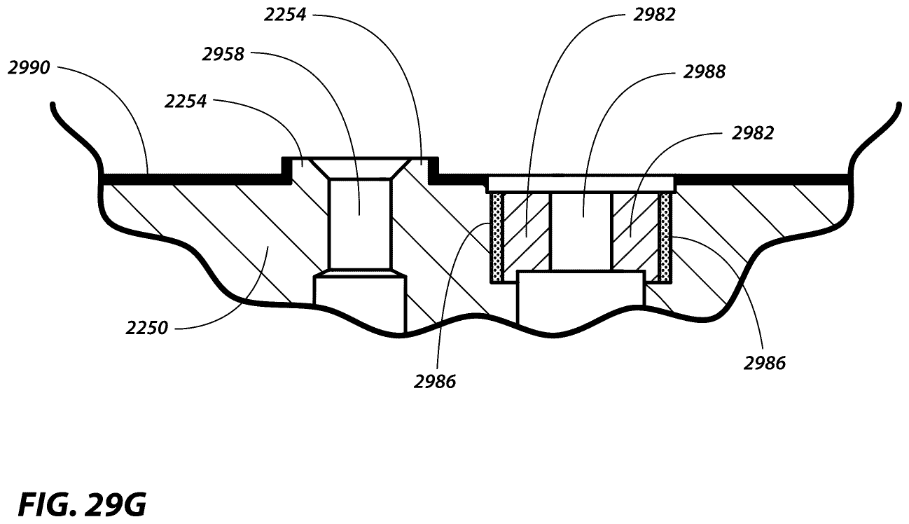

Referring now to FIGS. 28 and 29A-29G, high-level flow diagram 2800 illustrates an exemplary integrated manufacturing process for fabricating both dielectric bushings and raised ground annuli on the same contactor assembly using one or more of the various methods described in detail above. As shown in FIG. 29A, the first step 2811 of FIG. 28 creates an array of bushing pockets in either or both the upper and lower contactor block elements, e.g., pocket 2980. Step 2811 of FIG. 28 is also exemplified by bushing pockets 831, 1231, 1331, 1371 and 1431 of FIGS. 8B, 12A, 13A-B, 13E and 24A respectively.

As shown in FIG. 29B, step 2812 of FIG. 28 forms the dielectric plugs, e.g., plug 2984, inside the bushing pockets created in step 2811 of FIG. 28. Note that there are many methods for fabricating the dielectric plugs. In this example, an adhesive 2986 is used to secure plug 2984 to upper contactor block 2250. Note that these exemplary methods for fabricating dielectric plugs are described in detail above and are also depicted by, for example, FIGS. 12G-N in combination with FIGS. 12B-C, and also FIGS. 13C-D & 24B-C.

Referring now to FIG. 29C, the upper block 2250 is then further machined in step 2813 of FIG. 28 to form vertical cylinders, e.g., cylinder 2956, that protrude above the new upper surface of the block, by removing a surface layer of the upper block including some of the prepreg material that fills the bushing pockets to leave elevated annuli. As shown in FIG. 29D, step 2814 of FIG. 28 anodizes the upper block metal surface as well as the sides and tops of the protruding vertical cylinders to form an insulating hard anodized layer 2990. The dielectric plug 2984 and the thin ring of adhesive material 2986 are unaffected by the anodizing process. FIG. 29E depicts step 2815 of FIG. 28 wherein the anodized layer 2990 is selectively removed by machining it away from the tops of the vertical cylinders, e.g., the top of cylinder 2956, leaving bare metal exposed.

Referring to FIG. 29F and step 2816 of FIG. 28, pin openings, e.g., pin opening 2988, are machined into the dielectric plugs to form dielectric bushings, e.g., bushing 2982, so that the signal contact pins (not shown) may pass through from the inside of the upper block 2250 to protrude from the surface. As shown in FIG. 29G, step 2817 of FIG. 28 forms a pin opening, e.g., pin opening 2958, in each of the raised cylinders to form a raised annulus, e.g., annulus 2254, that allows passage of a ground contact pin (not shown) which protrudes until contacted by a corresponding contact point on a device under test. These signal pins and ground pins are compressed under pressure when the device under test is brought into proper placement for testing. Finally, any additional finishing steps, such as the provision of a clearance draft in the annulus 2254 for the contact balls on a device under test can now be completed.

VII. Synopsys of the Novel Aspects of the various Embodiments

In sum, the disclosed techniques overcome the limitations of traditional methods by integrating a dielectric component and grounded annuli into the contactor assembly to improve the broadband performance of the DUT test structures resulting in better electrical insulation between the contact pins. This is accomplished by a contactor assembly with an upper block and a lower block coupled to each other to house a plurality of depressible signal probes and ground probes for repeatedly maintaining reliable electrical contact with a corresponding plurality of DUT contact balls or pads. One or both of the upper block and the lower block is a bushed block made from a conductive material. The bushed block includes an array of bushing pockets for securing a corresponding plurality of dielectric bushings. These dielectric bushings are fabricated by machining the array of bushing pockets for housing dielectric plugs, and then machining holes within the plugs to form the dielectric bushings. The holes of the dielectric bushings function as pin openings for the contact pins of depressible signal probes to protrude and make electrical contact with the DUT signal contact pads.

The contactor assembly can also house depressible ground probes. The upper surface of the bushed upper block includes raised annuli protruding vertically from the upper surface. These raised annuli include ground pin openings for the contact pins of depressible ground probes to protrude and make electrical contact with the DUT ground contact pads. The lower surface of the lower block also includes raised annuli that include ground pin openings for the contact pins of depressible ground probes to protrude and make electrical contact with the test board ground contact pads. The novel approaches described above advantageously reduce the interfering signal level to an acceptable level, provides extended high frequency performance and enables both unbalanced and balanced signal feeds without compromising frequency response.

VIII. Permutations of Novel Aspects of the various Embodiments
1. In some embodiments, a method for fabricating a contactor assembly having improved dielectric insulation comprises machining an array of bushing pockets in a bushed block of the contactor assembly, wherein the contactor assembly includes an upper block and a lower block, wherein the upper block and the lower block are configured to be coupled to each other to house a plurality of depressible probes, wherein the bushed block is one of the upper block and the lower block, wherein the contactor assembly is configured to detachably make electrical contact with a plurality of contact pads of a Device-Under-Test (DUT), and wherein the machined array of bushing pockets are arranged in a pattern matching the plurality of contact pads of the DUT, forming a corresponding plurality of protrusions from a dielectric material, wherein the plurality of protrusions extends from a dielectric base, wherein the plurality of dielectric protrusions are arranged in the same matching pattern, and wherein the plurality of dielectric protrusions are accommodated inside the array of bushing pockets, machining away the dielectric base from the bushed block thereby forming a plurality of dielectric plugs in the bushed block, and wherein tops of the resulting plurality of dielectric plugs are flush with a surface of the bushed block, and machining a plurality of pin openings within the plurality of dielectric plugs to form a plurality of dielectric bushings, wherein the plurality of pin openings are configured to enable a plurality of contact pins of the plurality of depressible probes to protrude from the surface to make electrical contact with the contact pads of the DUT.
2. The method of clause 1 wherein the depressible probes are slanted, and wherein the plurality of pin openings are tilted at a corresponding angle relative to the surface of the bushed block to enable the contact pins of the depressible probes to protrude.
3. The method of any of clauses 1 and 2 wherein a subset of the plurality of dielectric plugs are disjointed from each other and configured to carry unbalanced signals.
4. The method of any of clauses 1 through 3 wherein a subset of the plurality of dielectric plugs are conjoined and configured to carry balanced signals.
5. The method of any of clauses 1 through 4 wherein the formation of the plurality of protrusions includes machining a plurality of pillars, wherein the plurality of pillars are the plurality of protrusions extending from the dielectric base, inserting the plurality of pillars into the array of bushing pockets, and securing the plurality of dielectric pillars inside the array of bushing pockets.
6. The method of any of clauses 1 through 5 wherein the pillars are secured with an adhesive.
7. The method of any of clauses 1 through 6 wherein the pillars include serrations for excess adhesive.
8. The method of any of clauses 1 through 7 wherein at least one of the array of bushing pockets and plurality of protrusions include a chamfer to ease insertion of the plurality of protrusions into the array of bushing pockets.
9. The method of any of clauses 1 through 8 wherein at least one of the array of bushing pockets and plurality of protrusions include a tapered profile to ease insertion of the plurality of protrusions into the array of bushing pockets.
10. The method of any of clauses 1 through 9 wherein the formation of the plurality of protrusions includes forming a plurality of rods, forming a plurality of holes in the dielectric base, inserting the plurality of rods into the plurality of holes to form the plurality of protrusions, and securing the plurality of pillars inside the array of bushing pockets.
11. The method of any of clauses 1 through 10 wherein the plurality of rods are formed by machining or by extrusion.
12. The method of any of clauses 1 through 11 wherein the pillars are secured with an adhesive.
13. The method of any of clauses 1 through 12 wherein the pillars include serrations for excess adhesive.
14. The method of any of clauses 1 through 13 wherein at least one of the array of bushing pockets and plurality of protrusions include a chamfer to ease insertion of the plurality of protrusions into the array of bushing pockets.
15. The method of any of clauses 1 through 14 wherein at least one of the array of bushing pockets and plurality of protrusions include a tapered profile to ease insertion of the plurality of protrusions into the array of bushing pockets.
16. The method of any of clauses 1 through 15 wherein the plurality of dielectric bushings are impedance tuned.
17. The method of any of clauses 1 through 16 wherein the contactor assembly is also configured to house a plurality of depressible ground probes, the method further comprising machining an upper surface of the bushed block of the contactor assembly to form a plurality of raised cylinders, wherein the plurality of raised cylinders protrude vertically from the machined upper surface of the bushed block, anodizing the upper surface of the bushed block to form an insulating anodized layer, selectively machining away the anodized layer from top surfaces of the plurality of raised cylinders, and machining a plurality of ground pin openings within the plurality of raised cylinders to form a plurality of raised annuli, wherein the plurality of ground pin openings are configured to enable contact pins of the plurality of depressible ground probes to protrude from the plurality of raised annuli to make electrical contact with a plurality of ground contact pads of the DUT.
18. The method of any of clauses 1 through 17 wherein the plurality of ground pin openings are chamfered.
19. In some embodiments, a contactor assembly including a bushed block with dielectric bushings useful for testing a packaged integrated circuit device under test (DUT), the contactor assembly comprises a first block having a first plurality of probe pin openings enabling a first plurality of contact pins of a plurality of compressible probes to protrude, a second block having a second plurality of probe pin openings enabling a second plurality of contact pins of the plurality of compressible probes to protrude, wherein the contactor assembly includes a plurality of probe retention cavities for housing the plurality of compressible probes configured to repeatedly maintain reliable electrical contact with a corresponding plurality of DUT contact pads when under a compliant force, each of the compressible probes having a probe barrel which is contained within its probe retention cavity and oppositely extending first and second contact pins, the oppositely extending contact pins of each of the compressible probes being depressible in the probe barrel, wherein at least one of the first block and the second block is a bushed block made from a conductive material, wherein the bushed block includes an array of bushing pockets and a corresponding plurality of dielectric bushings secured inside the array of bushing pockets, wherein one of the first plurality of contact pins and the second plurality of contact pins is a corresponding plurality of bushed contact pins, and wherein the plurality of dielectric bushings are fabricated by machining the array of bushing pockets in the bushed block of the contactor assembly, and wherein the machined array of bushing pockets are arranged in a pattern matching the plurality of DUT contact pads, forming a corresponding plurality of protrusions from a dielectric material, wherein the plurality of protrusions extends from a dielectric base, wherein the plurality of dielectric protrusions are arranged in the same matching pattern, and wherein the plurality of dielectric protrusions are accommodated inside the array of bushing pockets, machining away the dielectric base from the bushed block thereby forming a plurality of dielectric plugs in the bushed block, and wherein tops of the resulting plurality of dielectric plugs are flush with a surface of the bushed block, and machining a plurality of holes within the plurality of dielectric plugs to form the plurality of dielectric bushings, wherein the plurality of holes are configured to enable the plurality of bushed contact pins to protrude from the surface to make electrical contact with the plurality of DUT contact pads.
20. The contactor assembly of clause 19 wherein the bushed block is an upper block.
21. The contactor assembly of any of clauses 19 through 20 wherein the bushed block is a lower block.
22. The contactor assembly of any of clauses 19 through 21 wherein the plurality of dielectric bushings are impedance tuned.
23. The contactor assembly of any of clauses 19 through 22 wherein the depressible probes are slanted, and wherein the plurality of pin openings are tilted at a corresponding angle relative to the surface of the bushed block to enable the contact pins of the depressible probes to protrude.
24. The contactor assembly of any of clauses 19 through 23 wherein a subset of the plurality of dielectric plugs are disjointed from each other and configured to carry unbalanced signals.
25. The contactor assembly of any of clauses 19 through 24 wherein a subset of the plurality of dielectric plugs are conjoined and configured to carry balanced signals.
26. The contactor assembly of any of clauses 19 through 25 wherein the formation of the plurality of protrusions includes machining a plurality of pillars, wherein the plurality of pillars are the plurality of protrusions extending from the dielectric base, inserting the plurality of pillars into the array of bushing pockets, and securing the plurality of pillars inside the array of bushing pockets.
27. The contactor assembly of any of clauses 19 through 26 wherein the pillars are secured with an adhesive.
28. The contactor assembly of any of clauses 19 through 27 wherein the pillars include serrations for excess adhesive.
29. The contactor assembly of any of clauses 19 through 28 wherein at least one of the array of bushing pockets and plurality of protrusions include a chamfer to ease insertion of the plurality of protrusions into the array of bushing pockets.
30. The contactor assembly of any of clauses 19 through 29 wherein at least one of the array of bushing pockets and plurality of protrusions include a tapered profile to ease insertion of the plurality of protrusions into the array of bushing pockets.
31. The contactor assembly of any of clauses 19 through 30 wherein the formation of the plurality of protrusions includes forming a plurality of rods, forming a plurality of holes in the dielectric base, inserting the plurality of rods into the plurality of holes to form the plurality of protrusions, and securing the plurality of dielectric pillars inside the array of bushing pockets.
32. The contactor assembly of any of clauses 19 through 31 wherein the plurality of rods are formed by machining or by extrusion.
33. The contactor assembly of any of clauses 19 through 32 wherein the pillars are secured with an adhesive.
34. The contactor assembly of any of clauses 19 through 33 wherein the pillars include serrations for excess adhesive.
35. The contactor assembly of any of clauses 19 through 34 wherein at least one of the array of bushing pockets and plurality of protrusions include a chamfer to ease insertion of the plurality of protrusions into the array of bushing pockets.
36. The contactor assembly of any of clauses 19 through 35 wherein at least one of the array of bushing pockets and plurality of protrusions include a tapered profile to ease insertion of the plurality of protrusions into the array of bushing pockets.
37. The contactor assembly of any of clauses 19 through 36 wherein the contactor assembly is also configured to house a plurality of depressible ground probes, wherein an upper surface of the bushed block of the contactor assembly includes a plurality of raised annuli protruding vertically from the upper surface, and wherein the plurality of raised annuli include a corresponding plurality of ground pin openings configured to enable contact pins of the plurality of depressible ground probes to protrude from the plurality of raised annuli to make electrical contact with a plurality of ground contact pads of the DUT.
38. The contactor assembly of any of clauses 19 through 37 wherein the plurality of raised annuli is fabricated by machining the upper surface of the bushed block of the contactor assembly to form a plurality of raised cylinders, anodizing the upper surface of the bushed block to form an insulating anodized layer, selectively machining away the anodized layer from top surfaces of the plurality of raised cylinders, and machining the plurality of ground pin openings within the plurality of raised cylinders to form the plurality of raised annuli.
39. The contactor assembly of any of clauses 19 through 38 wherein the plurality of ground pin openings are chamfered.
40. In some embodiments, a method for fabricating a contactor assembly having improved dielectric insulation comprises machining an array of bushing pockets in a bushed block of the contactor assembly, wherein the contactor assembly includes an upper block and a lower block, wherein the upper block and the lower block are configured to be coupled to each other to house a plurality of depressible probes, wherein the bushed block is one of the upper block and the lower block, wherein the contactor assembly is configured to detachably make electrical contact with a plurality of contact pads of a Device-Under-Test (DUT), and wherein the machined array of bushing pockets are arranged in a pattern matching the plurality of contact pads of the DUT, filling the array of bushing pockets with a moldable dielectric material, and wherein the array of bushing pockets functions as a mold, machining away any excess moldable dielectric material from the bushed block thereby forming a plurality of dielectric plugs in the bushed block, and wherein tops of the resulting plurality of dielectric plugs are flush with a surface of the bushed block, and machining a plurality of pin openings within the plurality of plugs to form a plurality of dielectric bushings, wherein the plurality of pin openings are configured to enable a plurality of contact pins of the plurality of depressible signal probes to protrude from the surface to make electrical contact with the contact pads of the DUT.
41. The method of clause 40 wherein the moldable dielectric material is a thermoplastic material and wherein filling the array of bushing pockets includes hot-pressing the thermoplastic material directly into the array of bushing pockets.
42. The method of any of clauses 40 and 41 wherein the moldable dielectric material is an epoxy resin and wherein the filling the array of bushing pockets includes vacuum infusing the epoxy resin directly into the array of bushing pockets.
43. The method of any of clauses 40 through 42 wherein the moldable dielectric material is a plastic material and wherein filling the array of bushing pockets includes injecting the plastic material directly into the array of bushing pockets.
44. The method of any of clauses 40 through 43 wherein each of the array of bushing pockets includes a valley for securing the plastic material.
45. The method of any of clauses 40 through 44 wherein an inner circumferential surface of each of the array of bushing pockets have a negative draft angle relative to the surface of the bushed block, the negative draft angle enabling the plastic material to be secured to the array of bushing pockets.
46. The method of any of clauses 40 through 45 wherein the array of bushing pockets is trapezoidal-shaped.
47. The method of any of clauses 40 through 46 wherein the contactor assembly is also configured to house a plurality of depressible ground probes, the method further comprising machining an upper surface of the bushed block of the contactor assembly to form a plurality of raised cylinders, wherein the plurality of raised cylinders protrude vertically from the machined upper surface of the bushed block, anodizing the upper surface of the bushed block to form an insulating anodized layer, selectively machining away the anodized layer from top surfaces of the plurality of raised cylinders, and machining a plurality of ground pin openings within the plurality of raised cylinders to form a plurality of raised annuli, wherein the plurality of ground pin openings are configured to enable contact pins of the plurality of depressible ground probes to protrude from the plurality of raised annuli to make electrical contact with a plurality of ground contact pads of the DUT.
48. In some embodiments, a contactor assembly including a bushed block with dielectric bushings useful for testing a packaged integrated circuit device under test (DUT), the contactor assembly comprises a first block having a first plurality of probe pin openings enabling a first plurality of contact pins of a plurality of compressible probes to protrude, a second block having a second plurality of probe pin openings enabling a second plurality of contact pins of the plurality of compressible probes to protrude, wherein the contactor assembly includes a plurality of probe retention cavities for housing the plurality of compressible probes configured to repeatedly maintain reliable electrical contact with a corresponding plurality of DUT contact pads when under a compliant force, each of the compressible probes having a probe barrel which is contained within its probe retention cavity and oppositely extending first and second contact pins, the oppositely extending contact pins of each of the compressible probes being depressible in the probe barrel, wherein at least one of the first block and the second block is a bushed block made from a conductive material, wherein the bushed block includes an array of bushing pockets and a corresponding plurality of dielectric bushings secured inside the array of bushing pockets, wherein one of the first plurality of contact pins and the second plurality of contact pins is a corresponding plurality of bushed contact pins, and wherein the plurality of dielectric bushings are fabricated by machining the array of bushing pockets in the bushed block of the contactor assembly, and wherein the machined array of bushing pockets are arranged in a pattern matching the plurality of DUT contact pads, filling the array of bushing pockets with a moldable dielectric material, and wherein the array of bushing pockets functions as a mold, machining away any excess moldable dielectric material from the bushed block thereby forming a plurality of dielectric plugs in the bushed block, and wherein tops of the resulting plurality of dielectric plugs are flush with a surface of the bushed block, and machining a plurality of holes within the plurality of plugs to form the plurality of dielectric bushings, wherein the plurality of holes are configured to enable the plurality of bushed contact pins to protrude from the surface to make electrical contact with the plurality of DUT contact pads.
49. The contactor assembly of clause 48 wherein the moldable dielectric material is a thermoplastic material and wherein filling the array of bushing pockets includes hot-pressing the thermoplastic material directly into the array of bushing pockets.
50. The contactor assembly of any of clauses 48 and 49 wherein the moldable dielectric material is an epoxy resin and wherein the filling the array of bushing pockets includes vacuum infusing the epoxy resin directly into the array of bushing pockets.
51. The contactor assembly of any of clauses 48 through 50 wherein the moldable dielectric material is a plastic material and wherein the filling the array of bushing pockets includes injecting the plastic material directly into the array of bushing pockets.
52. The contactor assembly of any of clauses 48 through 51 wherein each of the array of bushing pockets includes a valley for securing the plastic material.
53. The contactor assembly of any of clauses 48 through 52 wherein an inner circumferential surface of each of the array of bushing pockets have a negative draft angle relative to the surface of the bushed block, the negative draft angle enabling the plastic material to be secured to the array of bushing pockets.
54. The contactor assembly of any of clauses 48 through 53 wherein the array of bushing pockets is trapezoidal-shaped.
55. The contactor assembly of any of clauses 48 through 54 wherein the contactor assembly is also configured to house a plurality of depressible ground probes, wherein an upper surface of the bushed block of the contactor assembly includes a plurality of raised annuli protruding vertically from the upper surface, and wherein the plurality of raised annuli include a corresponding plurality of ground pin openings configured to enable contact pins of the plurality of depressible ground probes to protrude from the plurality of raised annuli to make electrical contact with a plurality of ground contact pads of the DUT.
56. The contactor assembly of any of clauses 48 through 55 wherein the plurality of raised annuli is fabricated by machining the upper surface of the bushed block of the contactor assembly to form a plurality of raised cylinders, anodizing the upper surface of the bushed block to form an insulating anodized layer, selectively machining away the anodized layer from top surfaces of the plurality of raised cylinders, and machining the plurality of ground pin openings within the plurality of raised cylinders to form the plurality of raised annuli.
57. The contactor assembly of any of clauses 48 through 56 wherein the plurality of ground pin openings are chamfered.

Many modifications and permutations of the above-described embodiments are also possible and are contemplated in accordance with the present invention. For example, instead of being slanted, the pin assemblies can be housed inside vertical cavities formed in upper blocks of contactor assemblies.

While this invention has been described in terms of several embodiments, there are alterations, modifications, permutations, and substitute equivalents, which fall within the scope of this invention. For example, many modifications are possible and the above-described features from the various embodiments can be useful alone or in combination. Although sub-section titles have been provided to aid in the description of the invention, these titles are merely illustrative and are not intended to limit the scope of the present invention.

It should also be noted that there are many alternative ways of implementing the methods and apparatuses of the present invention. It is therefore intended that the following appended claims be interpreted as including all such alterations, modifications, permutations, and substitute equivalents as fall within the true spirit and scope of the present invention.

What is claimed is:

1. A method for fabricating a contactor assembly having improved dielectric insulation, the method comprising:
machining an array of bushing pockets in a bushed block of the contactor assembly, wherein the contactor assembly includes an upper block and a lower block, wherein the upper block and the lower block are configured to be coupled to each other to house a plurality of depressible probes, wherein the bushed block is one of the upper block and the lower block, wherein the contactor assembly is configured to detachably make electrical contact with a plurality of contact pads of a Device-Under-Test (DUT), and wherein the array of bushing pockets are arranged in a pattern matching the plurality of contact pads of the DUT;
forming a corresponding plurality of protrusions from a dielectric material, wherein the plurality of protrusions extends from a dielectric base, wherein the plurality of dielectric protrusions are arranged in the pattern matching the plurality of contact pads of the DUT, and wherein the plurality of dielectric protrusions are accommodated inside the array of bushing pockets;
machining away the dielectric base from the bushed block thereby forming a plurality of dielectric plugs in the bushed block, and wherein tops of the plurality of dielectric plugs are flush with a surface of the bushed block; and
machining a plurality of pin openings within the plurality of dielectric plugs to form a plurality of dielectric bushings, wherein the plurality of pin openings are configured to enable a plurality of contact pins of the plurality of depressible probes to protrude from the surface to make electrical contact with the contact pads of the DUT.

2. The method of claim 1 wherein the depressible probes are slanted, and wherein the plurality of pin openings are tilted at a corresponding angle relative to the surface of the bushed block to enable the contact pins of the depressible probes to protrude.

3. The method of claim 1 wherein a subset of the plurality of dielectric plugs are disjointed from each other and configured to carry unbalanced signals.

4. The method of claim 1 wherein a subset of the plurality of dielectric plugs are conjoined and configured to carry balanced signals.

5. The method of claim 1 wherein forming the corresponding plurality of protrusions includes:
machining a plurality of pillars, wherein the plurality of pillars are the corresponding plurality of protrusions extending from the dielectric base;
inserting the plurality of pillars into the array of bushing pockets; and
securing the plurality of pillars inside the array of bushing pockets.

6. The method of claim 1 wherein forming the corresponding plurality of protrusions includes:
forming a plurality of rods;
forming a plurality of holes in the dielectric base;
inserting the plurality of rods into the plurality of holes to form the plurality of protrusions; and
securing the plurality of dielectric pillars inside the array of bushing pockets.

7. The method of claim 1 wherein the plurality of dielectric bushings are impedance tuned.

8. The method of claim 1 wherein the contactor assembly is also configured to house a plurality of depressible ground probes, the method further comprising:
machining an upper surface of the bushed block of the contactor assembly to form a plurality of raised cylinders, wherein the plurality of raised cylinders protrude vertically from the upper surface of the bushed block;
anodizing the upper surface of the bushed block to form an insulating anodized layer;
selectively machining away the insulating anodized layer from top surfaces of the plurality of raised cylinders; and
machining a plurality of ground pin openings within the plurality of raised cylinders to form a plurality of raised annuli, wherein the plurality of ground pin openings are configured to enable contact pins of the plurality of depressible ground probes to protrude from the plurality of raised annuli to make electrical contact with a plurality of ground contact pads of the DUT.

9. A contactor assembly including a bushed block with dielectric bushings useful for testing a packaged integrated circuit device under test (DUT), the contactor assembly comprising:
a first block having a first plurality of probe pin openings enabling a first plurality of contact pins of a plurality of compressible probes to protrude;
a second block having a second plurality of probe pin openings enabling a second plurality of contact pins of the plurality of compressible probes to protrude;
wherein the first block and the second block are configured to be coupled to each other to form a plurality of probe retention cavities for housing a plurality of depressible probes configured to repeatedly maintain reliable electrical contact with a corresponding plurality of DUT contact pads when under a compliant force, wherein each of the compressible probes has a probe barrel which is contained within its probe retention cavity and oppositely extending first and second contact pins, the oppositely extending contact pins of each of the compressible probes being depressible in the probe barrel; and
wherein at least one of the first block and the second block is a bushed block made from a conductive material, wherein the bushed block includes an array of bushing pockets and a corresponding plurality of dielectric bushings secured inside the array of bushing pockets, wherein one of the first plurality of contact pins and the second plurality of contact pins is a corresponding plurality of bushed contact pins; and
wherein the plurality of dielectric bushings are fabricated by:
machining the array of bushing pockets in the bushed block of the contactor assembly, and wherein the array of bushing pockets are arranged in a pattern matching the plurality of DUT contact pads;
forming a corresponding plurality of protrusions from a dielectric material, wherein the plurality of protrusions extends from a dielectric base, wherein the plurality of dielectric protrusions are arranged in the pattern matching the plurality of contact pads of the DUT, and wherein the plurality of dielectric protrusions are accommodated inside the array of bushing pockets;
machining away the dielectric base from the bushed block thereby forming a plurality of dielectric plugs in the bushed block, and wherein tops of the plurality of dielectric plugs are flush with a surface of the bushed block; and
machining a plurality of holes within the plurality of dielectric plugs to form the plurality of dielectric bushings, wherein the plurality of holes are configured to enable the plurality of bushed contact pins to protrude from the surface to make electrical contact with the plurality of DUT contact pads.

10. The contactor assembly of claim 9 wherein the depressible probes are slanted, and wherein the plurality of pin openings are tilted at a corresponding angle relative to the surface of the bushed block to enable the contact pins of the depressible probes to protrude.

11. The contactor assembly of claim 9 wherein forming the plurality of protrusions includes:
machining a plurality of pillars, wherein the plurality of pillars are the corresponding plurality of protrusions extending from the dielectric base;
inserting the plurality of pillars into the array of bushing pockets; and
securing the plurality of pillars inside the array of bushing pockets.

12. The contactor assembly of claim 9 wherein forming the plurality of protrusions includes:
forming a plurality of rods;
forming a plurality of holes in the dielectric base;
inserting the plurality of rods into the plurality of holes to form the plurality of protrusions; and
securing the plurality of dielectric pillars inside the array of bushing pockets.

13. The contactor assembly of claim 9 wherein the contactor assembly is also configured to house a plurality of depressible ground probes, wherein an upper surface of the bushed block of the contactor assembly includes a plurality of raised annuli protruding vertically from the upper surface, and wherein the plurality of raised annuli include a corresponding plurality of ground pin openings configured to enable contact pins of the plurality of depressible ground probes to protrude from the plurality of raised annuli to make electrical contact with a plurality of ground contact pads of the DUT.

14. The contactor assembly of claim 13 wherein the plurality of raised annuli is fabricated by:
machining the upper surface of the bushed block of the contactor assembly to form a plurality of raised cylinders;
anodizing the upper surface of the bushed block to form an insulating anodized layer;
selectively machining away the insulating anodized layer from top surfaces of the plurality of raised cylinders; and
machining the plurality of ground pin openings within the plurality of raised cylinders to form the plurality of raised annuli.

15. A method for fabricating a contactor assembly having improved dielectric insulation, the method comprising:
machining an array of bushing pockets in a bushed block of the contactor assembly, wherein the contactor assembly includes an upper block and a lower block, wherein the upper block and the lower block are configured to be coupled to each other to house a plurality of depressible probes, wherein the bushed block is one of the upper block and the lower block, wherein the contactor assembly is configured to detachably make electrical contact with a plurality of contact pads of a Device-Under-Test (DUT), and wherein the array of bushing pockets are arranged in a pattern matching the plurality of contact pads of the DUT;
filling the array of bushing pockets with a moldable dielectric material, and wherein the array of bushing pockets functions as a mold;
machining away any excess moldable dielectric material from the bushed block thereby forming a plurality of dielectric plugs in the bushed block, and wherein tops of the plurality of dielectric plugs are flush with a surface of the bushed block; and
machining a plurality of pin openings within the plurality of plugs to form a plurality of dielectric bushings, wherein the plurality of pin openings are configured to enable a plurality of contact pins of the plurality of depressible probes to protrude from the surface to make electrical contact with the contact pads of the DUT.

16. The method of claim 15 wherein the moldable dielectric material is a thermoplastic material and wherein filling the array of bushing pockets includes hot-pressing the thermoplastic material directly into the array of bushing pockets.

17. The method of claim 15 wherein the moldable dielectric material is an epoxy resin and wherein filling the array of bushing pockets includes vacuum infusing the epoxy resin directly into the array of bushing pockets.

18. The method of claim 15 wherein the moldable dielectric material is a plastic material and wherein filling the array of bushing pockets includes injecting the plastic material directly into the array of bushing pockets.

19. The method of claim 18 wherein each of the array of bushing pockets includes a valley for securing the plastic material.

20. The method of claim 18 wherein an inner circumferential surface of each of the array of bushing pockets have a negative draft angle relative to the surface of the bushed block, the negative draft angle enabling the plastic material to be secured to the array of bushing pockets.

21. The method of claim 15 wherein the contactor assembly is also configured to house a plurality of depressible ground probes, the method further comprising:
machining an upper surface of the bushed block of the contactor assembly to form a plurality of raised cylinders, wherein the plurality of raised cylinders protrude vertically from the upper surface of the bushed block;
anodizing the upper surface of the bushed block to form an insulating anodized layer;
selectively machining away the insulating anodized layer from top surfaces of the plurality of raised cylinders; and
machining a plurality of ground pin openings within the plurality of raised cylinders to form a plurality of raised annuli, wherein the plurality of ground pin openings are configured to enable contact pins of the plurality of depressible ground probes to protrude from the plurality of raised annuli to make electrical contact with a plurality of ground contact pads of the DUT.
